(19) United States
(12) Patent Application Publication
(10) Pub. No.: US 2017/0212399 A1
(43) Pub. Date: Jul. 27, 2017

(54) W5RS: Anlinx & Milinx & Zilinx for Green Energy Smart Window

(71) Applicant: Min Ming Tarng, San Jose, CA (US)

(72) Inventors: Min Ming Tarng, San Jose, CA (US); Mei-Jech Lin, San Jose, CA (US); Eric Yu-Shiao Tarng, San Jose, CA (US); Alfred Yu-Chi Tarng, San Jose, CA (US); Angela Yu-Shiu Tarng, San Jose, CA (US); Huang-Chang Tarng, San Jose, CA (US)

(73) Assignee: tang system, San Jose, CA (US)

(21) Appl. No.: 15/472,262

(22) Filed: Mar. 28, 2017

Related U.S. Application Data
(63) Continuation-in-part of application No. 13/918,989, filed on Jun. 16, 2013.

(51) Int. Cl. G02F 1/153; C09K 9/02; H01L 31/048; G02F 1/157; F24J 2/04; G02F 1/163

(52) U.S. Cl. CPC G02F 1/1533; F24J 2/0433; G02F 1/163; H01L 31/0488; G02F 1/157; C09K 9/02; E06B 2009/2476

(57) ABSTRACT

The Green Energy Smart Window of Wireless Window 5R System W5RS is constituted of the Multimedia panel, the Electrochromic panel and the transparent Solar panel, etc. The Green Energy Smart Window harvests solar energy with transparent solar panel to be electric energy to provide power to smart Multimedia panel and smart Electrochromic panel, etc. “W5RS” is the Green Energy Smart Window of the next generation smart home standard. “W5” represents “Wireless Wireline Weave Wishful Window”. “5R” represents “Recycling Resonant Resynchronization Rectifying Regulator”. The novel 5R can have the AC/DC power efficiency 95% which is the highest for the wireless power supply standards. “5S” represents “Smart Solar Supply Silicon System”. “W5RS” is the killer application and “5R” is the killer core technology. To integrate the “W5RS” technology to be the Green Energy Smart Window, the “W5RS” adopts the 23Less Green Technology. The 23Less Green Technology are the Noiseless Field System On Chip FSOC, Curtainless Window, Bladeless Turbofan, Brakeless Vehicle, Sawless LNA, Resistorless, Capless, Inductorless, Diodeless Random Number Generator, Xtaless Clock Generator, Clockless Switch Mode Power Supply, Ground-Bounceless I/O, Switch Lossless Rectifier, Power-Lossless PA, Rippleless and EMI-Less Battery Charger, Overshootless and Rippleless LDO.

### RELATED APPLICATIONS

This patent application is the Continuation in Part application of application of Ser. No. 13/918,989 claiming priorities of application 12/422,719 filed Apr. 13, 2009, U.S. patent application Ser. No. 12/317,973, filed Dec. 31, 2008, now U.S. Pat. No. 8,089,324 issued on Jan.3, 2012; U.S. patent application Ser. No. 12/291,984, filed Nov. 12, 2008, U.S. patent application Ser. No. 12/291,618, filed Nov. 12, 2008, now U.S. Pat. No. 7,876,188 issued on Jan.25, 2011; U.S. patent application Ser. No. 12/288,770, filed Oct. 23, 2008, now U.S. Pat. No. 7,663,349 issued on Feb. 16, 2010; U.S. patent application Ser. No. 12/229,412, filed Aug. 23, 2008, now U.S. Pat. No. 8,089,323 issued on Jan. 3, 2012; U.S. patent application Ser. No. 12/082,601, filed Apr. 12, 2008; U.S. patent application Ser. No. 12/079,179, filed Mar. 25, 2008, now U.S. Pat. No. 8,089,353 issued on Jan. 3, 2012; U.S. patent application Ser. No. 11/593,271, filed Nov. 6, 2006, now U.S. Pat. No. 7,511,589; U.S. patent application Ser. No. 11/500,125, filed Aug. 5, 2006, now U.S. Pat. No. 7,525,392 issued on Apr. 28, 2009; U.S. patent application Ser. No. 892,358, filed Jul. 14, 1997, now U.S. Pat. No. 5,850,093; U.S. patent application Ser. No. 854,800; filed Mar. 23, 1992, now U.S. Pat. No. 5,280,200; U.S. patent application Ser. No. 81,074, filed Jun. 22, 1993, now U.S. Pat. No. 5,793,125; U.S. patent application Ser. No. 577,792 filed Sep. 5, 1990, now U.S. Pat. No. 5,198,691; U.S. patent application Ser. No. 577,791, filed Sep. 5, 1990, now U.S. Pat. No. 5,111,076; which herein incorporated by references in its entirety.

### BACKGROUND FIELD OF INVENTION

The sunshine shines into the room. The sun-shine, creates a lot heat. Therefore, the electrochromic film is used to reduce the light intensity injecting into the room. However, it has the internal leakage current in the electrochromic maintain the electrochromic film in the opaque state, it needs to continue supplying a lot of electric energy to maintain the opaque state of the electrochromic film. It needs the extra outside energy from the grid to maintain the opaque of electrochromic film.

With my invention of Green Energy Smart Window, the sunshine energy is converted to be electrical energy. The energy directly supplies to the electrochromic film to maintain, the opaque state. It is no more need the external power supply to supply the electricity. Furthermore, the electrical energy can supply to the external world. With the wire power connection, the electrical energy can be provided to the smart grid etc. With the wireless power connection, the electrical energy can be provided to the mobile device, etc.

As shown in the FIG. 1A, the Green Energy Smart Window of W5RS is the new standard which is promoted by the innovative company, Tang System. A Green Energy Smart Window of Wireless Window 5R System W5RS is constituted of Multimedia panel, Electrochromic panel and Transparent Solar panel, etc. The Transparent Solar Cell panel harvests solar energy to be electric energy to provide power to Multimedia panel and Electrochromic Window panel. The Green Energy Smart Window is not only self-powered but also provides the electrical energy to smart grid and mobile devices. “W5RS” is the killer product application in Silicon Valley and “5R” is the killer core IP technology in Silicon Valley. “W5” represents the “Wireless and Wireline Weaving Wishful Window”. “5R” represents “Recycling Resonant Desynchronizing Rectifying Regulator”. “5S” represents the “Smart Solar Supply Silicon System”.

In summary, the energy supplied for the house warming or the house cooling is the largest power consumption. The largest amount energy dissipation is released from the window of the house. The Electrochromic EC window is adopted to minimize the largest power consumption. However, the Electrochromic EC window has the leaking current that the EC window controller has the stand-by power consumption. So, we need to have the Green Energy Smart Window for the Smart Home. The Green Energy Smart Window of Smart Home has to be energy self-contained. The transparent solar window of the Smart Window for Smart Home can convert the sunlight energy to be the energy of battery, smart grid and electrochromic EC window, etc. The 23Less Green Technologies for the Field Programmable System On Chip FSOC of the Green Energy Smart Window are as follows.

(1) Defectless Uniform Multi-State Dimmer EC Glass.

(2) PowerLoss-Less 5R: Recycling Resonant Resynchronous Rectifier Regulator;

(3) H-Bridgeless AC DC converter;

(4) RF-Noiseless Window Driver;

(5) H-Bridgeless Microinverter;

(6) Rippleless Battery Charger;

(7) Curtainless Smart Window;

(8) Filmless Touch Screen;

(9) Touchless Screen;

(10) Rippless Fast Lock PLL;

(11) Humidity-EMI-Less Xtaless LC Clock with plastic package;

(12) bladeless turbofan;

(13) PowerLoss-Less PA;

(14) Xtaless Clock;

(15) Inductorless SMPS;

(16) Ground BounceLess I/O;

(17) Overshootless LDO;

(18) Rippleless LDO;

(19) Sawless LNA;

(20) Capless LDO;

(21) Diodeless Random Generator;

(22) Resistorless Current Sensor;

(23) Brakeless Motor Vehicle;

So, the green technology needs to improve the house energy to fill up the energy requirement. It needs to convert the conventional window to be the Green Energy Smart Window. It needs to incorporate the dimmer light, dimmer window, multimedia window and solar window, etc to be wireless network. The green technology is for the smart window multimedia panel, solar panel and EC panel, etc. To have the efficient wireless charging of Power over WiFi, PoWiFi, the RF power amplifier PA of the window controller needs to be power efficient. The WiFi PA has power efficiency to be less than 15%. For the WiFi standard, our Power-Lossless conjugated PA has the power efficiency more than 75%. To receive the wireless efficiently, the 5R core technology converts the AC sinusoidal power energy to DC energy with high power efficiency being larger than 95%. Even for the wireless power supply standards of the Wireless Power Consortium (WPC) Qi and Alliance For Wireless Power (A4WP), the novel “single stage” 5R can have the AC/DC power efficiency as high as 95% which is the highest record in the world. It is the record of the world.

Furthermore, our Sawless low noise amplifier LNA works in the noiseless integrated chip with our Power-Lossless conjugated PA. Our noise isolation technology is the key technology for the next-generation cutting-edge Field-System-On-Chip FSOC. The controller costs a lot. The controller has to be the integrated chip to save the cost. To integrate the controller to be an integrated chip, it must have the noise isolation technology. To merge ASIC with FPGA to be the FSOC, it needs the Noise Isolation Technology of Green Technology. With our 23Less Green Technology, we can generate the noiseless Field Programmable System On Chip FSOC. With our ultrasonic assisted deposition, platen and hardening process, the Defectless Uniform multi-state dimmer EC Glass can be achieved to make the smart EC Window to be commercial.

A Green Energy Smart Window of Wireless 5R System W5RS is constituted of Multimedia panel, Electrochromic panel and transparent Solar panel. The transparent Solar Cell panel harvests solar energy to be electric energy to provide power to Multimedia panel and Electrochromic panel. The electrical energy further provides to smart grid and mobile devices. Furthermore, Green Energy Smart Window of W5RS adopts the isolation technology to integrate the FPGA, Analog Front, RF Front. Digital circuits, etc to be FSOC. ASIC is Application Specific Integrated Circuit. FPGA is Field Programmable Gate Array and FSOC is the Field-System-On-Chip. For the Green Technology, FSOC will merge ASIC and FPGA together to be the Field-System-On-Chip. As the semiconductor device process continues shrinking down, the mask price and process price are much higher. The product revenue of one-generation cannot recover the investment. It needs the revenue of several generations to cover the Non-recurring engineering (NRE) cost. So, all the chips will be forced to be FSOC. So far, there are ASIC and FPGA two categories. In the future, it will have FSOC, Field-System-On-Chip, only.

Anlinx is analog programmable chip. Milinx is mixed signal programmable chip. Zilinx is the analog, digital, mixed signal and RF programmable chip. The Field-System-On-Chip FSOC of Anlinx, Milinx and Zilinx is based on the 23Less green technology to integrate the FPGA with ASIC to be the field programmable FSOC. Thanks to the cooperative works of Dr. Mei Jech Lin, Eric Yu-Shiao Tang, Alfred Yu-Chi Tarng, Angela Yu-Shia Tarng, Huang Chang Tarng, the revolutionary innovations had developed to be the FSOC of Anlinx, Milinx and Zilinx.

### BACKGROUND-DESCRIPTION OF PRIOR ART

The thin film battery and Electronic Chromatic EC window technology have developed more than 80 years. However, the Electronic Chromatic EC window cannot be widely accepted by the market yet. There is non-uniform local defect and there is serious leakage. The Electronic Chromatic EC window have the most difficult problem to be the “uniformity in color” of the Electronic Chromatic EC window. In the middle voltage state, the non-uniform in color of the Electronic Chromatic EC window will show up. To avoid the show up of the non-uniform defect, the Electronic Chromatic EC window has to operates at bi-state, bleach state or color state. It causes the Electronic Chromatic EC window consumes a lot of power.

Before, the system integration of the multiple smart panels doesn't exist. The smart solar panel doesn't exist. The Electrochromic window consumes a lot of power due to the leakage of the electrochromic thin-film battery of the electrochromic glass. The Multimedia window is not compatible with Electrochromic window. The Solar Window energy doesn't provide to smart grid and mobile devices, either. Furthermore, the FPGA cannot integrate the ADC on the same chip. The switch noise generated by the FPGA will destroy all the performance of the high performance of ADC. Therefore, there is no high performance ADC on FPGA. The other RF/AF/analog cannot be integrated on FPGA, either. All these ADC and RF/AF/analog circuits are left to be on the ASIC chip. The chips are the noise generators. All the noise generated by the chips is dumped on the board. There is an implicit assumption that the board is the ground having the infinite capacitance. However, this implicit assumption is no more true as the mobile products becomes thin and small. There is no big board to serve as the ideal ground. Since there is no,isolation technology in the conventional chip that the ASIC still has to be used. The noise isolation of the conventional chip adopts the multiple power and ground buses.

### OBJECTS AND ADVANTAGES

The object to promote the Green Energy Smart Window of W5RS to be the international standard for the next generation green technology. A Green Energy Smart Window of Wireless Window 5R System W5RS is constituted of Multimedia panel, Electrochromic panel and transparent Solar panel. The Solar Cell panel harvests solar energy to be electric energy to provide power to Multimedia panel and Electrochromic panel. The electrical energy further provides to smart grid and mobile devices. Furthermore, this integration is extended to the Scalable iPindow of iPhome & Scalable Smart Window of Smart Home to provide the electricity for the whole home. It saves the national energy consumption by more than 20%. The Green Energy Smart Window of W5RS has the communication and multimedia capabilities of phone, internet and TV services. Even for the WPC Qi and A4WP wireless power supply standards, the novel single stage 5R can have the AC/DC power efficiency as high as 95% which is the highest record in the world. “5S” represents “Smart Solar Supply Silicon System”. “W5” represents “Wireless Wireline Weave Wishful Window”. “5R” represents “Recycling Resonant Resynchronization Rectifying Regulator”. “W5RS” is the killer application product of Silicon Valley and “5R” is the killer core IP technology of Silicon Valley. Using the noise isolation technology to build up the platform to integrate all the FPGA and ASIC together to be FSOC, the Green Energy Smart Window provides the complete set solution for smart home. It saves all the world energy consumption by more than half.

### DRAWING FIGURES

FIG. 1 (A1) is the overall system of the Green Energy Smart Window for the Smart Home, it includes multimedia window such as LCD/LED/OLED/TV Flat panel, the transparent solar cell panel, ventilation, smart fan controller, humidity controller, the touch screen, touchless screen, battery and thin-film battery, wireless communication, wireless power supply, SeDes, fiber optic communication, smart fan EC window and dimmer light, etc.; (A2) is the overall system of the Green Energy Smart Window having multiple glass or plastic support panels; (B) is the architecture of the Smart Window of Smart Home; (C) is the Field System On Chip FSOC for the Smart Window of Smart Home; the FSOC includes sub-modules listed at the bottom; (D) is the system and architecture of the multimedia Smart Window of Smart Home; (E1) is the cross-section of they touch-screen; (E2) is the top-view of the conventional touch-screen; (E3) is the top-view of the filmless touch-screen; (E4) is the touch on the top of the filmless touch-screen; (E5) is the equivalent circuit of the touch on the top of the filmless touch-screen; (E6) is the pulsing wave propagating in the conducting layer of the filmless touch screen; (F1) is the smart fan having the bladeless turbofan and humidity/de-humidity/filter air-conditional multi-function; (F2) is the section view of the smart fan embedded in the smart window; (F3) is the working principle of the bladeless turbofan; (F4A) is the diode characteristic curves over temperature; (F4B) is the temperature sensor circuit to measure the on-chip temperature for the smart ventilation window, etc.; (G1) is the smart plug made of the FSOC, (G2) is the analogy between the phone plug and power plug; (G3) is the combinatory Phone Plug and Power Plug made of the FSOC for the Smart Window of Smart Home; (H1) is the AC/DC conversion of the rectifier and micro-inverter, etc. with the H-bridge; (H2) is the Unipolar-DC/Bipolar-DC conversion of the battery charger and window driver, etc. with H-bridge; (I) is the global view of the power conversions among different power resources; (J1) is the block diagram of the H-Bridgeless power conversion; (J2) is the circuit of H-Bridgeless power conversion injecting the power; (J3) is the circuit of H-Bridgeless power conversion extracting the power; (J4) is the timing diagram for the triggering action of the H-Bridgeless power conversion; (K) is one illustrated example to show the fundamental working principal of power re-cycling between the huge SMPS output switches; it is to reduce the power switch loss especially in high-frequency switching operation; (L1) is the W5RS Window 5R System using the Wireless 5R Recycling Resonant Resynchronization Rectifier Regulator Supply, programmable LDOs of Analog LDO and Digital LDO; (L2) is the waveforms of the Analog LDO for the power supply of bandgap circuit, etc; (L3) is the waveform of the Digital LDO for the power supply of microprocessor, etc, (L4) is the comparisons between Analog LDO and Digital LDO; (M1) is the exterior view of the smart window; (M2) is the interior view of the smart window, (N1) is the air circulation loop of the smart window; (N2) is the low frequency current oscillatory loop for the wireless charging; (N3) is the antenna of the wireless charging for high frequency protocols such as POWiFi, BlueTooth BT and RFID, etc.

FIG. 2 is the frequency impact on the Green Technology. (A) is the low frequency clock/signal waveform; (B) is the high frequency clock/signal waveform; (C) is the chain reaction mechanism impacting on the system integration; (D) is the performance degrade as the function of the frequency for the analog/ADC or RF/LNA circuit.

FIG. 3 is the conventional system, (A) is the partition of the system to be chips; (B) is the signal level and the substrate noise level of the chips.

FIG. 4 is the impact of the substrate noise coupling; (A) is the analog chip; (B) is the digital chip having the substrate noise; (C) is the substrate noise coupling in the integration of the analog chip and the digital chip; (B) is the noise coupling mechanism of the substrate noise.

FIG. 5 is the conventional digital and FPGA switching noise; (A) is the switching noise generated by the digital and/or FPGA chips; (B) is the switch noise augmented by the decoupling capacitor.

FIG. 6 is the introduction of the noise isolation technique; (A) is the conventional digital chip having the ground node (0 node) set at the board; (B) is the ground nodes (0 node) set at the substrate of the chip in the SPICE simulation; (C) is the noise isolation having the ground node (0 node) set at the board; (D) is the analogy of the magnetic shield for the heat isolation in the fusion chamber; (E) is the electric shield for the noise isolation in the planar chip.

FIG. 7 is the fundamental pattern of the noise isolation technique; (A) is the noise isolation for the digital chip having the noiseless substrate; the Kirchhoff's Current Law (KCL) shows I_{U}=I_{B} that only one current regulator is needed; (B) the analog circuit can co-exist in the same chip having noiseless substrate.

FIG. 8 is the substrate model; (A) is the substrate; (B) is the electric model for the substrate; (C) is the noise coupling in substrate model with separate ground buses; (D) is the hydraulic model for the noise coupling in substrate model with separate ground buses; (E) is the hydraulic model for the noise isolation technique; (F) is the electric model for the Noise Isolation Technology.

FIG. 9 is the analysis of the power and ground voltages in the noise isolation technique; it proves that there is no substrate noise injected into the substrate; (A) is the capacitor with the current loop of charging and discharging; (B) is the capacitor with the current loop having the ground node for charging and discharging; (C) is the capacitor with the current loop having the ground node and substrate for charging and discharging; (D) is the Electric Field analogy of the Noise Isolation Technology; (E) is the power and ground voltages in the system integration with the noise isolation technology.

FIG. 10 is the comparisons to make the differential between the “current regulator noise isolation platform” and the “voltage regulator analog-digital multi-power-bus platform”; (A) is the noise isolation technique with the current regulator; (B) is the conventional analog chip to use the voltage regulator to get rid of the power supply noise by the factor PSRR power supply rejection ratio; (C) is the table of comparisons between the “current regulator of the noise isolation technique” and the “voltage regulator of the analog chip in the noisy board” environment; (B) is the switching operation of the voltage regulator; (E) is the switching operation of the current regulator.

FIG. 11 is the comparison of voltage source and current source; (A) is the voltage source; (B) is the current source; (C) is the current source of the current regulator; (D) is the adaptive current source of the current regulator.

FIG. 12 is the comparisons of the current regulator and voltage regulator; (A) is the digital switching noises in the power supply; (B) is the spectrum of the power supply having the digital switching noise; (C1) is the waveforms of signals of current regulator; (C2) is the block diagram of the current regulator; (C3) is the input noise signal spectrum of the current regulator; (C4) is the control signal spectrum of the current regulator; (D1) is the signal waveform of voltage regulator; (D2) is the block diagram of the voltage regulator; (D3) is the input noise signal spectrum of of the voltage regulator; (D4) is the control signal spectrum of the voltage regulator.

FIG. 13 is the average current generator for the current regulator; (A) is the current average; (B) is the voltage average; (C) is the current average of the current regulator being implemented with the voltage average; (D1) is the preferred implementation of the current regulator of which the pre-filter serves as the average function; (D2) is the alternative implementation of the current regulator of which the post-filter serves as the average function; (D3) is the cascading current regulator; it has the pre-filter and post-filter for the feedback signal; the filter is for the feed forward output current.

FIG. 14 is the different ways to implement the average function; (A) is the block diagram of the average; (B) is the window function in the time domain to implement the average with the integration and divider; (C) is the timing window function to implement the average function; (D) is the low pass filter to implement the average function; (E1) is the waveform of the digital switching noise; (E2) is the sampling to implement the average function: (F) is the current regulator adopting the filter as shown in the FIG. 14D and the sampling as shown in FIG. 14E2 to get the average current for the P-P type cascading current regulator; (G) is the alternative implementation of the current regulator; it adopts the filter as shown in the FIG. 14D; the sampling is as shown in FIG. 14E2; it is to get the average current for the P-N type cascading current regulator. It is noted that the current regulator having the filter Fp and Fn; the voltage regulator doesn't have a filter.

FIG. 15 is the fundamental current collator; (A) is the architecture of the current regulator; (B) is the circuit and system of the current regulator.

FIG. 16 the current regulator is for the digital circuit or whole chip; the voltage regulator is for the analog or RF circuit; (A) is the architecture having the current regulator and voltage regulator: (B) is the circuit and system having the current regulator and voltage regulator.

FIG. 17 is the cascade current regulator for the digital circuit or whole chip; the voltage regulator is for the analog or RF circuit; (A) is the architecture of the cascade current regulator and voltage regulator, (B) is the circuit of the cascade current regulator and voltage regulator.

FIG. 18 is the cascade current regulator for the digital circuit or whole chip; (A) is the system block diagram of the cascade current regulator; (B) is the architecture of the cascade current regulator; (C) is the circuit of the cascade current regulator; (D) is the simulation of power and ground curves of the conventional Power and Ground plan: (E) is the simulation of power and ground curves of the Noise Isolation Technology.

FIG. 19 is the cascade of current regulator and the voltage regulator; (A) is the system of the cascade current regulator and voltage regulator; (B) is the architecture of the cascade current regulator and voltage regulator; (C) is the circuit of the cascade current regulator and voltage regulator.

FIG. 20 is the cascade of the current regulator and switch mode power supply; (A) is the system of the cascade of the current regulator and switch mode power supply; (B) is the architecture of the cascade current regulator and switch mode power supply; (C) is the circuit of the cascade current regulator and the switch mode power supply.

FIG. 21 is the comparison of the conventional power supply with the current regulator power supply; (A) is the switch mode power supply for the digital circuit or voltage regulator; (B) is the voltage regulator power for the analog circuit or RF circuit; (C1) is the signal flow block diagram of the current regulator; the signal flowing direction is in the reverse direction of the voltage regulator; (C2) is the signal flow block diagram of the current regulator; the signal flowing direction is in the normal left-to-right direction.

FIG. 22 is the current regulator; (A) is the current regulator having the constant current; (B) is the spectrum of the current regulator having the constant current.

FIG. 23 is the slow varying current regulator: (A) is the current regulator having the slow varying current; (B) is the spectrum of the current regulator having the slow varying current.

FIG. 24 is the the versatile arrangements of the on-chip multi-power supplies; (A) is the current regulator located at the upper power layer; (B) is the current regulator located at the lower power layer; (C) is the multi-current regulator located at the upper and lower power layer; (D) is the hierarchical view of the multi-current regulator; (E) is the circuit model for the current regulator; it generates the voltage source for the digital circuit, etc; (F) is the general platform of the multiple current sources.

FIG. 25 is the N-type fundamental current regulator; it is shown by the CR in bottom ground layer in FIG. 24B; (A) is the architecture of the N-type current regulator; (a) is the circuit and system of the N-type current regulator.

FIG. 26 is the cascade current regulator or the hierarchical current regulator shown in FIG. 24D; (A) is the system block diagram of the cascade current regulator or the hierarchical current regulator; (B) is the architecture of the cascade current regulator or the hierarchical current regulator; (C) is the circuit of the cascade current regulator or the hierarchical current regulator; (D1) is the design hierarchy as shown in conventional I/O: (D2) is the design hierarchy as shown in ground-bounce-less I/O; (E) is the noise-less Power and Ground P&G-Plan; (F) is the ground-bounce-less I/O; (G) is the analog/digital Programmable 1 LDO having the Brake, Accelerating and steeling, wheel functions; (H) is the alternative design of the analog/digital Programmable LDO with transimpedance cascade Amplifier.

FIG. 27 (A) is the general current regulator noise isolation platform; (B) is the conventional mixed signal chip; (C) is the CR wrapper of the current regulator noise isolation platform for the conventional mixed signal chip.

the conventional system integration; (A) is the partition of the chips; (B) is the A|D waveform of the ADC or DAC; (C) is the S|P waveform of the SERDES.

FIG. 29 is the system integration of the A|D, S|P with FPGA, DSP and Embedded Controller, etc; (A) is the chip partition with the system integration of the A|D, S|P with FPGA, DSP and Embedded Controller, etc; (B) is the platform of the system integration of the A|D, S|P with FPGA, DSP and Embedded Controller, etc.

FIG. 30 is the system integration of all the RF, AF, A|D with FPGA, DSP and Embedded Controller, etc; (A) is the system integration of all the A|D, S|P with FPGA, DSP and Embedded Controller, etc; (B) is the platform of the system integration of all the RF, AF, A|D, S|P with FPGA, DSP and Embedded Controller, etc.

FIG. 31 (A) is the Xtaless Clock circuit with the embedded Noise Isolation Technology; the embedded Noise Isolation Technology is implemented as shown in FIG. 30A; (B) the timing diagram of the Rippleless Fast lock FPLL; (C) is the block diagram of the Rippleless Fast lock FPLL; (D) is the comparison between the conventional PLL said the Rippleless Fast lock FPLL; (E1) is the wandering of oscillatory wave; (E2) is the normal oscillatory wave; (F1) is the spectra growth of idea oscillatory wave; (F2) is the spectra growth of the square wave; (F3) is the spectra growth due to the parametric inductance and capacitance: (G1) is the historical review of Xtaless Clock theory; (G2) is the route map of the Xtaless Clock development; (H) is the magnetic enhanced transimpedance amplifier TIA of the optical SerDes as shown in FIG. 1A; (I) is the schematic symbol of the magnetic enhanced transformer type inductors; (J) is the 3-dimensional view of the magnetic enhanced transformer type inductors; (K) the architecture and system of the Xtaless Clock having Bandgap Generator; (L1) is the linear curvature compensation for the conventional bandgap voltage generator; (L2) is the bandgap generator for bandgap voltage and bandgap current having (V_{BG}, I_{BG}) coupling; it has both the 1st and the 2nd curvature compensation; (M) is the system and architect of I_{BG} Bandgap Current generator; (N) is the system and architect of V_{BG} Bandgap Voltage generator; (O) is the system and architect for the wide frequency PLL/Clock generator; (P) is the system and architect of the RC type Xtaless Clock; (Q1) is the schematics of the N-type current buffer made of current mirror; (Q2) is the schematics of the P-type current buffer made of current mirror.

FIG. 32 is the performance comparison among the super-drive ADC, the conventional ADC and the comparator based ADC; (A) is the MDAC of the conventional pipeline ADC; (B) is the MDAC of the comparator based ADC; (C) is the MDAC of the super-drive ADC; (D) is the comparison of speed of the super-drive ADC with the conventional ADC and the comparator based ADC; (E) is the comparison of speed, accuracy and power of the super-drive ADC with the conventional ADC and the comparator based ADC; (F) is the schematics of the MDAC of the super-drive ADC where MDAC is multiplying digital-to-analog converter.

FIG. 33 is the ultra-fast dynamic power supply for the high power-efficiency high peak-average-ratio PAR Power Amplifier; (A) is the waveform of the high PAR signals; (B) is the RF system having the high power efficiency Power Amplifier; (C) is the circuit of the low power ultra-fast dynamic power supply the power amplifier having the high power efficiency and low power operation; (D) is the SMPS output stage of buck converter; (E) is the illustration of the fundament principle of the SMPS buck converter; (F) is the illustration of the operation of the Adaptive Optimum Constant On Time AOCOT Buck Converter with the hybrid combination of the voltage mode and current mode.

FIG. 34 is the operation characteristics of the Thin-Film Battery and/or Electrochromic EC window; (A) is the layered structure of the Thin-Film Battery and/or EC window; (B) is the electrical model of the Thin-Film Battery and/or EC window; (C) is the signal flow of the temperature compensated Thin-Film Battery and/or EC window; (D) is the optical hysteresis curve of Thin-Film Battery and/or EC window; (E) is the operation of the Thin-Film Battery and/or EC window.

FIG. 35 is the switching operation of Thin-Film Battery and/or EC window; (A) is the bipolar operation of the Thin-Film Battery and/or EC window; (B) is the unipolar operation of the Thin-Film Battery and/or EC window; (C) is the non-linear unipolar operation of the Thin-Film Battery and/or EC window; (D1) is the unipolar operation for the positive voltage; (D2) is the unipolar operation for the negative voltage.

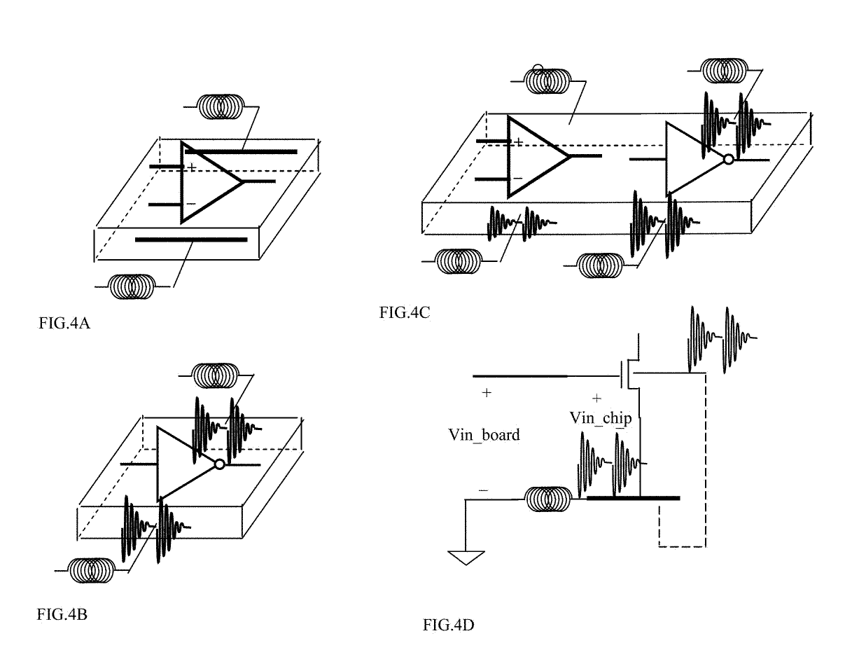

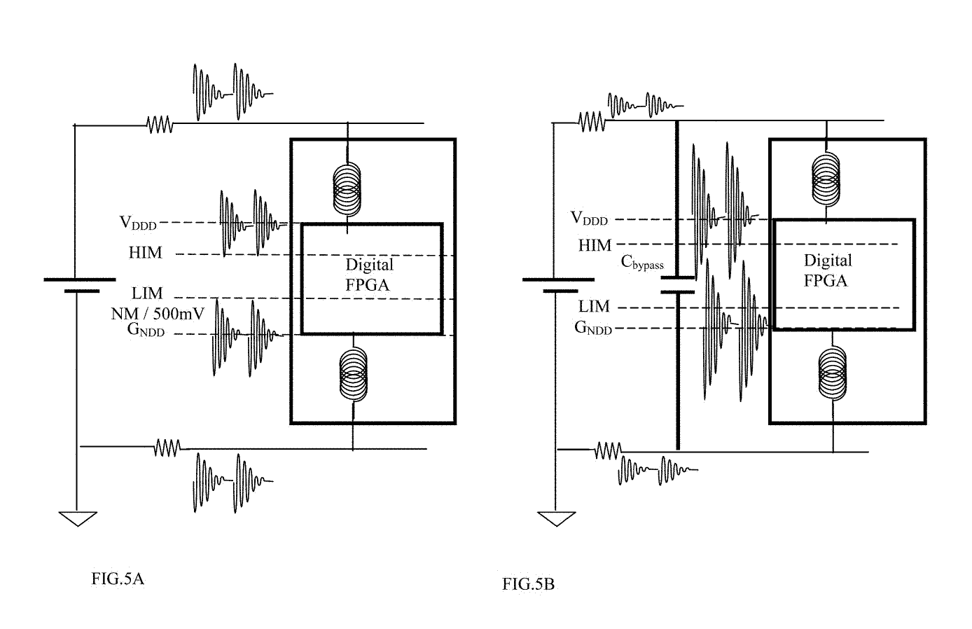

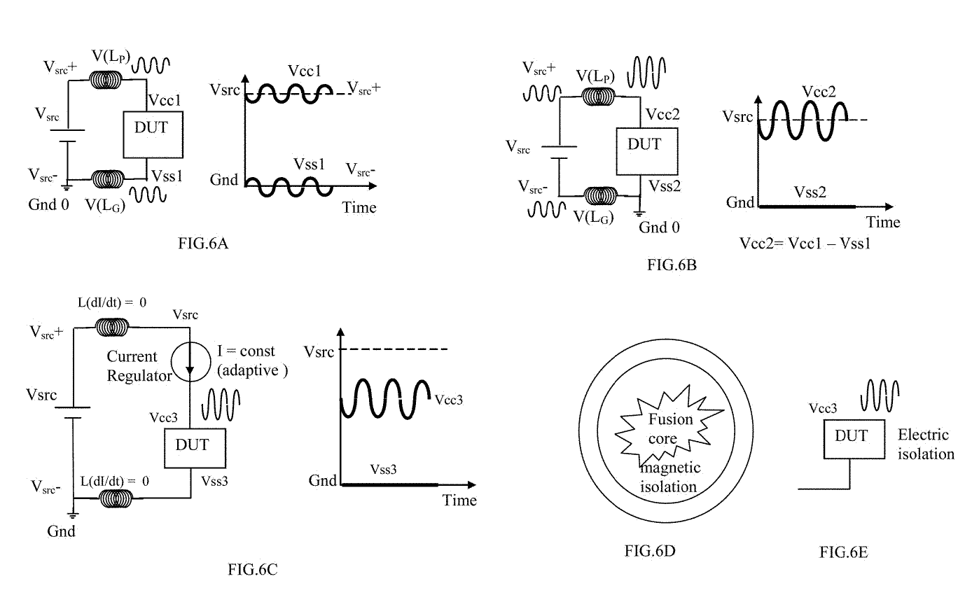

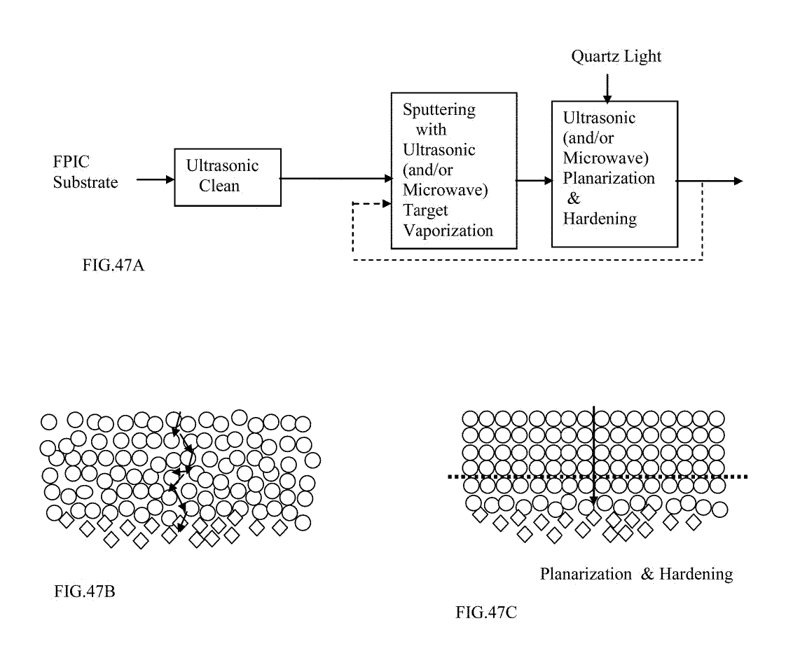

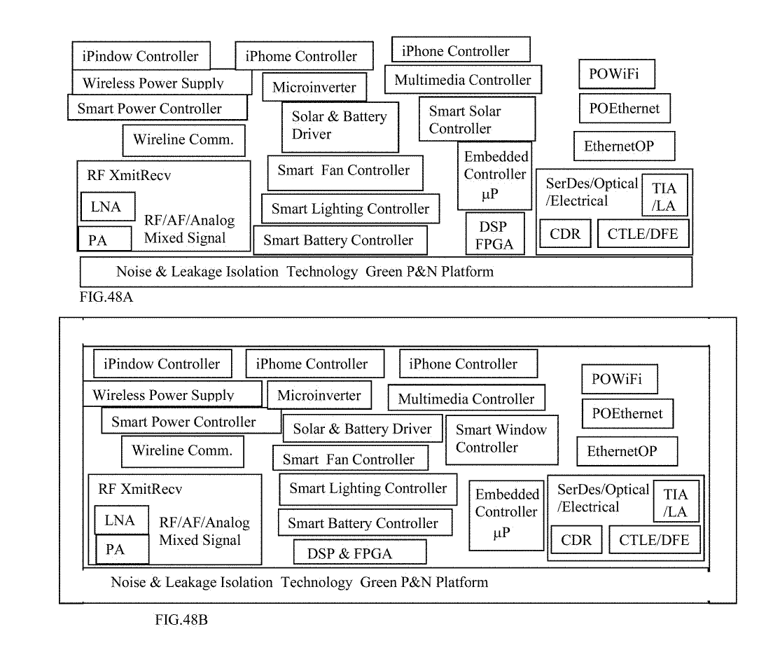

FIG. 6 is the Battery and/or EC window unipolar operation with the H-Bridge as shown in FIG. 35A and FIG. 35B; (A) is the unipolar operation of the region 1 charging up Battery and/or EC window; (B) is the unipolar operation of the region 2 hold Battery and/or EC window: (C) is the unipolar operation of the discharging Battery and/or EC window of region 3; (D) is the unipolar operation of the charging up Battery and or EC window of region 4; (E) is the unipolar operation of the hold Battery and/or EC window of region 5; (F) is the unipolar operation of the discharging Battery and/or EC window of region 6.

FIG. 37 is the H-Bridge operating on the power circuit to generate the EC window controller; (A1) is the analog buffer circuit with the H-Bridge; (A2) is the H-Bridge operating on the analog buffer to generate the voltage ramping circuit; (B1) is the buck converter circuit with the H-Bridge; (B2) is the H-Bridge operating on the capacitor load of the buck converter to generate the voltage ramping or current charging; (C1) is the buck converter circuit with the H-Bridge operating on the inductor and capacitor, etc.; (C2) is the H-Bridge operating on the inductor and capacitor load of the buck converter to generate the voltage ramping or current charging; (D1) is the buck converter circuit with the H-Bridge operating on the whole buck converter; (D2) is the H-Bridge operating on the buck converter to generate the voltage ramping or current charging.

FIG. 38 (A) is conventional wrong way to drive a big load with the unit-gain amplifier; (B1) is the correct way to drive a big load with analog buffer; (B2) is the Power Management Unit PMU having the Switch Mode Power Supply SMPS and Low Drop Voltage Regulator LDVR to supply power to the Battery type device such as battery, thin film battery and electrochromic glass devices, etc.; (B3) is the PMI. Power Management Unit having the Switch Mode Power Supply SMPS and Analog Buffer to supply power to the Battery typed device such as battery, thin film battery and electrochromic glass devices, etc.; (B4) is the PMU Power Management Unit having the Switch Mode Power Supply SMPS and LDO typed Analog Buffer to supply power to the Battery type device such as battery, thin film battery and electrochromic glass devices, etc.; (B5) is the block diagram of the Analog Buffer; (B6) is the detailed schematics of the Analog Buffer; (B7) is the SMPS, LDO typed Analog Buffer and H-Bridge; (B8) is the SMPS and H-Bridge with LDO typed Analog Buffer embedded in the H-Bridge; (B9) is the SMPS, LDO typed Analog Buffer and H-Bridge; (B10) is the analog buffer embedded in the H-Bridge; (B11) is the LDO typed analog buffer embedded in the H-Bridge for voltage control; (C1) is the block diagram of the Switch Mode Power Supply combining with low Drop Voltage Regulator (LDVR) type Analog Buffer to be the Rippleless battery charger and RF-Noiseless EC window controller; (C2) is the design platform for the Rippleless battery charger and RF-Noiseless battery charger and/or EC window controller; (D1) is the architecture of the H-Bridge buck converter typed battery charger and/or EC window controller; (D2) is the block diagram of the H-Bridge buck converter typed EC window controller; (D3) is the embedded battery charger and/or window controller; (D4) is the operation of the embedded battery charger and/or window controller; (E1) is the algorithm of the current-limited voltage ramping in charging up phase; (E2) is the algorithm of the current-limited voltage ramping in discharging phase; (F1) is the algorithm of the voltage-limited current charging in Charging up phase; (F2) is the algorithm of the voltage-limited current charging in discharging phase.

FIG. 39 is the super-performance battery, thin-film battery and EC window driver, etc. which can be developed to be the dedicated chip; (A) is the block diagram for the current-limited super-performance battery, thin-film battery and/or voltage-ramping EC window controller, etc.; (B) is the block diagram for the current-limited super-performance battery, thin-film battery and/or voltage-limited current charging EC window controller etc.; (C) is the bleaching/discharging process; (D) is the coloring/charging process; (E) is the complete super-performance battery, thin-film battery and/or CC window driver, etc.

FIG. 40 is the analysis of the analog buffer typed voltage ramping; (A) is the conventional power supply system; (B) is the power supply made of the analog buffer for voltage ramping operations of the battery charger and/or EC window controller; (C) is the waveform of the voltage ramping operation of the analog buffer; (D) is the analog buffer circuit for the voltage ramping battery charger and/or EC window controller.

FIG. 41 (A) is the triple-wire connection for long-distance connection to drive device; (B) is the wire architecture of the triple-wire connection for long distance connection to drive device.

FIG. 42 (A) is the energy injection into AC line; (B1) is the energy injection into AC line at the peak voltage of the AC line; (B2) is the energy injection into AC line at the valley voltage of the AC line.

FIG. 43 (A) is the energy extraction out of AC line: (B1) is the energy extraction cut of AC line at the peak voltage of the AC line; (B2) is the energy extraction out of AC line at the valley voltage of the AC line.

FIG. 44 (A) is the Rectifier-DC/DC-Regulator; (B) is the 5R Recycling Resonant Re-synchronous Rectifier Regulator with the controlled capacitors for frequency tuning; (C) is the timing diagram of the 5R; (D) is the tuning circuit for oscillation.

FIG. 45 is the fundamental principles of 5R Recycling Resonant Re-synchronous Rectifier Regulator; (A1) is the fundamental Oscillatory Resonator; (A2) is the equivalent fundamental Oscillatory Resonator having two different ends, V_{DC} and Ground; (A3) is the fundamental 5R Oscillatory Resonator which can he derived from FIG. 45A2; (A4) is the basic 5R Recycling Resonant Resynchronization Rectifying Regulator which can be derived from FIG. 45A3; (B1) is the Recycling Resonant mechanism for the switch of DC/DC converter; (B2) is the timing diagram of the Recycling Resonant mechanism for the switch of DC/DC converter; (C1) is the resonant oscillation of the LC resonator of the wireless power receiver; (C2) is the rectifier operation without the bias voltage; (C2B) is the rectifier operation with the bias voltage; (D1) is the resonant voltage, current and power of the ideal resonant circuit as shown in FIG. 45D2; (D2) is the ideal resonant circuit; (E1) is the resonant voltage, current and power of the resonant circuit having the diodes which emulates the rectifier circuit having H-bridge with Schottky diodes; (E2) is the resonant circuit having the diodes which emulates the rectifier circuit having H-bridge Schottky diodes; (E1) is the resonant voltage, current and power of the resonant circuit having the active MOS which emulates, the rectifier circuit having H-bridge with MOS; (F2) is the resonant circuit having MOS device which emulates the rectifier circuit having H-bridge with MOS; (G1) is the resonant voltage, current and power of the resonant circuit having the active MOS Which emulates the rectifier circuit having H-bridge with MOS and wave-shaper switching driver; (G2) is the resonant circuit having the MOS which emulates the rectifier circuit having H-bridge with MOS and wave-shaper switching driver; (H1) is the rectifier having nave-shaper switching driver as shown in FIG. 45H2; (H2) is the fundamental wave-shaper; (I1) is the rectifier having wave-shaper switching driver as shown in FIG. 45I2; (I2) is the mutual-latch enhanced wave-shaper; (J1) is the rectifier with multi-voltage Inductor-Free DC/DC converter; (J2) is the Waveform of the multi-voltage Inductor-Free Dc/Dc converter; (K) is the complete set of Recycling Resonant Resynchronization Rectifying Regulator 5R having the single power-conversion stage; (L1) is the complete schematics of the 5R having the Analog Signal Process/Power Factor Correction ASP/PFC wave shaper; (L2) is the alternative design of 5R circuit with Schottky Diodes; (L3) is the alternative design of 5R circuit with active MOS; (L4) is the alternative design of 5R circuit with Schottky Diodes; (L5) is the alternative design of 5R circuit with active MOS; (M) is the complete schematics of the 5R having the ASP/PFC wave shaper, SMPS and A&D programmable LDO; (N) is the functional block diagram of the 5R having ASP/PFC wave shaper, SMPS and A&D programmable LDO, (O) is the generic wave shaper of WS; (P) is the gate-activated switching buffer driver typed wave shaper; (Q) is the source-activated switch-energy recycling wave shaper WS2; (R) is the operational mechanism analysis of wave shaper.

FIG. 46 is the operation of the self-cleaning sputtering chamber; (A) is the characteristics of the gas reaction sputtering process; (B) is the detonating phenomena in the gas reaction sputtering chamber; (C) is the self-cleaning sputtering process; (D) is the block diagram of the system for the self-cleaning sputtering chamber.

FIG. 47 is the high performance EC window manufacturing process; (A) is the recursive/pipeline manufacturing process for the high performance EC window manufacturing process; (B) is the section view without the plating and hardening process; (C) is the section view with the plating and hardening process.

FIG. 48 is the Anlinx & Milinx & Zilinx Field Programmable System On Chip FSOC with the 23Less Green Technology for Smart Window; (A) is the platform of the Anlinx & Milinx & Zilinx FSOC having the 23Less Green Technology for Smart Window; (B) is the Anlinx & Milinx & Zilinx FSOC having the IP wrapper of Noise isolation Technology for 23Less Green Technology for Smart Window.

### DESCRIPTION AND OPERATION

The Green Technology is the reduction of energy consumption, noise generation and resource saving. The green technology integration system comprises an smart insulated Glass Unit. The smart Insulated Glass unit is referred as the Intelligent Graphic Unit IGU. The Intelligent Graphical Unit IGU further comprises the multimedia panel, electrochromic panel and the transparent solar cell panel, etc. The electrical energy generated by transparent Solar panel can provide to Smart Multimedia panel and Electrochromic panel, etc. Furthermore, the electrical energy generated by the green energy Smart Window can provide to the smart grid with wireline power line and provide to the mobile devices with wireless power supply, etc.

The green energy smart window is based on the W5RS Wireless Window 5R System. “5S” represents “Smart Solar Supply Silicon System”. “W5” represents “Wireless Wireline Weave Wishfull Window”. “5R” represents “Recycling Resonant Resynchronization Rectifying Regulator”. “W5RS” is the killer product applications of Silicon Valley and “5R” is the killer core IP technologies of Silicon Valley. Even for the WPC Qi and A4WP wireless power supply standards, the novel “single-stage 5R” can have the AC/DC power efficiency as high as 95% which is the highest record in the world. The green energy smart home of iPhome has the green energy smart window/iPindow. The green energy smart window is constituted of the multiple types of smart window. The multiple smart windows are such as multimedia window, transparent solar window and electrochromic window, etc. These panels are integrated to be one unit.

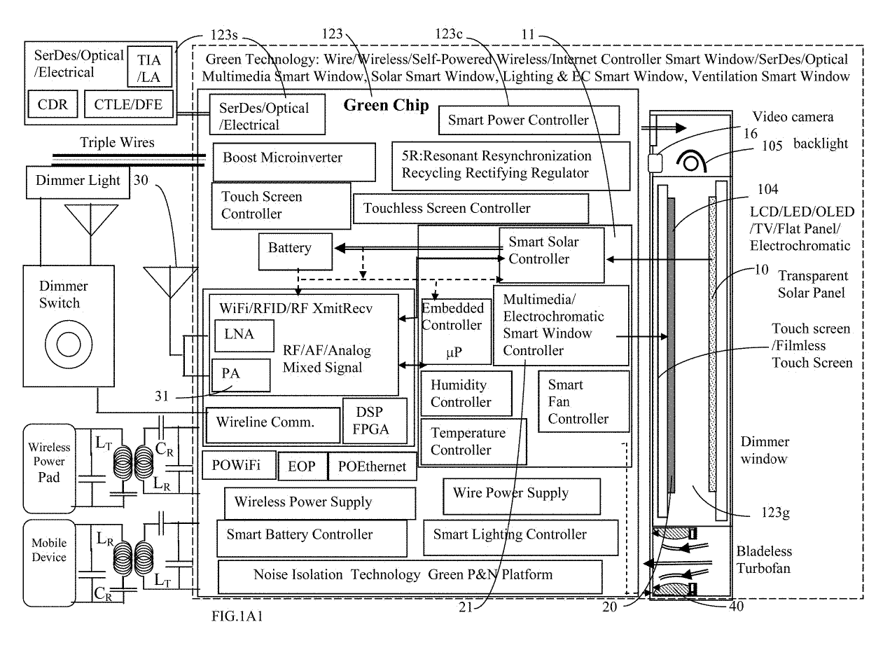

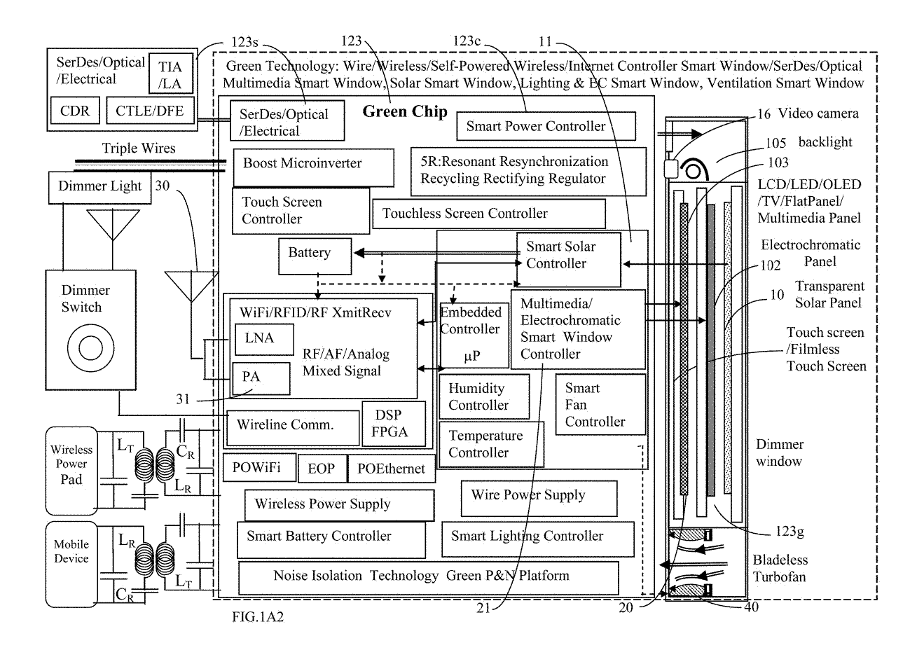

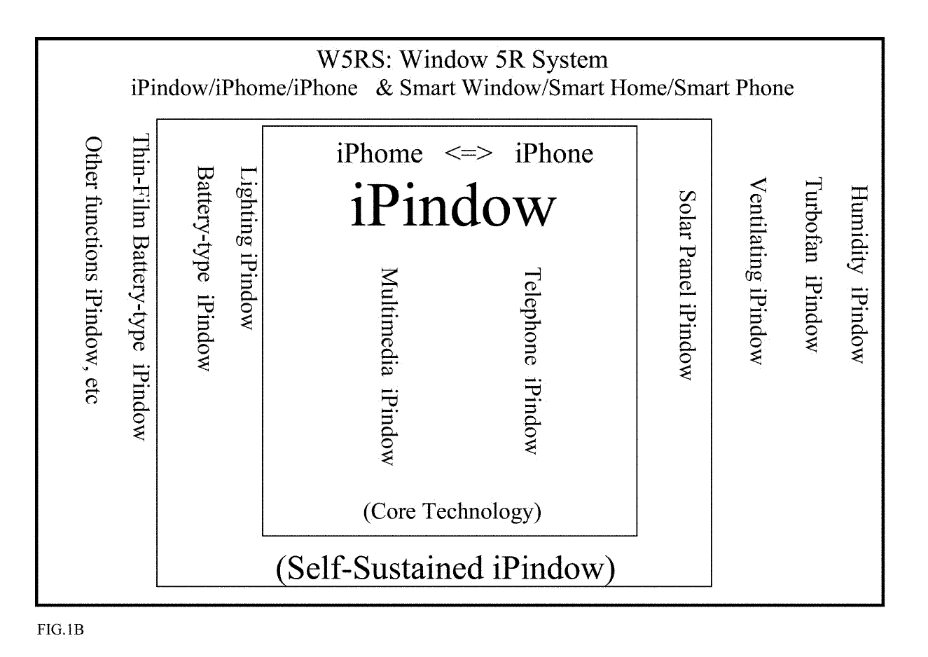

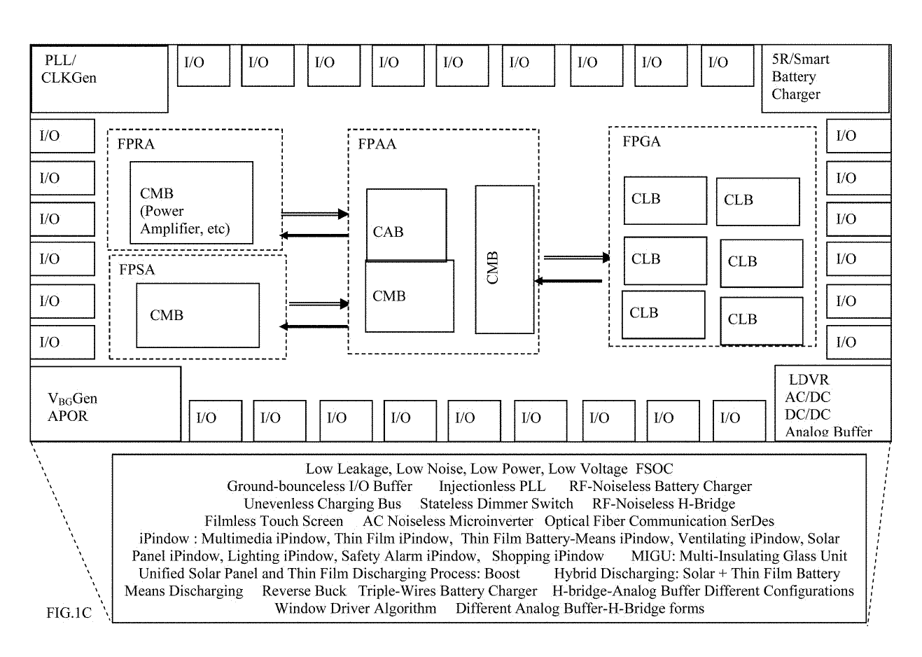

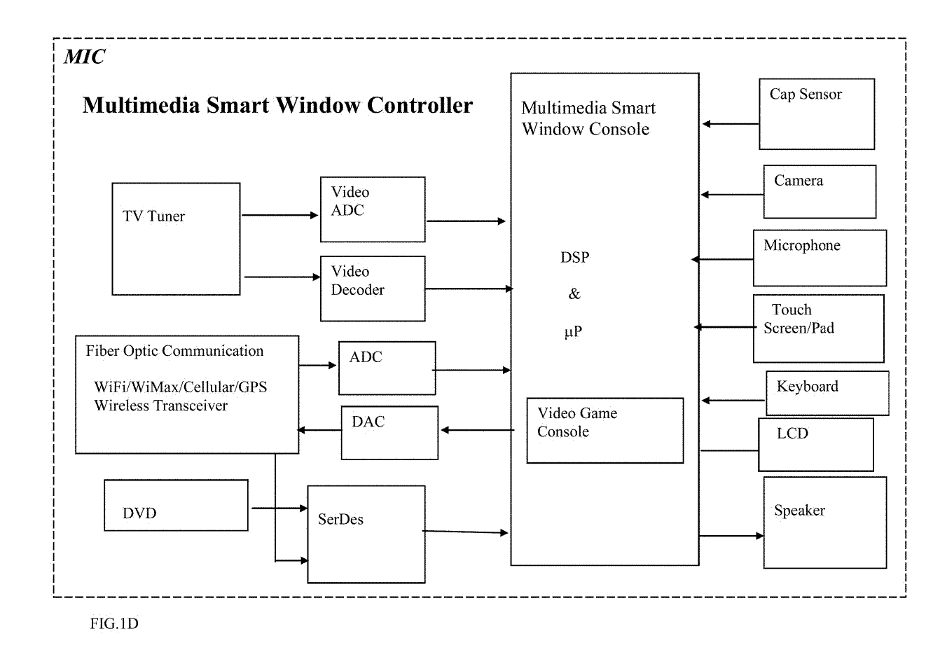

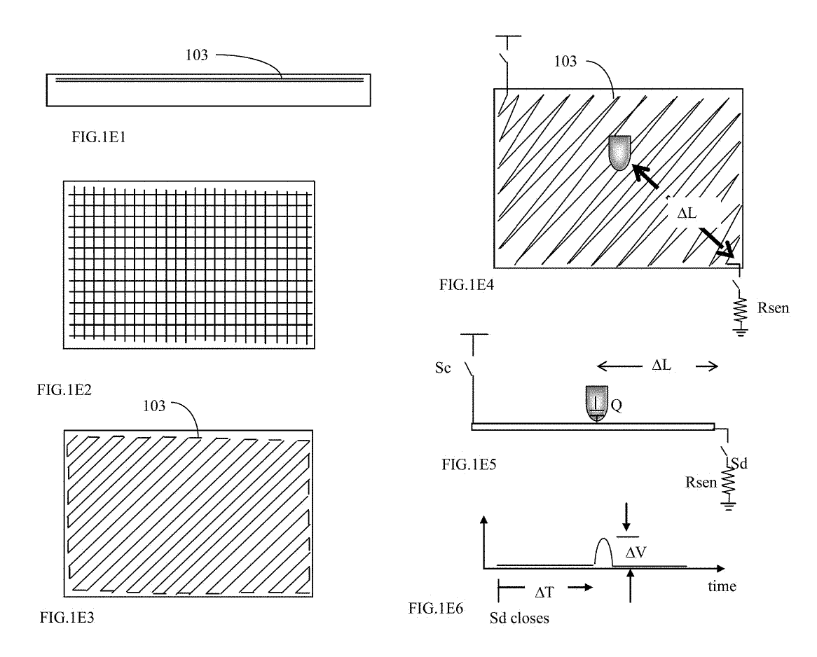

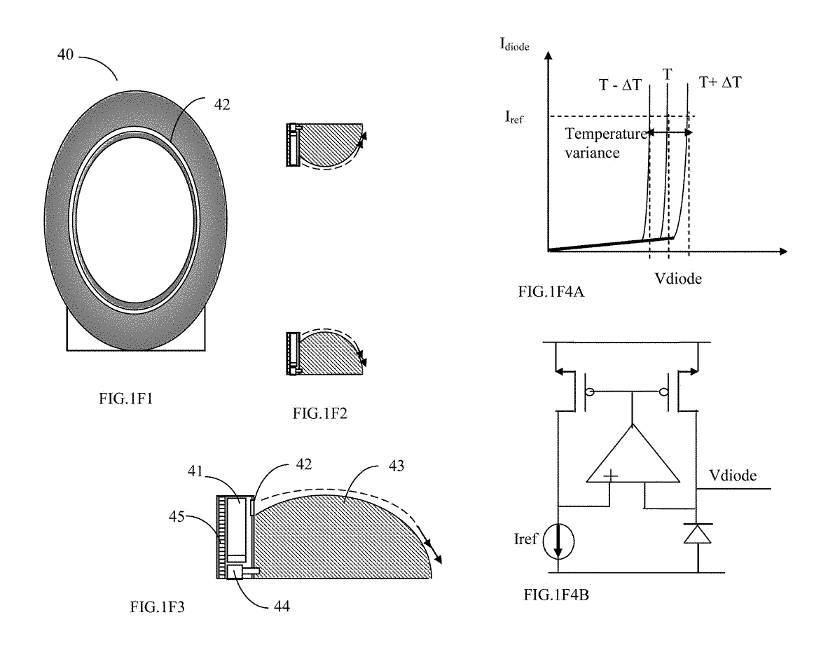

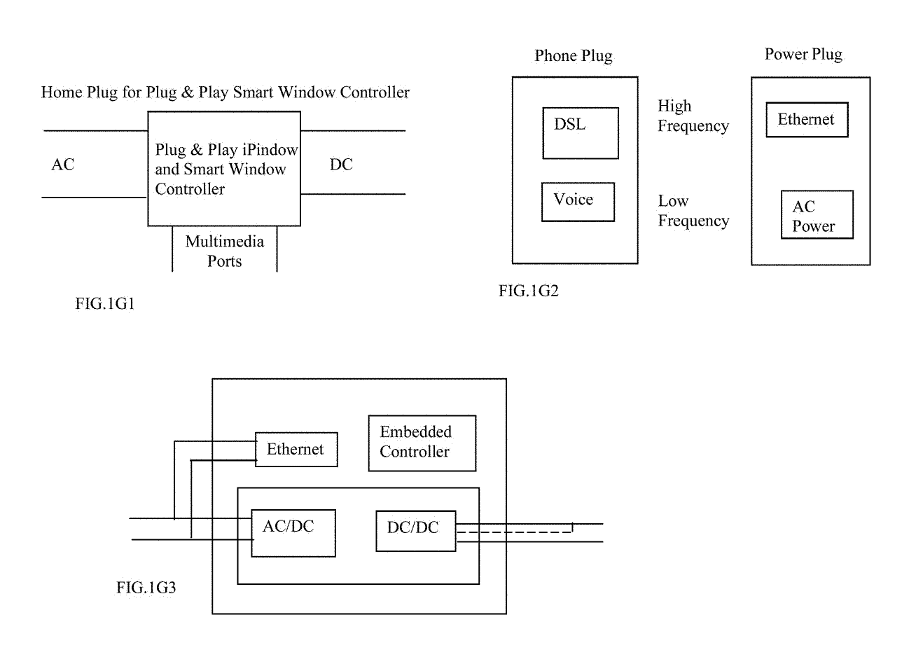

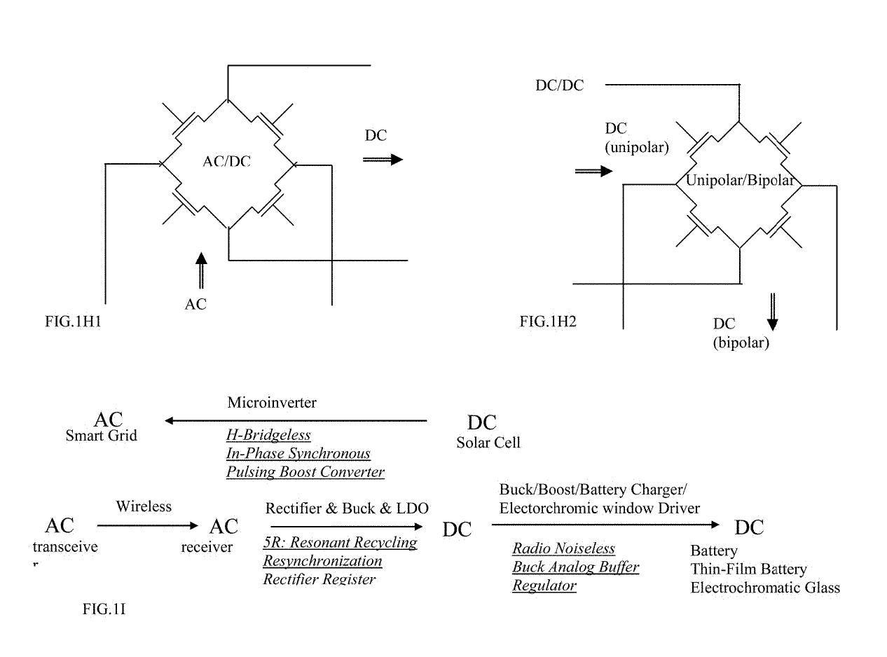

As shown in FIG. 1A and FIG. 1B, the green energy Wireless Window 5R System W5RS is constituted of Smart Multimedia Panel, Smart Electrochromic Panel and Smart Solar Panel, etc. The Smart Solar Panel harvests solar energy to be electric energy to provide power to the Smart Multimedia Panel and Smart Electrochromic Panel, etc. The electrical energy further provides to smart grid and mobile means. There are versatile arrangements for the multimedia window and Electrochromatic window. For the FIG. 1A the LCD/LED/OLED/TV/FlatPanel/Electrochromatic 140 can be (1) LCD/LED/OLED/TV/FlatPanel multimedia window only; or (2) Electrochromatic window only; or (3) LCD/LED/OLED/TV/FlatPanel/Electrochromatic multimedia window and Electrochromatic window. For the FIG. 1B, the interior panel is multimedia; the middle panel is Electrochromatic window; the exterior panel is the solar transparent window. The LED backlight 105 provides the backlight for the LCD flat panel multimedia window during the night.

The Transparent Solar Cell is transparent that exterior light passes through the Transparent Solar Cell and shines on the Electrochromic Panel and Multimedia Panel. The multimedia widow is the video display such as LCD/LED/TV/Flat Panel to provide interactive entertainment. The Solar Cell Panel harvests the solar energy to be electric energy to provide power to the Multimedia Panel and Electrochromic Panel. The electrical energy further provides to smart grid and mobile devices. Furthermore, the electrical energy can provide to mobile devices with wireless power.

The Smart Window of Smart Home is based on the 23Less Green Technology. The 23Less Green Technology for the Noiseless Field Programmable Integrated Circuit FSOC are Curtainless Window, Bladeless Turbo Fan, Brakeless Vechicle, Sawless LNA, Resistorless SMPS and Transceiver, Capless LDVR, Inductorless SMPS, Diodeless Random Number Generator, Xtaless Clock Generator, Clockless Switch Mode Power Supply, etc.

As shown in FIG. 1A and FIG. 1B, the green energy smart window 123 has the window 123g comprising multimedia LCD panel, transparent solar panel 10 and EC panel 20, etc. On the right side of FIG. 1A, it is the green energy smart window. On the left side of the FIG. 1A, there are the blocks which are implemented as the electronic system embedded in the frame of the green energy smart window. The Intelligent Graphical Unit IGU 123g has the multimedia LCD panel, transparent solar panel 10 and/or EC panel 20, etc. integrated to be one unit. The transparent solar panel 10 and the Switch Mode Power Supply SMPS 11 provide the solar power energy to the green energy smart window 123 and the smart fan. In the smart window, there are many smart controllers such as Smart Home controller, smart lighting controller, smart solar controller, smart battery controller, smart power controller and smart fan controller, etc. As shown in FIG. 1C, FIG. 48A and FIG. 48B, Anlinx & Zilinx & Zilinx' Field-System-On-Chip FSOC will integrate all the smart controllers on the same platform to be one single chip.

The transparent Solar panel provides the electricity to the Multimedia panel and Electrochromic panel, etc to be “self-contained Intelligent Graphical Unit IGU”. All the smart controllers will be embedded in the frame of the Intelligent Graphical Unit IGU. As shown in FIG. 1F1, the Intelligent Graphical Unit IGU further comprises the smart fan and the smart fan controller. In the smart fan, there are the multiple functional modules of the bladeless turbofan, air conditioner, the humidity/de-humidity and air-filter, etc. The bladeless turbine circulates the air for air conditioning and ventilation. In the winter, the ceiling warm air will be sucked in to the channel inside the Intelligent Graphical Unit IGU then be blown out at the floor by the blades of turbofan.

The green energy Wireless Window 5R System W5RS is constituted of Multimedia Panel, Electrochromic Panel and Transparent Solar Cell Panel. The Multimedia Panel, Electrochromic Panel and Transparent Solar Cell Panel are enclosed in the isolated glass unit. The isolated glass unit further comprises exterior glass and interior glass. The exterior glass faces the outside of building. The interior glass faces the inside of room. The Transparent Solar Cell Panel is attached on the exterior glass in the isolated glass unit. The Multimedia Window is attached on the interior glass in the isolated glass unit. As shown in FIG. 1M1, the transparent solar panel is attached to the exterior transparent support such as glass of flexible plastics. As shown in FIG. 1M2, LCD/LED/OLED Flat Panel/etc and Electrochromic are attached to the exterior transparent support such as glass or flexible plastics. As shown in FIG. 1N1, the air 402, 403 doesn't flow through the channel between two glasses. The bladeless turbofan 40 is located at the corner of IGU. The IGU is completely isolated and filled with the clean inert gas. The IGU is to use the isolation of double window to keep the room temperature to save the energy. It is impossible to clean up the dust inside the IGU. Therefore, the IGU is completely isolated and filled with the inert gas. The air will not flow through the channel between the two glasses of the window. As shown in FIG. 1N2, for the low frequency wireless charging system, the wireless charge uses the current loop 412, 413 embeded in the Frame of IGU. The magnetic field 422 and 423 oscillates to charge the wireless charger. As shown in FIG. 1N3, for the high frequency charging system, the wireless charge uses the Antenna embeded in the Frame of IGU. The chip 432 drives the antenna 433 to emit the EM wave to charge the wireless charger.

FIG. 1B is the architecture of Smart Window for the Smart Home. The Smart Window of Smart Home includes the multimedia iPindow and Telephone iPindow to be the core. The self-sustained iPindow is constituted of the core of iPindow, Solar Panel iPindow, Battery-type iPindow and Lighting iPindow, etc. The Smart Window of Smart Home further comprises the options of Ventilating iPindow, Turbofan iPindow, Humidity iPindow, Thin-Film Battery iPindow and other functions iPindow etc.

The noise isolation is a platform serving as wrapper to integrate versatile combinations of ASIC, FPGA, ADC, DSP, microprocessor, RF/AF/Analog circuit and digital circuit to be FSOC. FIG. 1C is the Field-System-On-Chip FSOC for the Smart Window of Smart Home. Furthermore, the FSOC has the versatile circuits of Ground-bounce-less I/O Buffer, Injectionless PLL, RF-Noiseless Battery Charger, Uneven-less Charging Bus, Stateless Dimmer Switch, RF Noiseless H-Bridge, Filmless Touch Screen, AC Noiseless Micro-inverter, iPindow, Multimedia iPindow, Thin-Film iPindow, Thin-Film Battery-Means iPindow, Ventilating iPindow, Solar Panel iPindow, Lighting iPindow, Safety Alarm iPindow, Shopping iPindow, MIGU: Multi-Insulating Glass Unit, Unified Solar Panel, Thin Film, Discharging Process with Boost, Hybrid Discharging for Solar and Thin Film Battery, Discharging with Reverse Buck, Triple-Wires Battery Charger, H-bridge-Analog Buffer Different Configurations, Low Leakage, Low Noise, Low Power, Low Voltage Window Driver Algorithm and Different Analog, Buffer-H-Bridge forms, etc. These versatile circuits will be disclosed in the hallowing description in details.

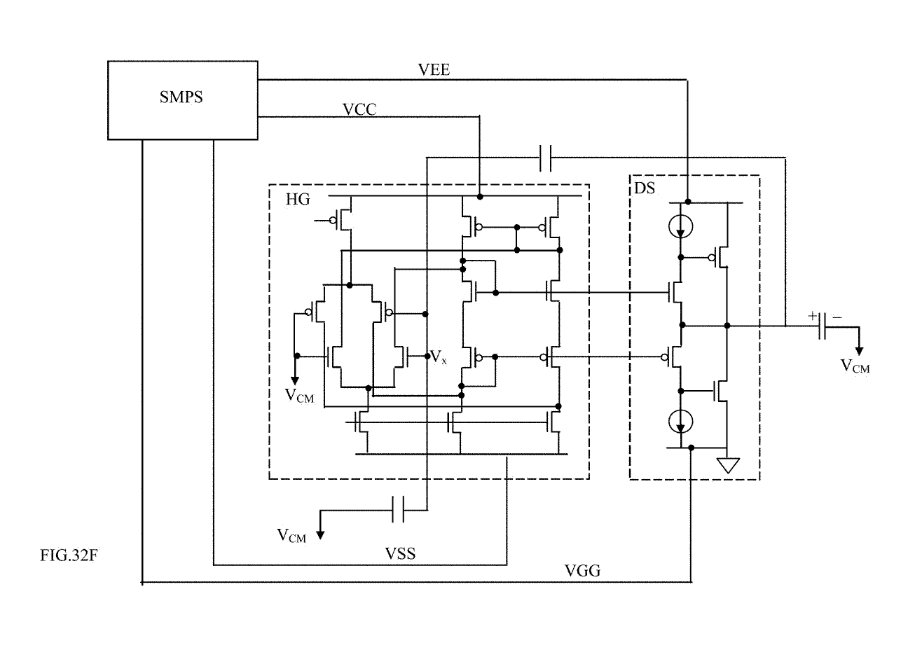

A green energy Wireless Window 5R System W5RS further comprises microcomputers to control Smart Multimedia Window/Panel. The microcomputer further comprising touching sensor, video camera, etc to have both touch and touchless user interactive with Multimedia Window. FIG. 1D is the multimedia Window controller having the computer/communication/commander function for the multimedia Window. As shown in FIG. 32C, the multimedia Smart Window controller integrated system computes the pipeline buffer ADC. The pipeline baiter ADC comprises high gain operational amplifier stage and dynamic switching output stage.

There is Cap Sensor for the touch screen of LCD fiat panel. The camera is for the touchless LCD panel application and Video phone, etc. The Touch screen pad is for the touch screen of the multimedia LCD panel of multimedia Smart Window. FIG. 1E1 is the cross-section of the filmless LCD panel. The conducting layer 103 is embedded in the glass type media. FIG. 1E2 is the orthogonal two layers touch screen. FIG. 1E3 is the single layer touch screen. FIG. 1E4 shows the finger touching on the screen having a single conducting layer. FIG. 1E5 shows the circuit of touch screen. FIG. 1E6 shows the signal waveform propagating on the conducting layer.

A green technology IGU integrated system comprises smart fans. The smart fan comprises bladeless turbofan. The bladeless turbofan circulates the humidity-controlled and temperature-controlled air for air conditioning and ventilation. As shown in FIG. 1F1, it is the bladeless turbofan. The blade of the turbofan is hidden inside the ring frame and cannot be reached from outside that it is named as the bladeless. FIG. 1F2 shows the cross-section of the bladeless turbofan. As shown in FIG. 1F3, the gear 44 of the motor drives the blade 41 of the turbofan. The air is sucked to flow through the humidify/de-humidify/air-filter 41 and flows out of the slot 42. As shown in FIG. 1F1 and FIG. 1F2, the expanded cone 43 makes the air pressure to drop to suck more air to flow through the center of the cone. The air-multiplying factor is about 16. One volume of air flows through the blade, there are sixteen times air volume flows out the cone. As shown in FIG. 1A, the warm air at the ceiling is sucked into the side channels of the IGU and is blown out at the, floor. It keeps the fresh air circulating in the room that a lot of energy is saved.

The Green Energy Smart Window 5R System W5RS comprises smart fans. The smart fan further comprises the bladeless turbofan. The bladeless turbofan circulates air for air conditioning. The turbofan needs the temperature sensor to detect the air temperature and the overheat of the motor, etc. As shown in FIG. 1F4A, the diode characteristic curve varies over temperature that we can use this diode characteristic curve to detect the temperature. As shown in FIG. 1F4B, the temperature sensor circuit can get the temperature as follow's.

I_{ref}=Iₒe^{(Vdiode/VT)} where V_{T}=kT/q

ln(I_{ref}/Iₒ)=V_{diode}/(kT/q)=>T=V_{diode/[(}k/q)ln(_{ref}/Iₒ)]

As shown in FIG. 1G1, it is the Home Plug for Plug & Play Smart Battery Charger and/or Window Controller. There are AC port input, the DC port and the multimedia port. As shown in FIG. 1G2, the power plug is similar to the phone plug having the high frequency and low frequency port. As shown in FIG. 1G3, the Home Plug for Plug & Play Smart Battery Charger and/or Window Controller is constituted of the Ethernet, AC/DC converter, DC/DC converter and embedded controller, etc.

The Field-Programmable-System-On-Chip FPSOC needs to unify the different circuits to have the platform for the versatile different applications. For H-Bridge, the operation of Diode-Bridge is continuous and analog. However, the operation of MOS-Bridge is Impulse/digital. To unify the circuit, as shown in FIG. 1H1, the H-Bridge makes the conversion between the AC and DC. The rectifier, inverter and micro-inverter use the AC/DC conversion. As shown in FIG. 1H2, the H-Bridge makes the conversion between the Unipolar-DC/Bipolar-DC. The Battery Charger and EC-Window Driver use the Unipolar-DC/Bipolar-DC conversion. Therefore, the H-Bridge is unified to be the two-way “Bipolar-AC/Unipolar-DC” for rectifier, inverter, micro-inverter, battery charger and EC-window driver, etc. As shown in FIG. 1H1, FIG. 45H1 and FIG. 45G1, for the H-Bridge, the AC/DC operation is “DIPFC: Dignal/Impulse PFC Phase-Frequency Control”. With the wave-shaper of the “DIPFC: Digital/Impulse PFC Phase-Frequency Control”, the sinusoidal oscillation of LC resonator is converted to be the digital switch signal.

FIG. 11 shows the global map of the power conversions among different power supplies. The conventional way to convert the solar cell DC power to smart grid AC power conversion is to use micro-.inverter. As shown M FIG. 1J2 and FIG. 42A, our innovation is to use the “H-Bridgeless In-Phase Synchronous Pulsing Boost Converter” to convert the solar cell DC power to smart grid AC power.

The conventional way for the AC power converting to DC power is going through “three stages” power conversion of “rectifier, buck converter and LDO”. As shown in FIG. 1L1 and FIG. 45M, our innovation is “single stage” power conversion with “5R: Resonant Recycling Resynchronization Rectifier Register”. With the wave-shaper, the “Current-Voltage out-of-phase” is converted to the “Current-Voltage in-phase” recycling operation to have switch-loss-less rectifier operation.

As shown in FIG. 1J1, it shows the block diagrams of the energy injected into another power supply and the energy extracted from another power supply. As shown in FIG. 1J2, the energy is injected into another power supply with triggering impulse action. As shown in FIG. 1J3 the energy is extracted from another power supply. As shown in FIG. 1J4, the impulse/triggering impulse action is constituted of the Pre-Building-Up energy-inductor and the triggering MOS. The instant-Impulse is the instantaneously turn-off of the MOS switch to trigger the energy injection.

FIG. 1K shows the fundamental principle of the recycling resonant oscillator to reduce the switch loss. To reduce the on-resistance of MOS switch, the switch gate voltage must be in the digital switch mode signal. The key issue is to convert the analog sinusoidal waveform to be the digital switch form with the wave-shaping techniques. As shown in FIG. 1L1, the A5RS is constituted of the wireless transmitter 5RT and Wireless Receiver 5R as shown in FIG. 44A and FIG. 44B. Referring to FIG. 1L1, FIG. 45G1, FIG. 45G2 and FIG. 45M, the wave-shaper in 5R converts the analog sinusoidal wave form to be the digital switch form.

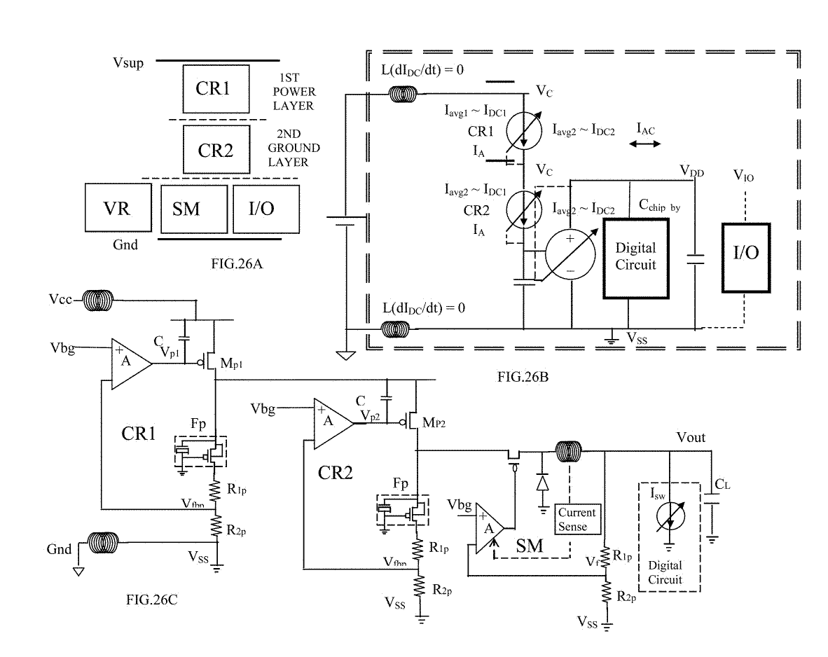

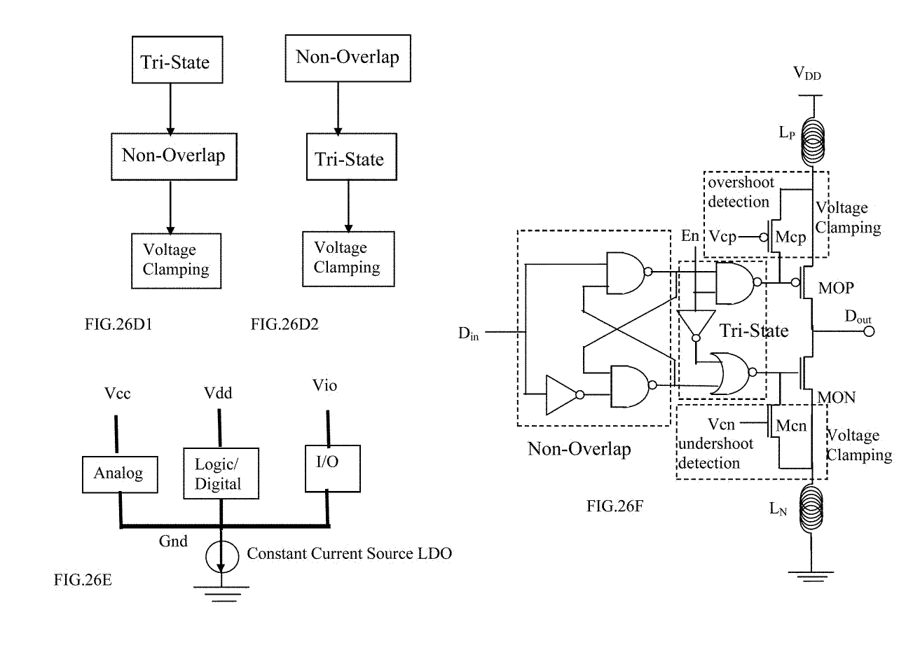

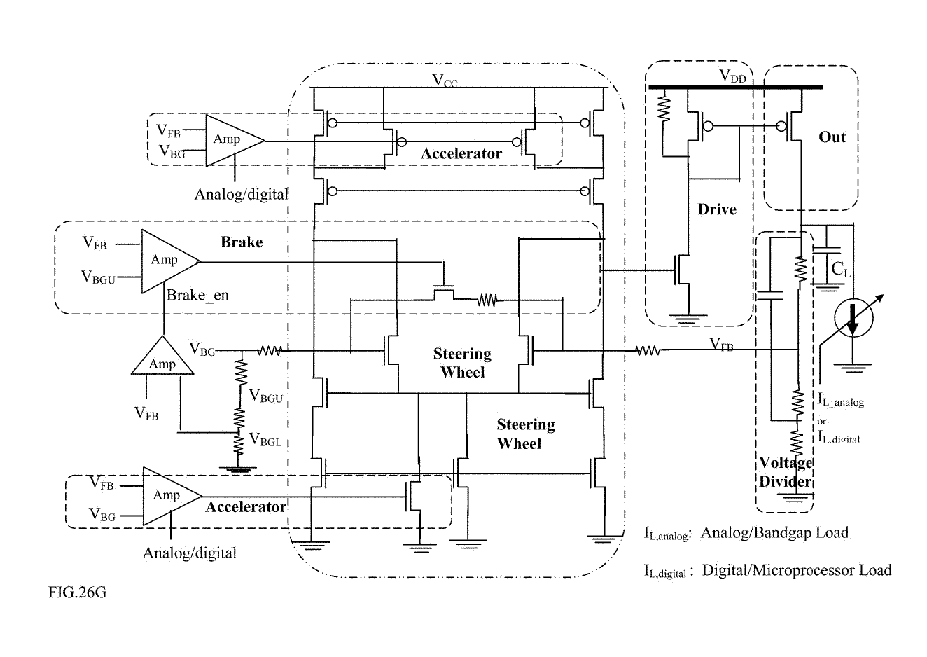

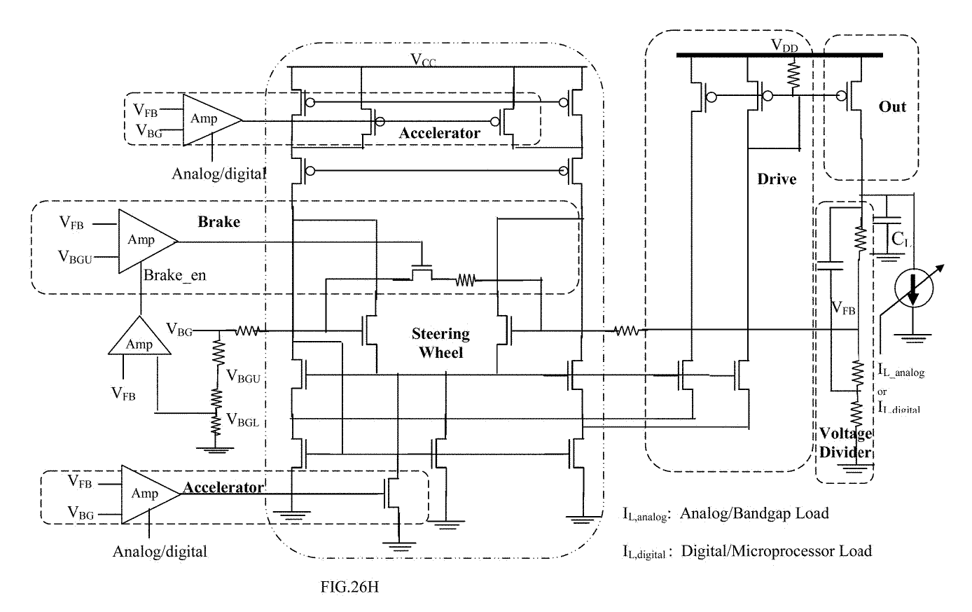

Referring to FIG. 1L1 and FIG. 26G, the Wireless Receiver 5R thither has the programmable Analog/Digital LDOs be able to be programmed to be Analog LDO and Digital LDO. For example, the Analog LDO supplies the 1.8V analog power of constant current to the Bandgap and analog circuits, etc; the Digital LDO supplies, the 1.2V digital power, with pulsing current load to the microcomputer and digital circuit, etc. FIG. 1L4 shows the comparison between the analog LDO and digital LDO.

Referring to FIG. 26G and FIG. 26H, a Wireless Window 5R System W5RS comprises a programmable LDO which further comprises programmable analog LDO/digital LDO mechanism, brake mechanism, accelerator mechanism and steering-wheel mechanism. Referring to FIG. 26G and FIG. 26H, the programmable analog LDO/digital LDO is programmed to be high-gain for analog LDO and high-bandwidth for digital LDO. The brake mechanism reduces the difference of the differential input voltages of said steering-wheel mechanism to eliminate the overshoot during the POS Power-On-Sequence. Due to the requirement of ripple reduction of the output voltage caused by digital loading of μP, as shown in FIG. 26G and FIG. 26H, the accelerator mechanism is orthogonal-conjugate with the steering-wheel mechanism of error amplifier to have the fast reaction to ripple.

There are the wire-line connection and/or the wireless connection for the dimmer/bi-state/multi-state smart window and light. They integrate the light, ventilation and smart window to be building management system. There are wireline and wireless connections and the switching powers for the battery charger and smart window. The wireless circuit is sensitive to noise. However, the switching power generates a lot of noise. To be the consumer product, the cost must be low. The switching power circuit, digital circuit, analog circuit and wireless circuit, etc. are integrated together to be a single Integrated Chip. To enable tile Green Energy Smart Window, we must have the Noise Isolation Technology NIT first.

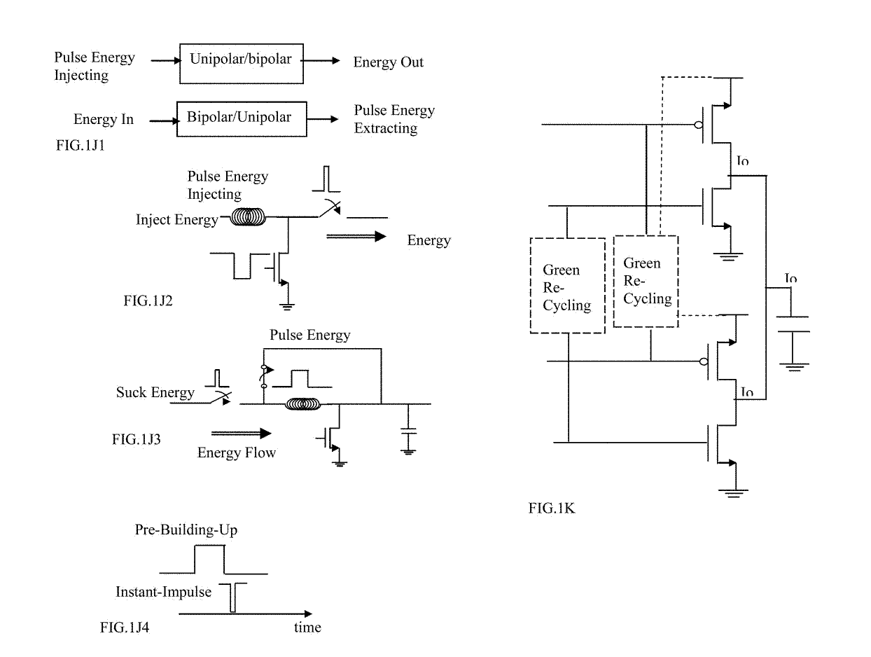

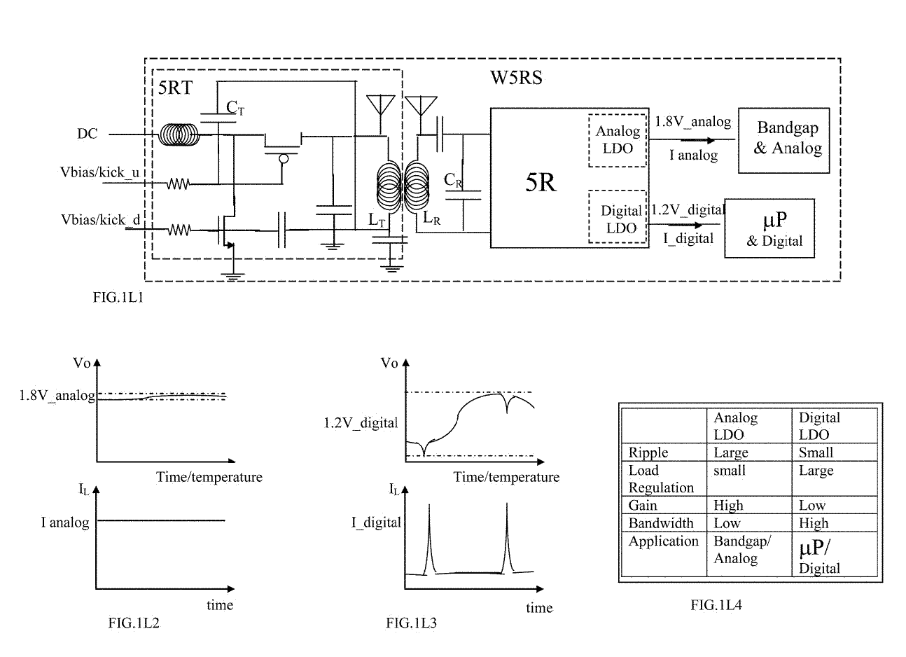

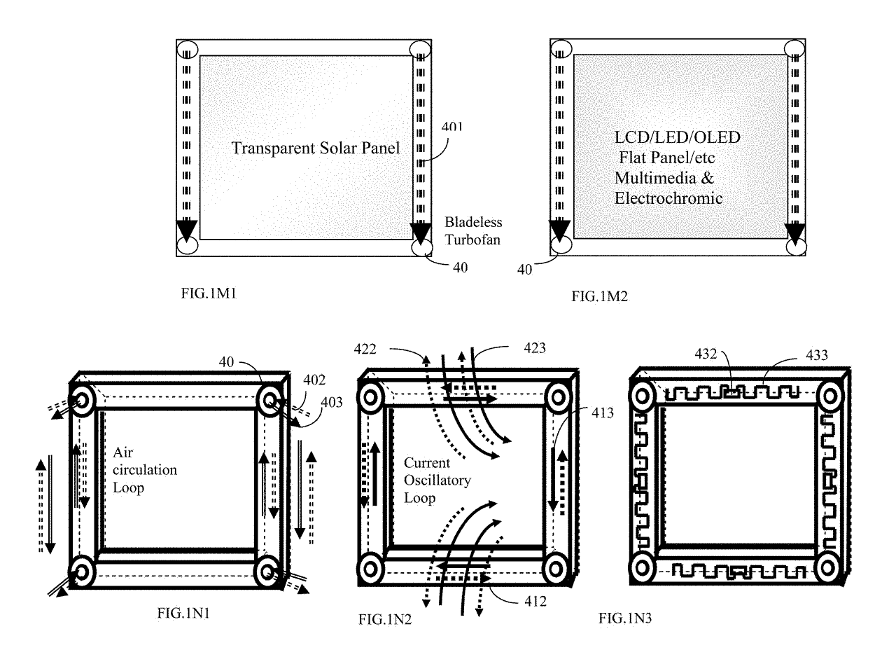

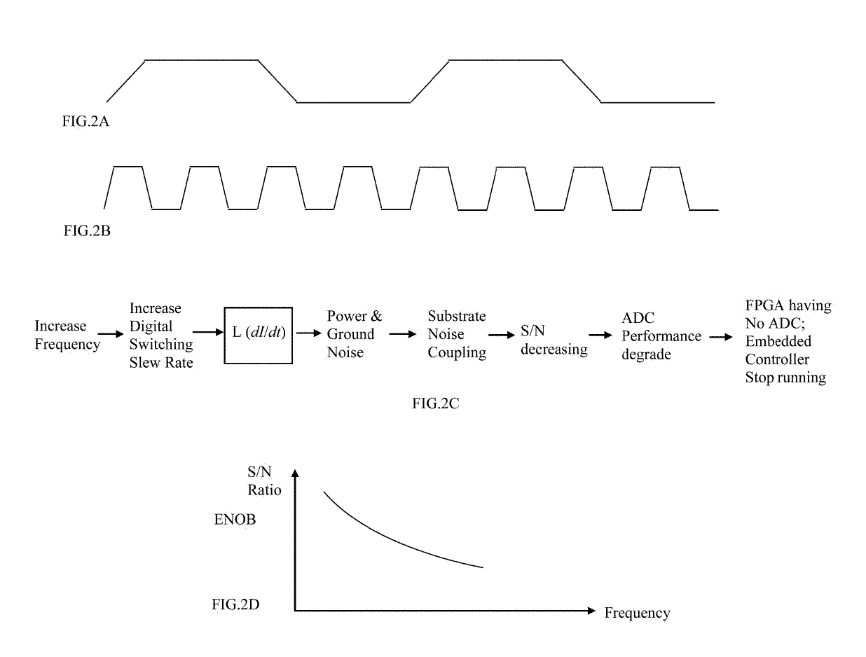

A Green Energy Smart Window integration system has noise isolation. The noise isolation has a plural of current regulators to regulate the current flowing through a plural of connections of pins and bonding wires, etc. The connections have parasitic inductors. The current regulator regulates the current flowing through the parasitic inductors to reduce noise generated by the parasitic inductor. As shown in FIG. 2A, FIG. 2B and FIG. 2C, the generated noise and system degraded as the frequency increases. As shown in FIG. 2A, the switching frequency is low that the slopes of the rising edges and failing edges cam be slow. As shown in FIG. 2B, the switching frequency is high that the slopes of the rising edges and falling edges are fast. As shown in FIG. 2C, as the frequency increase, the slew rate of the digital switching increases. The switching noise of L(dI/df) of the parasitic inductor increases. It induces the power and wound noises. The noise injected into the substrate becomes the coupling substrate noise.

The SINAD is the ratio of the signal (the fundamental) to the sum of all distortion and noise. As shown in FIG. 4D and FIG. 2C, the substrate coupling noise injected into the circuit and system causes the degradation of the circuit and system performance. The signal to noise ratio S/N and SINAD decrease. The Effective Number of Bits ENOB decreases where

EMOB=(SINAD−1.76)/6.02

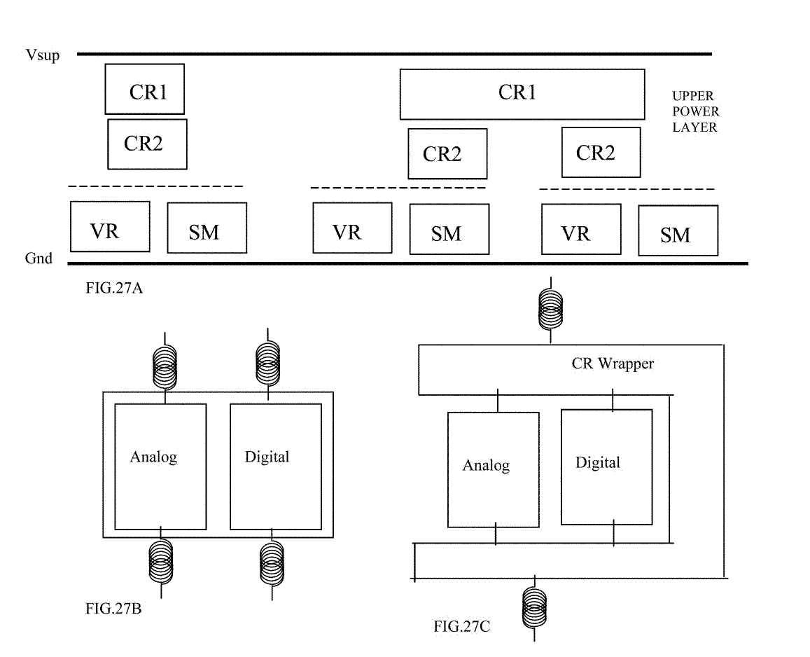

As shown in FIG. 27B and FIG. 2D, decrement of the ADC is unacceptable. Therefore, the ADC and DAC cannot be integrated on the FPGA.

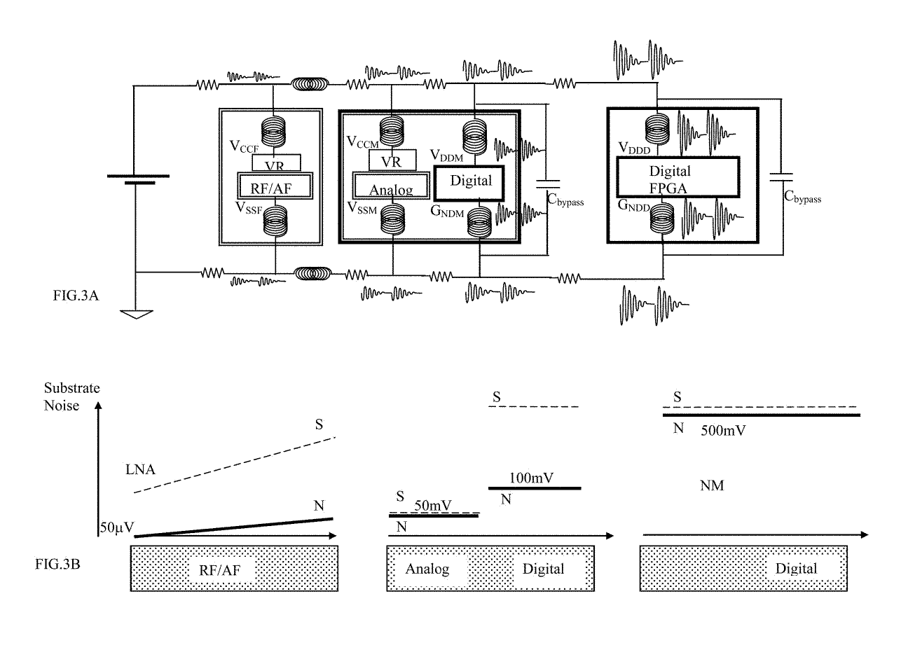

To solve the noise in system, the conventional, system is partitioned as shown in FIG. 3A. The system is partitioned to be RF/AF chip, Mixed Signal Chip and Digital/FPGA chip. The parametric inductance of the package generates a lot oscillation in power and ground. To minimize the noise dumped on the board, there is the bypass capacitor C_{bypass}. However, as shown in FIG. 5A and FIG. 5B, this bypass capacitor C_{bypass} makes the on-chip oscillatory noises even worse. All the switching noise is dumped on the board. For the analog chip and RF chip, there is the on board inductor/choke to block the digital switching noise from the noise contamination.

As shown in FIG. 3B, to keep the circuit performance requirement, the substrate noise for the RF/AF chip, Mixed Signal Chip and Digital/FPGA chip are bounded at separate levels. The RF/AF signal and noise will be amplified along the chain. The noise level at the front end of LNA is very small. For the mixed signal, the substrate noise of the ADC signal has to be small. After the analog signal is converted to be the digital signal, the substrate noise cart be missed to be the noise margin. The digital circuit has large substrate noise which exceeds the allowance of the substrate noise of the ADC. It makes the ADC not be able to be integrated with the FPGA.

As shown in FIG. 4A, it is the analog circuit in the AF/RF chip. There is no switching noise in the power and ground. As shown in FIG. 4B, it is the digital circuit in the digital/FPGA chip. There is switching noise in the power and ground. As shown in FIG. 4C, it is the mixed signal chip switching noise injecting into the substrate to be the coupled substrate noise.

FIG. 4D shows how the substrate noises coupling into the circuit destroying the circuit performance. First, the on-board signal Vin_board will be much different the on-chip Vin_chip.

Vin_board=Vin_chip+N_substrate

Vin_chip=Vin_board−N_substrate

It means the substrate noise N_substrate becomes the circuit input signal at the front gate. Second, the substrate noise N_substrate applies on the substrate of the input MOS. It is the back gate effect. Due to the dual substrate noise effect of the front gate and back gate, the RF circuit cannot have the digital switching circuit to be integrated into the RF/AF chip.

Regarding to the substrate noise, there are a lot of misunderstanding and, mistakes in the system design. As shown in FIG. 5A, the digital circuit or FPGA generates the switching current. As the switching current flows through the parametric inductor, the noise oscillations are generated. The switching noise is dumped on the board and it contaminates the board.

As the board shrinks, the assumption of the board having the infinite large capacitance is no more valid. The traditional way to dump the noise on the board is no more allowed. To reduce the noise dumped on the board, as shown in FIG. 5B, there is the bypass capacitor C_{bypass} connecting between the power and ground. However, due to LC oscillation, this bypass capacitor C_{bypass} makes the chip substrate noise even larger. Comparing FIG. 5B with FIG. 5A, it shows the substrate noise oscillation of chip having the bypass capacitor C_{bypass} is much larger than the substrate noise of chip having no bypass capacitor C_{bypass}. To reduce the substrate noise, it had better not to add the bypass capacitor C_{bypass}. It completely reverses the conventional thinking of the design practice.

Due to the wrong concepts about the substrate noise, the substrate noise problem becomes the mysterious and nobody can solve it. Actually, the substrate noise is the essential problem of the planarization of the chip system integration. With the multi-disciplinary training, now the grand master Ming recognized the fundamental problem and solved this problem. The Noise Isolation Technology is introduced as follows.

As shown in FIG. 6A and FIG. 18D, the Device Under Test DUT has the digital switch. The power and ground are oscillatory in the conjugate phases. The Vsrc+ node voltage is Vsrc and the Vsrc− is 0V. As the P-device and N-device of the digital circuit are both on, there is the crowbar current. At the same time, the parametric inductor tries to supply more current for the crowbar current. The continuous flows of the inductor will charge up the Vcc1 power node and discharge the Vss1 ground node. It causes the Vcc1 to go upward and the ground to go downward. The cycle of the power ground oscillation will be the doubling frequency of the switching frequency of the digital circuit. The oscillation of the power and ground are in conjugate 180° out of phase.

The substrate noise can be zero with the proper design of circuit. To illustrate the zero substrate noise concept, two different zero substrate noise conditions are introduced fin comparison. FIG. 6B is virtual mathematical model. FIG. 6C is the real world Noise Isolation Technology.

As shown in FIG. 6B, the Vss2 has the 0V. Vsrc− has the Vss1 voltage. The Vsrc+=Vss1+Vsrc that the Vss+ curve is phase of Vss−. For the two cases of FIG. 6A and FIG. 6B the voltage across the inductor should be the same.

$$\begin{matrix}V ( Vcc 2 ) = V ( Vsrc + ) + V ( {L}_{p} ) \\ = V ( {L}_{p} ) + Vsrc + V ( Vsrc - ) \\ = V ( {L}_{p} ) + V ( {L}_{G} ) + Vsrc\end{matrix}$$

$$V ( Vss 2 ) = 0$$

$${V}_{A} ( Vcc 2 ) = V ( {L}_{p} ) + V ( {L}_{G} )$$

with

V(Lₚ)=−V(L_{G})!=0

Vss2=Gnd(0 v)

It shows the substrate noise can be zero and the power oscillation is double. It gives the implication that the substrate noise can be zero.

Now, with our innovative Current Regulator of Noise Isolation Technology, as shown in FIG. 6C and FIG. 18E, in the physical real world, the substrate noise is real zero.

V(Vss3)=0

V_{A}(Vcc3)=V_{A}(Vcc2)

with

V(L_{P})=V(L_{G})=0

Vsrc−=Gnd

The conventional noise technology is to try to reduce the digital switch noise. Our approach is completely different. Our innovation is to confine the noise in the local power node VCC3 and isolate it from the substrate. Just as the heat isolation using the magnetic shield in the fusion reaction as shown in FIG. 6D, our noise isolation uses the electric shield in the planar chip as shown in FIG. 6E. Instead of the dump of the noise on the board, our innovation is to confine the noise in the digital power bus chip locally. The board, is clean without noise.

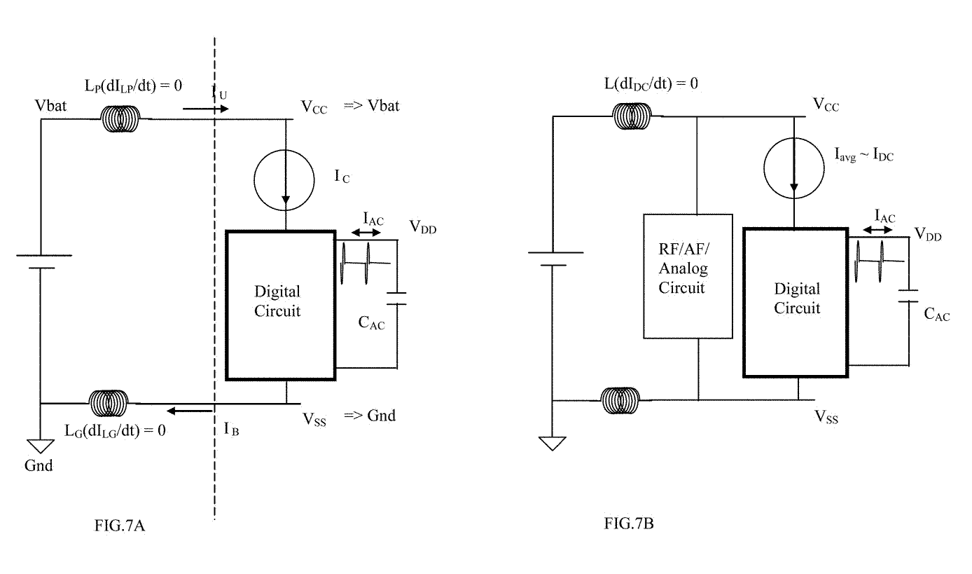

As shown in FIG. 7A, the current regulator regulates the current supply to be a constant current source IC. As the digital circuit is switched, all the time varying current I_{AC} flows through the capacitor C_{AC}. I_{LP} and I_{LG} are the current flowing through the parametric inductors.

I_{LP}=I_{U}=I_{C}=const

L_{P}(dI_{LP}/dt)=0

Furthermore, according to Kirchhoff's Current Law, the section cut is shown as the dotted line, we have I_{U}=I_{B}.

I_{LG}=I_{B}=I_{U}=const

L_{P}(dI_{LG}/dt)=0

As shown in FIG. 5A, the inductor is the noise amplifier of the noisy instantaneous current with the L(dI/dt) mechanism. As shown in FIG. 7A the noise isolation technique has the instantaneous current I_{AC} to be confined locally with the local bypass storage capacitor C_{AC}. The I_{AC} doesn't go through the inductor L_{G}. The-capacitor C_{AC} at the output absorbs variance of current to keep variance of current flowing through the current regulator I_{C} to be minimum.

As shown in FIG. 7A, with the short circuit L_{G}(dI_{LG}/dt)=0 of the parametric inductors, the substrate Vss is clamped to be the zero voltage. All the noise is confined and isolated at the node VDD. The ground and substrate are shorted and clamped by the ground 0 with the inductor L_{G}.

Since the VCC and VSS are quite, as shown in FIG. 7B, the RE/AF radio frequency, analog front and analog circuit can be connected to the quite power, ground VCC and VSS. The substrate is connected to the VSS that there is no substrate noise coupling problem. In other words, the RF/AF radio frequency, analog front and analog circuit can be integrated with the digital and FPGA to be a single chip.

The Green Energy Smart Window integration system has noise isolation. The noise isolation means has the current regulator to regulate the current flowing a plural of bonding wires. The bonding wire connection has the parasitic inductor. The current regulator regulates the current flowing through the parasitic inductor of bonding wire to reduce the switching noise generated by the parasitic inductor.

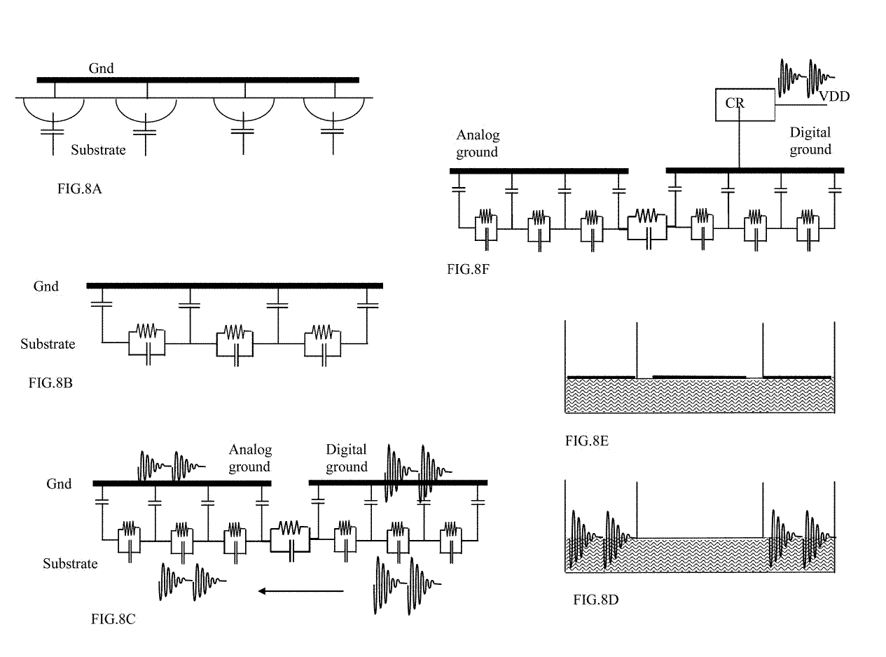

As shown in FIG. 8A, the on-chip metal ground line Gnd is connected to the substrate through the high density doping wells, etc. There are the parametric capacitors. As shown in FIG. 8B, it is the equivalent circuit of the substrate connection. The substrate has the resistance 3000Ω per square; the metal has the resistance about 0.001Ω per square. So, the ground metal shorts all the substrate circuit together to be a lump node. The low resistance metal has shortened all the substrate circuit together.

Comparing the conventional noise isolation techniques as shown in FIG. 8C, the digital noise injects into the substrate. This substrate noise is in the substrate under the analog circuit. The substrate noise contaminates the analog ground. So, the conventional separate power and ground doesn't solve the coupling substrate problem.

As shown in the FIG. 8D, it is the hydraulic model of the electron sea in the substrate. The substrate noise in the digital substrate will disturb the substrate of analog circuit. In other words, it must have all the substrate connected together to be a calm sea as shown in FIG. 8E. The separation of power and ground cannot eliminate the substrate noise to meet the high S/N or ENOB requirements that the analog RF/AF ASIC chip has to separate from the large digital or FPGA circuit.

To have the quite ground for the digital substrate in the FIG. 8E, as shown in FIG. 8F, the current regulator CR confines all the digital noise at the power node V_{DD}. The ground is kept isolated from the noise to be the electrical isolation layer.

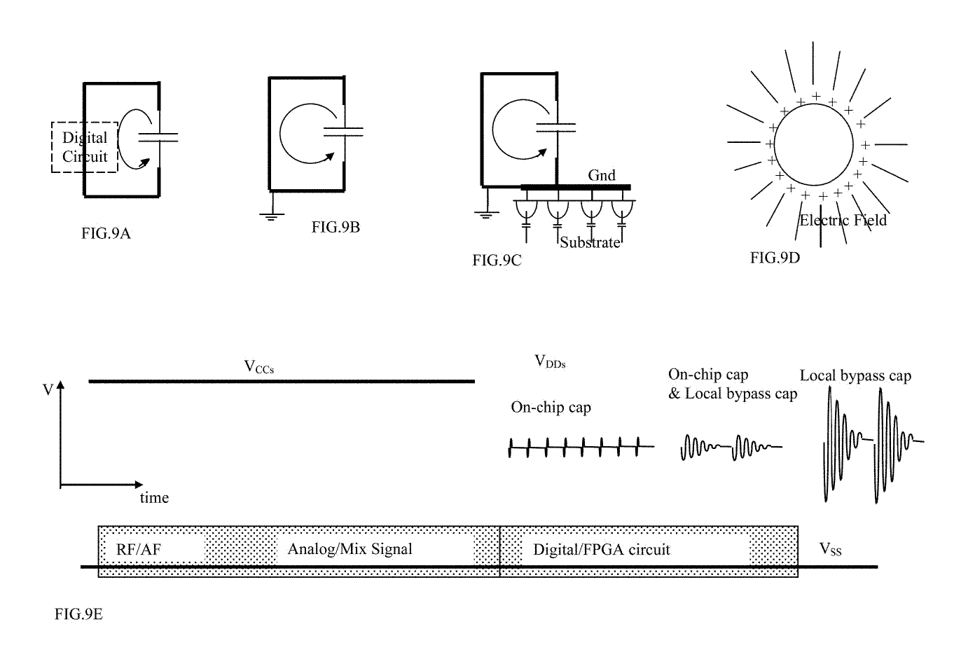

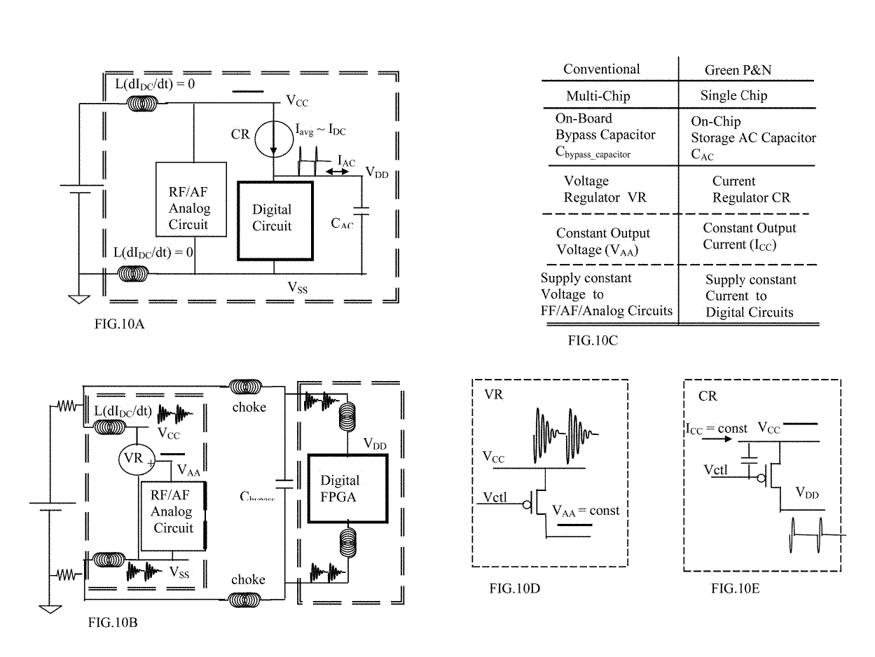

With the innovative CR in FIG. 8F, the power voltage, ground voltage and noise voltage are shown in FIG. 9E. The ground voltage and the substrate voltage are clamped to be the ground 0V with the L_{G} inductor. There is no substrate noise. All the digital switching noise is confined at the V_{DD} node. Depending on the size of digital/FPGA circuit, the C_{AC} might be the versatile combinations of the on-chip capacitor and on-board capacitor. However, the on-chip capacitor can reduce the inductor current that the peak voltage oscillation is reduced.

In the Noise Isolation Technology NIT, there is a question whether the oscillation of the current between the digital circuit and the capacitor will inject into the substrate to generate the noise. To answer this question, as shown in FIG. 9A, there is one capacitor with the positive terminal being connected to the negative terminal of this capacitor. There is no ground and/or substrate. The closed loop current will not inject to ground and/or substrate. As shown in FIG. 9B, the ground is added to the circuit however the loop current will he still the same. So, as shown in FIG. 9C, the loop current will not inject into the ground and/or substrate. In other words, just as the electric field inside the closed metal cavity as shown in FIG. 9D, the ground and substrate are shielded from the inject current FIG. 9C. FIG. 9D is the static electric field case; FIG. 9C is the dynamic current case. There is no switching noise outside the current loop and it is names as the Tangs' Law.

A green technology integration system comprises application specific integrated circuit ASIC and field programmable gate army FPGA. The green technology integration system integrates the ASIC and FPGA on a platform made of the noise isolation means to be the field programmable integrated chip FSOC. FIG. 9E is the application of the Tangs Law to the platform of the system integration. All the Radio Front, Analog Front RF/AF, analog mixed signal and Digital/FPGA circuit are integrated on the same chip to share the same substrate. With the Tangs' Law, the power V_{CCS} of the RF/AF, analog circuit is constant over time. The switching noise is confined on the multiple V_{DDS} digital power buses. For the switching current spikes, the switching noise is small. With the on-chip capacitor, the oscillation voltage is much smaller than the on-board capacitor.

FIG. 10 illustrates the differences between the innovative current regulator and conventional voltage regulator. As shown in FIG. 10A, the current regulator eliminates the internal on-chip substrate noise generated by the on-chip digital switching noise. As shown in FIG. 10B, the voltage regulator eliminates the external on-board power noise injected into the analog circuit.

The digital switch has the periodic curve that we can take advantage to get rid of the digital switch noise. As shown in FIG. 10A, the digital circuit consumes the switching current I_{switch}=I_{AC}+I_{DC}. The I_{DC} is the slow varying low frequency average current which can be treated to be constant in the timing window. The current regulator CR only provides the constant average current I_{DC}. In the short time window, I_{DC} can be approximated to be constant, I_{DC}=constant. For I_{DC}=constant, L(dI_{DC}/dt)=0. The substrate has V(Vss)=V(0) to be the ground node voltage and has no digital switch noise. The capacitor C_{AC} will smooth the voltage V_{DD}. The amplitude variance of V_{DD} is the inverse proportional function of the capacitor C_{AC}. To make the variance of V_{DD} smaller, we need the larger C_{AC}. However, there is the limit of the on-chip capacitor. Then the off-chip capacitor can be used with the combination of the on-chip capacitor. The on-chip capacitor reduces the peak voltage and the off-chip capacitor reduces the large variance of the V_{DD} amplitude.

As shown in FIG. 10A, for the current regulator, the current switching occurs at, node V_{DD}. The protected node V_{CC} voltage is a constant voltage. On the contrary, as shown in FPGA the node V_{CC} has the on-board injecting noise. This on-board injecting noise is coming from the digital switching noise of the neighboring digital or FPGA chips. The digital or FPGA chip dumps the digital switching noise on the board. Even having the bypass capacitor and/or choke, it still has the digital switching noise injecting into the RF/AF analog chip. Under the V_{CC} injecting noise, the voltage regulator is trying to have the on-chip analog supply voltage V_{AA} to be constant. Comparing FIG. 10A with FIG. 10B, the noise injecting node and the protected node are exactly reverse. It shows the essential difference between the current regulator CR and voltage regulator VR. The current regulator CR has the completely different functional features from the voltage regulator.

As shown in FIG. 10C, the comparison table summarizes the difference between the conventional approach and the Green Technology. In the conventional approach, the system is partitioned to be multi-chip of the RF/AF analog chip, mixed signal chip digital and FPGA chip. The Green Technology uses the single chip system approach. It saves power and has higher performance. The conventional multi-chip system uses the on-board bypass capacitor. The on-board bypass capacitor will generate much more on-chip digital switching noise. The conventional system dumps the noise on the board. The Green Technology confines the noise in the local chip. The conventional uses the voltage regulator to isolate the analog circuit from the on-board power and ground noise. The Green Technology uses the current regulator to isolate the digital switch circuit to keep the switching noise from the contamination of the on-board power and ground. The conventional system uses the voltage regulator VR to generate the internal constant chip voltage V_{AA} for the analog circuit. The Green Technology uses the current regulator to generate the constant current for the digital switching circuit.

Comparing the voltage regulator VR in FIG. 10D and the current regulator CR in FIG. 10E, the voltage regulator VR is to filter the voltage oscillation in Vcc to generate the constant voltage at V_{AA} node; the current regulator CR is to filter the current spikes in the V_{DD} to generate the constant current in the node Vcc. The current regulator CR has the conjugate and opposite functions of the voltage regulator VR.

From the power source view, we compare and make the analysis for the characteristics of the current regulator. As shown in FIG. 11A, it is the characteristic curve and symbol of the voltage source of the voltage regulator VR. The output voltage is constant over all the current load. As shown in FIG. 11B, it is the characteristic curve and symbol of the current source. The output current is constant over all the voltage load. As shown in FIG. 11C, it is the characteristic curve and symbol of the current regulator. Both the output current and voltage are the specified constants. So, the current regulator is neither the voltage source nor the current source. The current regulator is a new kind of power source. Furthermore, for the dynamic loading, the output current load varies but the output voltage is constant. This is an adaptive smart current regulator. However, the current regulator is different from the voltage regulator. The voltage regulator is high speed and broad spectrum circuit to keep the out voltage to be constant. The current regulator is low speed and narrow spectrum circuit to keep the output current to be constant.

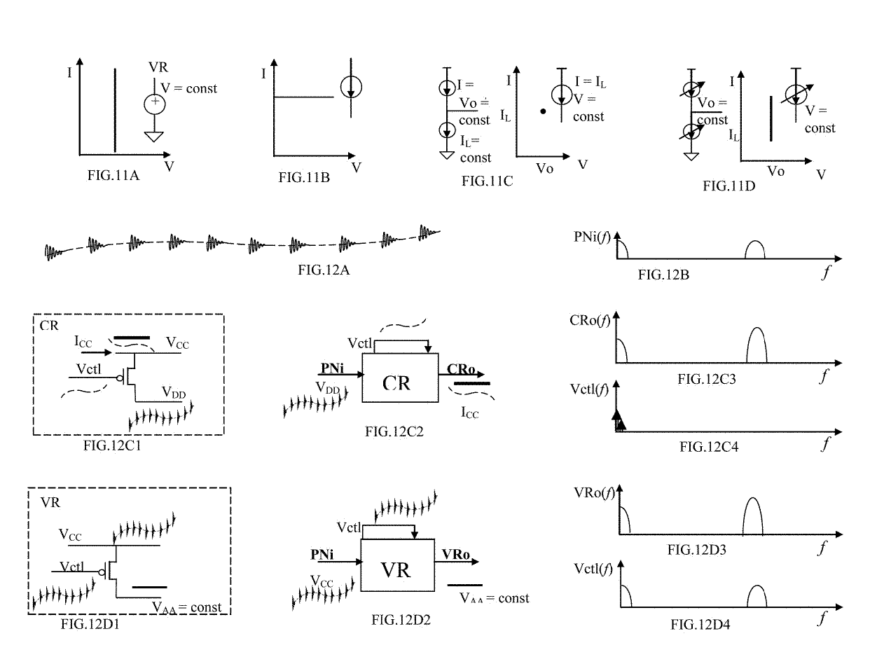

As shown in FIG. 12A, it is the digital switching curve with the slow wandering. The slow wandering comes from oscillation having the large on-board capacitance, etc. The spectrum of the digital switching curve is shown in the FIG. 12B. The high frequency band is the digital switch. The low frequency band is the wandering baseline coming from the large on-board capacitance, etc. FIG. 12C2, FIG. 12C3 and FIG. 12C4 are the waveform, symbol, spectrum of the input and output signals of the current regulator CR. FIG. 12D2, FIG. 12D3 and FIG. 12D4 are the waveform, symbol, spectrum of the input and output signals of the voltage regulator VR.

FIG. 12C1 and FIG. 12C2, the power noise PNi input is at VDD and the output is constant or slow varying current ICC. The control signal Vct1 slow varies to keep the current ICC to be constant. As shown in FIG. 12C3, the power noise PNI input has both high frequency digital switching noise and the km frequency wandering baseline. As shown in FIG. 12C4, the control signal Vct1 only has the low frequency control for the low frequency wandering baseline.

On the contrary, in FIG. 12D1 and FIG. 12D2, the power noise PNi input is at V_{CC} and the output is the constant voltage V_{AA}. The control signal Vct1 fast varies to keep the voltage V_{AA} to be constant. As shown in FIG. 12D3, the power noise PNi input has both high frequency digital switching noise and the low frequency wandering baseline. As shown in FIG. 12D4, the control signal Vct1 has high frequency control for the digital switching and the low frequency control for the low frequency wandering baseline.

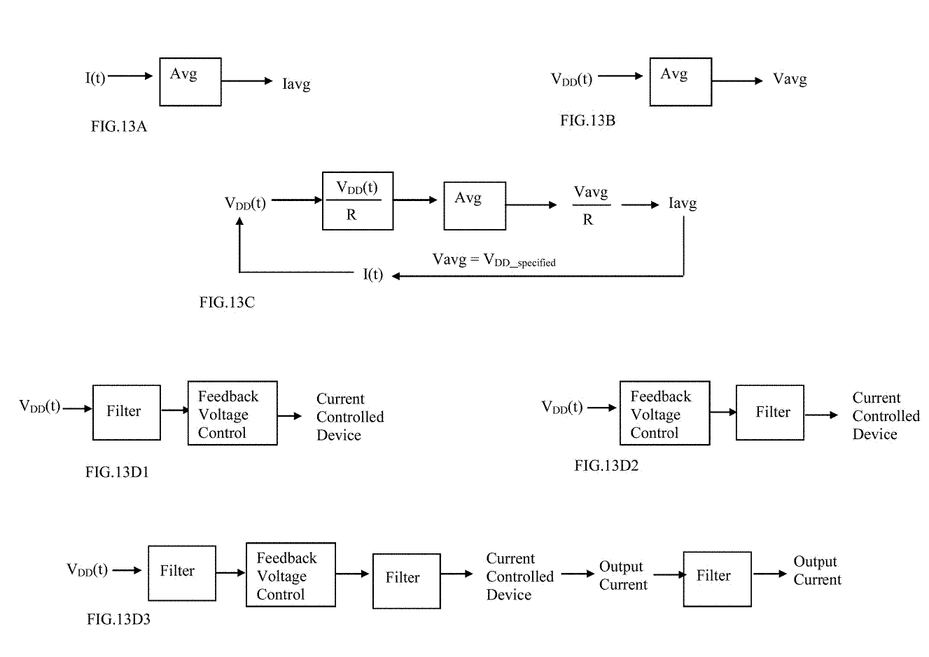

To generate the low frequency control signal for the current regulator, we need to extract the baseline wandering information from the input PNi digital switching power noise signal. As shown in FIG. 13, there are versatile different ways to extract the baseline wandering information from the input PNi digital switching power noise signal.

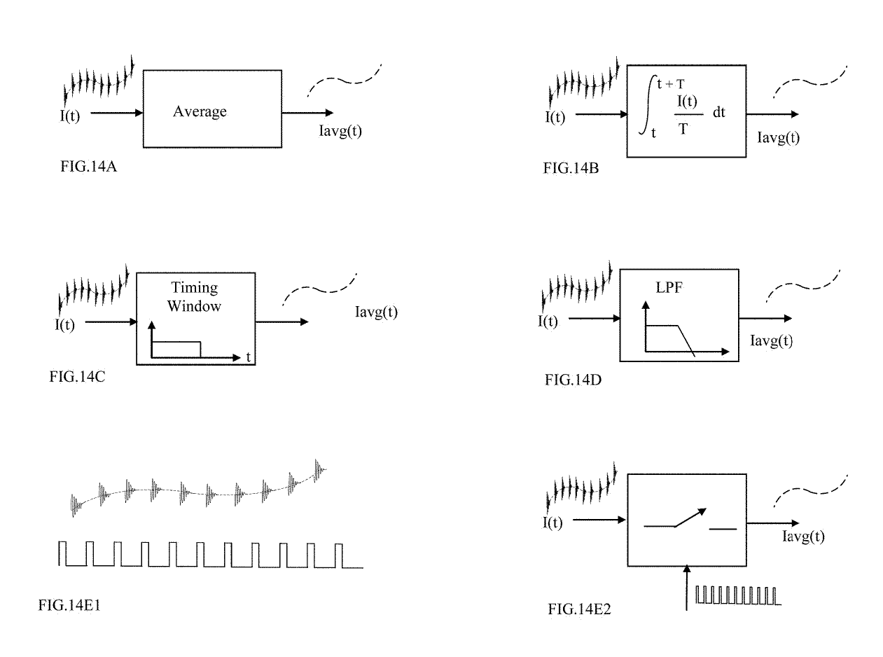

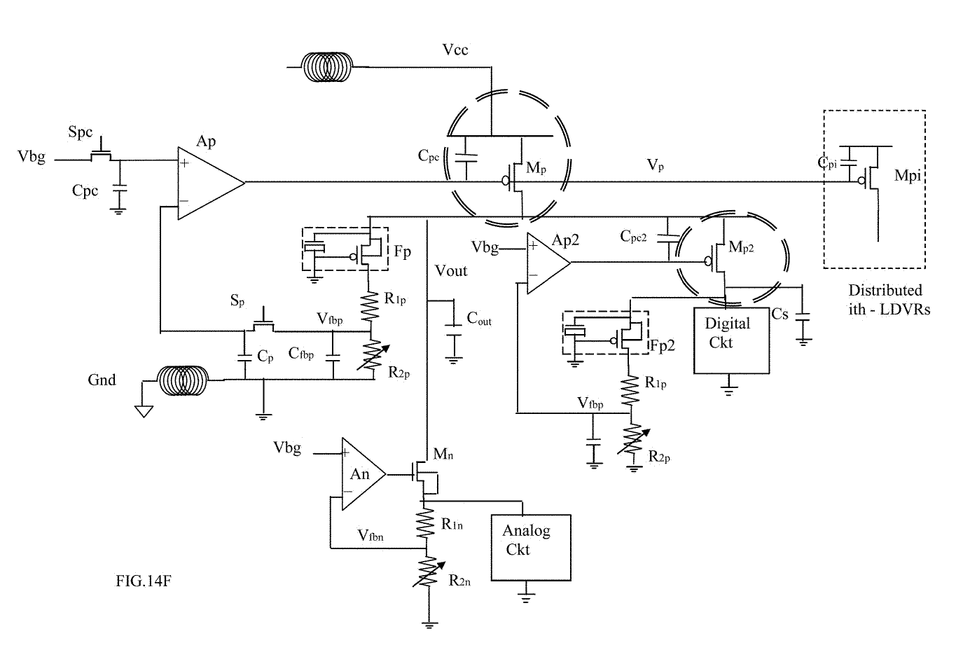

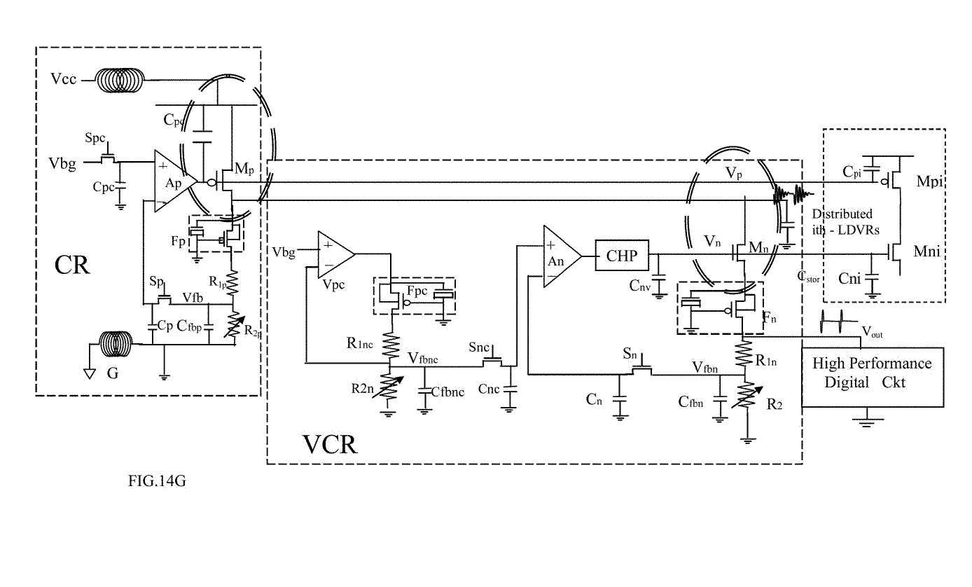

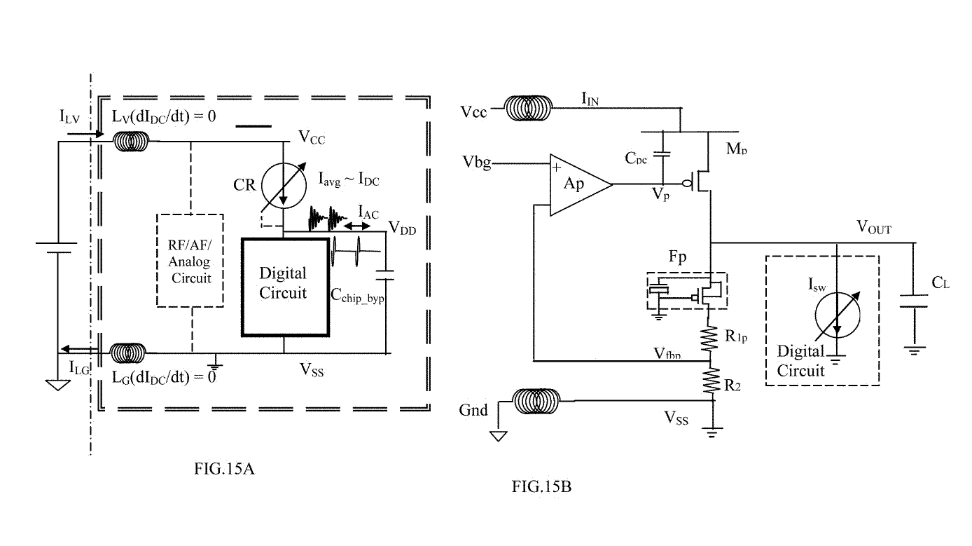

FIG. 13A is the basic block diagram of average circuit to extract the average value I_{avg} from current I(t). FIG. 13B is the basic block diagram of average circuit to extract the average value V_{avg} from current V(t). FIG. 13C is the block diagram which generates the average current from the voltage instead of the current directly. The fundamental principle of the current regulator is to minimize the variance of current flowing through the parasitic inductor of the bonding wire and pin, etc. The current flowing through the parasitic inductor is only the average of the current. The feedback control circuit provides the low frequency current to current loading and keeps the voltage to be the specified voltage level. The abrupt change and variance of switching current is absorbed by the storage capacitor. There are many different implementations of the above principles. As shown in FIG. 13D1 and as shown by the F_{P} in FIG. 14F, the switching noise is filtered out first, then the low frequency signal is compared with the reference voltage to generate the control signal. This pre-filter is the preferred implementation. Of course, as shown in FIG. 13D2, there is possible to have the alternative post-filter implementation to feedback the voltage first then filter the switch noise. However, in the practical implementation, as shown in FIG. 13D3 and FIG. 18C, the pre-filter of FP, post-filter made of the Cpc and the output impedance of amplifier AP are adopted. As shown in FIG. 18C, the cascade current regulators and the cascade filter FP3 are, adopted. The green technology integration system has the current regulator further comprises the filter, feedback and comparing circuits. The filter filters out the high frequency variance of output to get low frequency variance of output. The comparing circuits feedback the information of variance of output current loading. The current devices are controlled based on the information of the low frequency variance of output loading current.

FIG. 14 illustrates the versatile techniques to generate the dynamic average current. FIG. 14A is to use the average circuit to generate Iavg(t) from I(t). The current regulator comprises filter, feedback and comparator. The filter filters out high frequency variance of loading to get low frequency variance of loading. The comparator feedbacks information of variance of loading. A plural of current device is controlled based on information of low frequency variance of loading. FIG. 14B is the timing integration block to generate the Iavg(t) from I(t). FIG. 14C is the timing window to generate the Iavg(t) from I(t). FIG. 14D is to use the low pass filter to generate the Iavg(t) from I(t). FIG. 14E1 shows the waveform of the power buses and clock. At the clock edge, the simultaneous switches of the digital circuit generate the switch noise instantly. The switch noise dies away to be the average value. As shown in FIG. 14E2, the sampling circuit samples the average value at the average value period to get the average value Iavg(t). According to the principle illustrated in the FIG. 13C, FIG. 14F shows the current regulator design which integrates of the above techniques to have the practical application. The filter Fp is to serve as the filter as shown in FIG. 14D to generate the average voltage for the average current The voltage divider R1p, R2 and Cfbp are the feedback circuit and filter. The sampler Sp is to sample the average value at the average period to have the much cleaner average value. The sampling gate Spc and capacitor is to compensate for the sampling noise generated by the switch gate Sp. The output capacitor Cpc and the output resistance of the amplifier Ap are another filter. So, there are four filters are in cascade to get the high quality average current. Finally, the average bias voltage for the average current applying on the P device Mp to generate the constant “current source” which has the “constant” current value Iavg(t) to be the “average” value of the current load I(t). It is noted that the circuit is dynamical that the Iavg(t) is also dynamic. The “constant” means over, a short time period of time window. The time window shifts and the “constant” value also varies and shift slowly at very low frequency. For a short period time, the average value can biotreated as a constant. For the constant current L(dIavg/dt)=0, the voltage across the inductor is zero, i.e., the switching noise generated by the inductor is zero.

To increase the switching noise rejection capability, the current regulator can be cascaded to get the high ratio of the switch noise rejection. The Noise Isolation Factor of the switch noise rejection is defined as

NIF=Switching Noise in Isolated Power Bus/Switching Noise in Substrate

As shown in FIG. 14F and FIG. 18C, the green technology integration system has the current regulator comprising P type current devices and N type current devices. The P type current device M_{P} and N type current device M_{N} are connected in cascade with drains. The capacitor C_{OUT} is connected to the drains of devices. As shown in FIG. 14G, the Hybrid current regulator HCR is made of the P type current regulator PCR and N type current regulator NCR. FIG. 14G is the cascade of the voltage regulators of the current regulator and it is the hybrid voltage regulator of P-type current regulator PCR and N-type current regulator NCR. The current regulator CR has the constant current flowing through the P-type current regulator and the N-type current regulator is to minimize the switching noise as seen by the high performance circuit to have the fast circuit speed and less noise. The noise is isolated in the capacitor between the P-type current regulator and the N-type current regulator that both the inductor and circuit do not see the violent switching noise. The hybrid current regulator is much better than the two P-type cascaded current regulators as shown in FIG. 18. The two P-type cascaded current regulator has the NIT to be 1800; however, the hybrid current regulator has the NIF much larger than 1800.

FIG. 15A is the basic system and architecture of the Noise Isolation Technology. The noise isolation comprises capacitor at current output. It is to absorb variance of current loading to keep variance of current flowing through current regulator to be minimum. FIG. 15B is the circuit implementation of the Noise Isolation Technology. FIG. 15A illustrates the fundamental principles of the Noise Isolation Technology. In FIG. 15A, the current regulator CR is constant DC current I_{DC} of the current average I_{avg}. First, assumes the RF/AF/Analog, circuit not existing that only the current flows through the current regulator CR. Applying the Kirchhoff's current law at the cross-section as shown in FIG. 15A, the current I_{LC} flows through the inductor of the power supply is equal to the current I_{LG} flows through the inductor of the ground, I_{LV}=I_{DC}=I_{LG}=constant. So the voltage across inductors L_{V}(dI_{DC}/dt)=0 and L_{G}(dI_{DC}/dt)=0. In other words, there is no switching noise generated by the inductor L_{V} and L_{G}. The on-chip ground or substrate voltage Vss is the same voltage as the on-board ground.

The same argument can be applied to the circuit having the RF/AF/Analog circuit. As shown in FIG. 15A, the current flowing through the RE/AF/Analog circuit is constant. Both the current regulator and the RF/AF/Analog circuit are constants. The current flowing through inductor L_{V} and L_{G} is constant. The on-chip ground or substrate voltage Vss is the same voltage as the on-board ground.

FIG. 15B is the circuit for the current regulator. The current regulator is very similar to the voltage regulator. However, the function of the circuit is much different from the voltage regulator. The voltage regulator is to keep the “output voltage” to be constant. The current regulator is to keep the “input current” to be constant. The difference between the current regulator and voltage regulator is the current regulator having the low pass filters such as Fp and Cpc. The voltage regulator has to be hist response to the high frequency switch noise. The current regulator is only to trace and follow the low frequency average current.

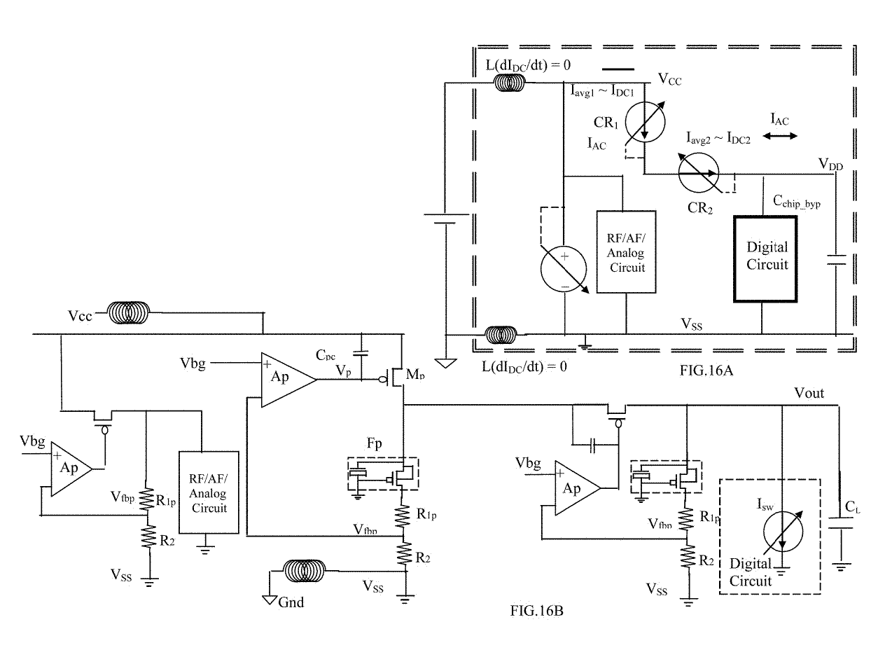

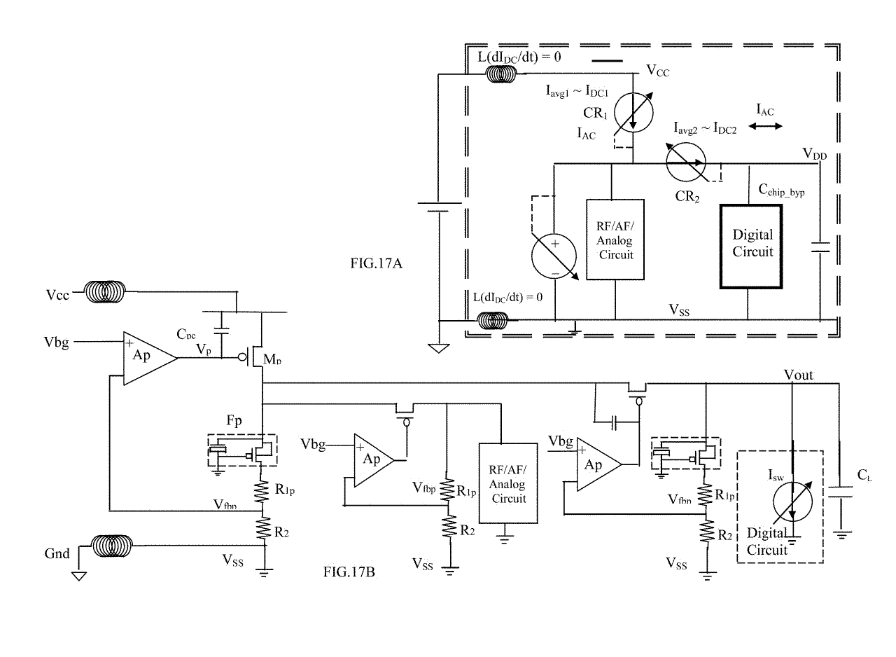

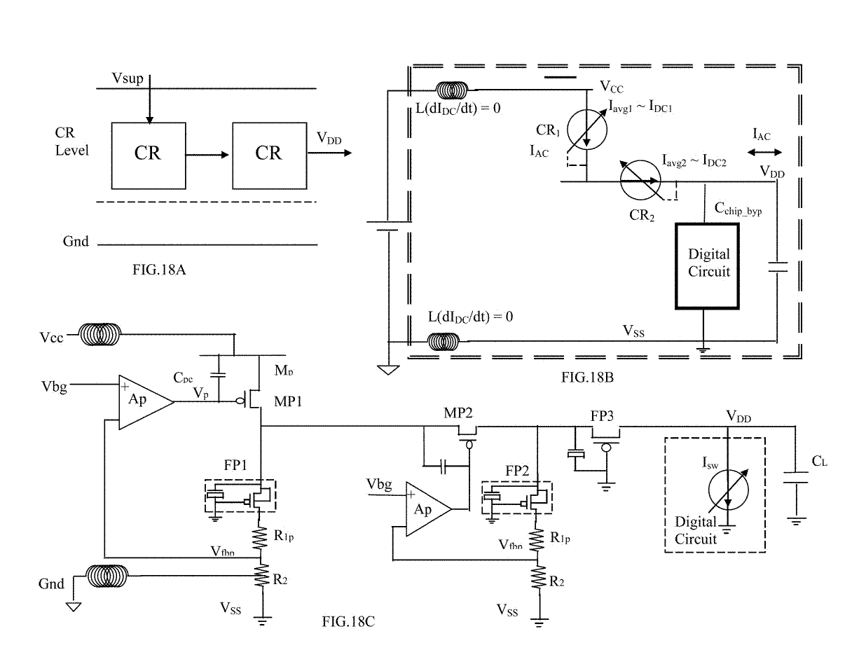

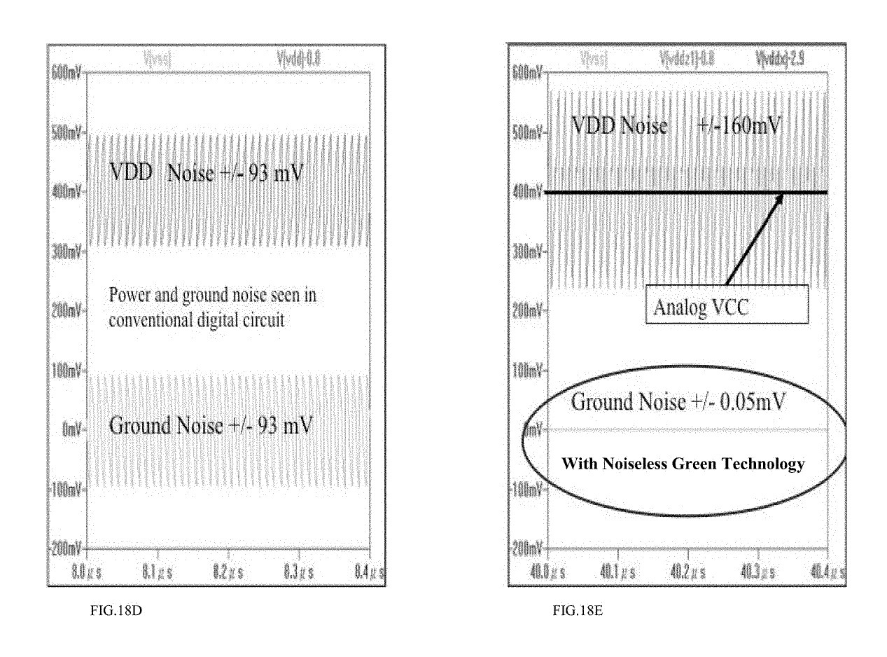

As shown in FIG. 16A, for the cascade current regulator, the total SNRR

NIF=NIF₁×NIF₂

where the NIF₁ is the Noise Isolation Factor NIF of the first stage current regulator; the NIF₂ is the NIF of the second stage current regulator. Usually one stage current regulator has the SNRR to be 50. For the two stage current regulator, the SNRR is bout 2500. It is equivalent to 13 Bits improvement for ADC. FIG. 16B is the circuit for the 2-stage cascade current regulator.

As shown in FIG. 17A, for the cascade current regulator architecture, the RF/AF/Analog Circuit can be located between the two current regulators. FIG. 17B is the circuit implementation of the FIG. 17A.

Referring to FIG. 18C, the green technology integration system has the noise isolation means is constituted of a plural of cascading controlled, current devices MP1 and MP2. It is to regulate the current flowing through the parasitic inductor to reduce noise generated by the parasitic inductor. Furthermore, with the basic patterns, we can have the versatile combinations of the different patterns for the noise isolation technology. The noise isolation means further comprises a plural of filters FP1 and FP2 to filter out the high-frequency noise to control cascading controlled current devices. FIG. 18is the basic pattern of the cascade, current generators. FIG. 18A is the block diagram for the cascade current generators. FIG. 18B is the system and architecture of the cascade current generators. FIG. 18C is the circuit of the cascade current generators. As shown in FIG. 18D, it is the SPICE simulation to show the switching noise of digital circuit as shown in FIG. 6A. It is the SPICE simulation with the Noise Isolation Technology Circuit in FIG. 18E to show the switching noise of digital circuit as shown in FIG. 6C. The Noise Isolation Factor NIF is 1800. Referring to FIG. 18C, the noise isolation means comprises a plural of cascading controlled current devices MP1, MP2 and filters FP3 to regulate current to reduce noise generated by the parasitic inductor means.

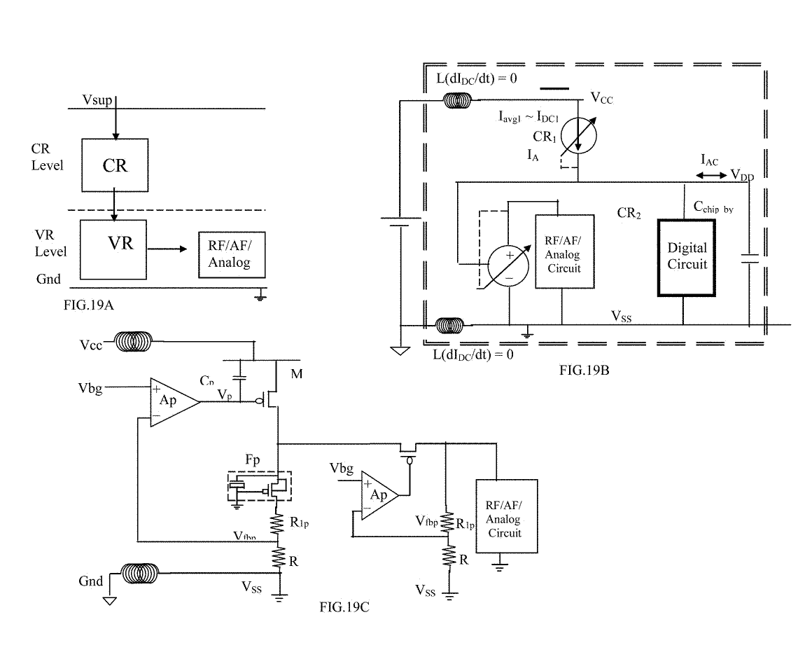

FIG. 19A, FIG. 19B and FIG. 19C are the cascade connection of the current regulator and the voltage regulator. FIG. 19A is the block diagram of the current regulator and the voltage regulator. FIG. 19B is the system and architecture of the cascade current generator and voltage regulator. FIG. 19C is the circuit of the cascade current generator and voltage regulator.

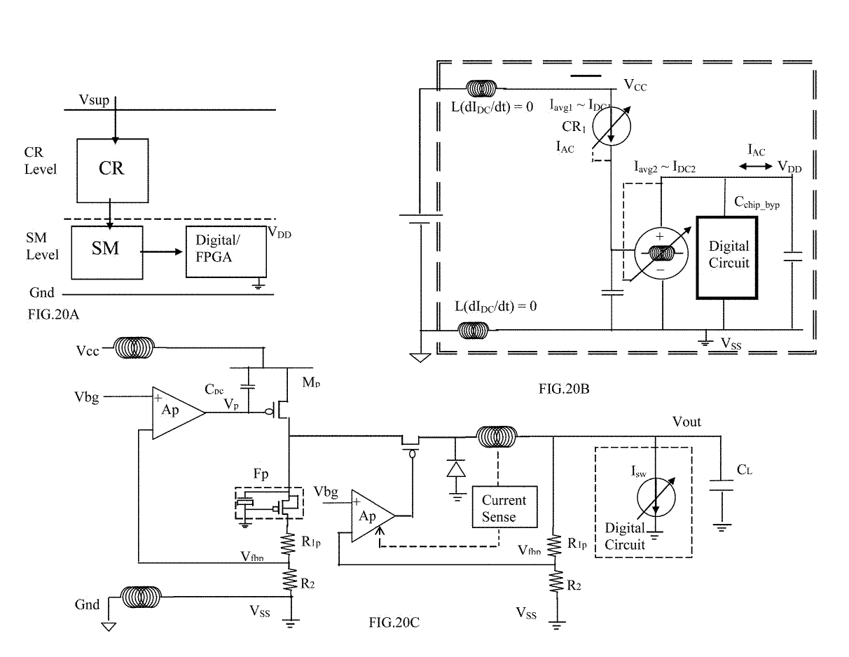

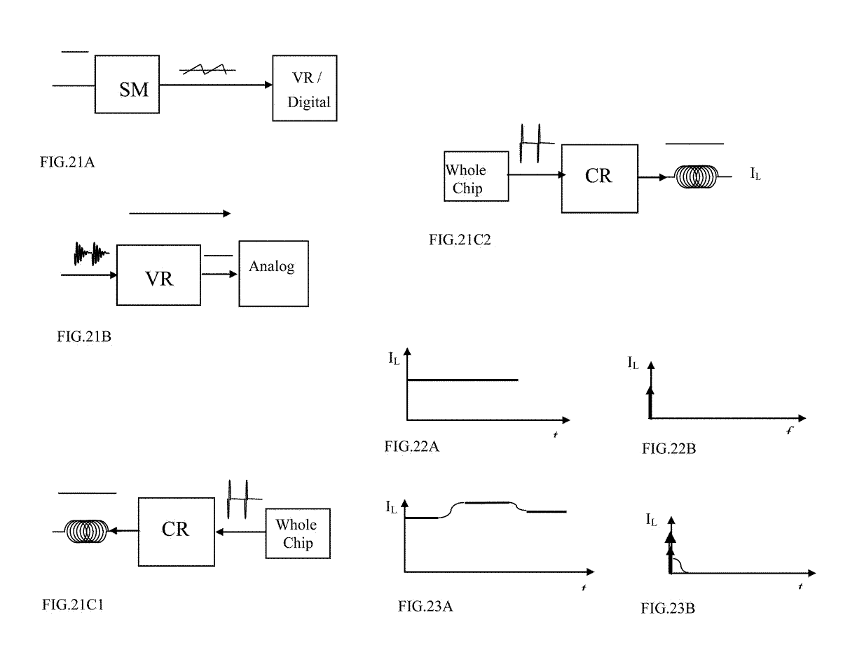

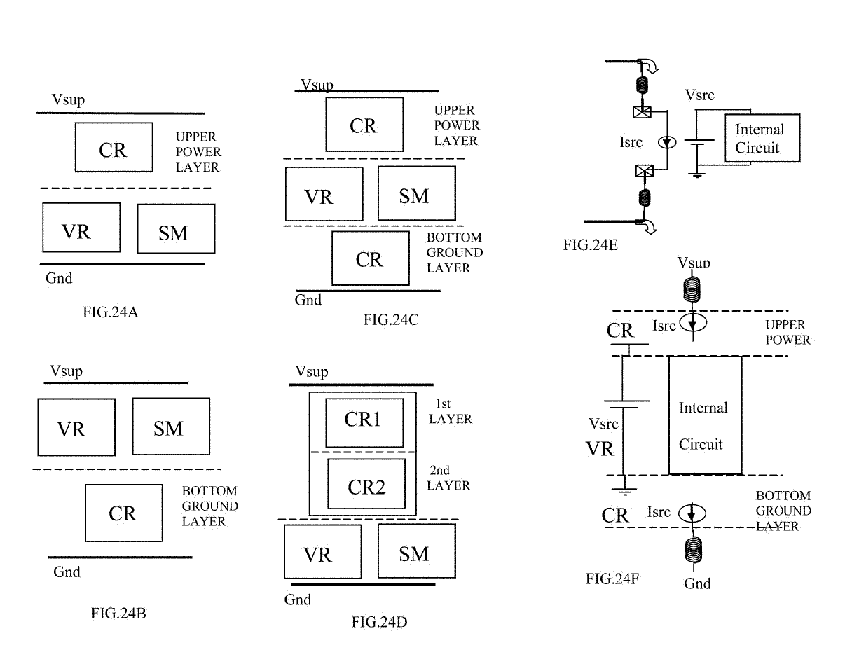

FIG. 20 is the cascade of the current regulator and the Switch Mode power supply. FIG. 20A is the block diagram of the current regulator and the Switch Mode power supply. FIG. 20B is the system and architecture of the cascade current generator and Switch Mode power supply. FIG. 20C is the cascade current generator and Switch Mode power supply of buck converter. The switch mode power supply can be boost converter, buck converter, etc.

FIG. 21 is the comparisons among the three different power management unit, Switch Mode SM, Voltage Regulator VR and Current Regulator CR. In FIG. 21A, the Switch Mode power supply changes the power from one voltage level to another voltage level. The output voltage has the ripple voltage. The output voltage is fed into the voltage regulator VR or directly to be the low voltage digital circuit, etc. In FIG. 21B, the voltage regulator VR is to filter the input power noise to have the output voltage to be the clean constant voltage for the analog circuit. FIG. 21C1 is the block diagram of the current regulator which is analogy to the voltage regulator VR. However, the signal flow is in the reverse direction. So, the signal flow diagram is as shown in FIG. 21C2. FIG. 22A is the current regulator for the constant average current output loading I_{L}. FIG. 22B is the frequency spectrum of the current regulator. FIG. 23A is the current regulator. FIG. 22B is the frequency spectrum of the current regulator.

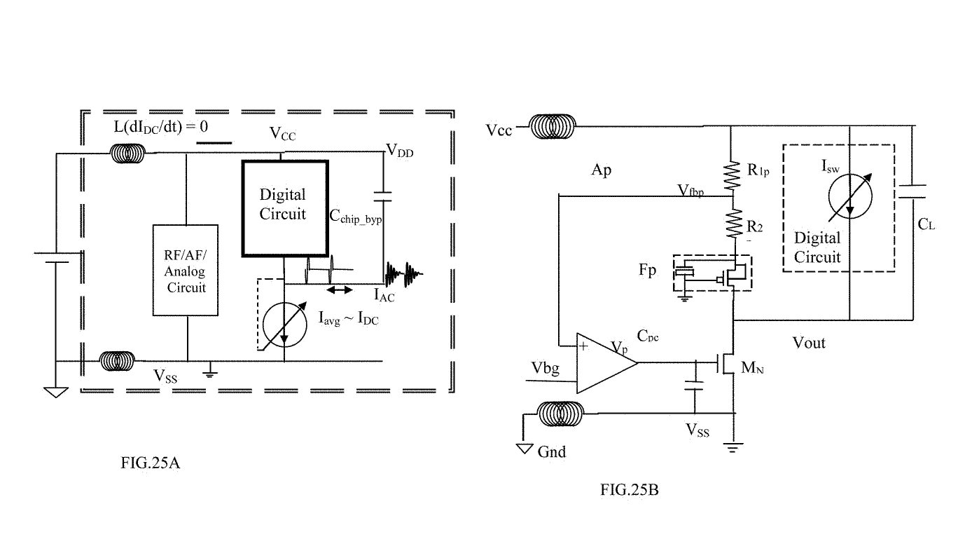

With the manipulation of the block diagrams, we can make novel innovations of the Noise Isolation Technology in the system and architecture level. FIG. 24A is the basic system and architecture of the noise isolation technology. The current regulator is at the upper power layer; the voltage regulator and the switch mode power supply are at the low layer. FIG. 24B is the conjugate architecture of FIG. 24A. The current regulator is at the lower ground layer; the voltage regulator and the switch mode power supply are at the upper layer. The architecture is shown as FIG. 25A and the circuit implementation is shown as FIG. 25B.

To have the higher Noise Isolation Factor NIF, as shown in FIG. 24C, the current regulators are in both upper layer and ground layer. The Noise Isolation Factor is

NIF=NIF_{P}×NIF_{G}

where the NIF_{P} is the NIF of the current regulator at upper power layer, the NIF_{G} is the NIF of the current regulator at bottom ground layer.

Similarly, we can have the different ways to cascade the current regulator. As shown in FIG. 24D, all the current regulators are in the upper power layer. It can be interpreted that the current regulator CR is the hierarchical current regulator having the current regulator CR₁ to be cascaded with the current regulator CR₂. The cascade current regulators are as shown in FIG. 18. FIG. 18A is the system and block diagram of the cascade current regulator. FIG. 18B is the architecture of the cascade current regulator. FIG. 18C is the circuit of the cascade current regulator.

Applying the hierarchical principles to the versatile combination of the current regulator, voltage regulator and switch mode power supply, there are many different novel power and ground plans. With the versatile novel combination, as shown in FIG. 24E, it is the equivalent circuit for the ideal power supply. The board provide the constant current source to the chip. Then the chip generates the constant voltage source to the circuit. As shown in FIG. 24F, it is the architecture of the ideal power supply which is corresponding to the ideal circuit in FIG. 24E. It is equivalent to the system and block diagram in FIG. 24C.

The current regulator comprises a plural of P type current devices and N type current devices. The P type current device and N type current device are connected in cascade with draining nodes being connected together. The capacitor is connected to draining nodes.

A green technology noise isolation integration system comprises a plural of cascading controlled current device with addition of a plural of cascading filter to regulate current flowing through parasitic inductor to reduce noise generated by parasitic inductor. FIG. 25A is the conjugate Noise Isolation Technology as shown in FIG. 15A. The P device is changed to be the N device M_{N} and the power bus Vcc is changed to be the Ground Bus Vss. FIG. 26A is the alternative design of the FIG. 24C. It has the cascade current regulator effect to increase the Noise Isolation Factor NIF. The FIG. 26E is the Preferred implementation. As shown in FIG. 26C, the green technology integrated system noise isolation comprises a plural of cascading controlled current device and filter. It is to regulate current flowing through the parasitic inductor to reduce noise generated by the parasitic inductor. As shown in FIG. 26F, to reduce the ground bounce, we can reduce the undershoot. The voltage-clamping device M_{CN} is biased at the voltage V_{CN}. As the undershoot occurs, the voltage clamping device M_{CN} is turned-off the output device M_{ON}. As the ground bounce occurs, the output device M_{ON} is turned-off that the overshoot of the ground will not show at the node Dₒᵤₜ. Similarly, as shown in FIG. 26F, to reduce the power surge, we can reduce the overshoot of the V_{DD}, The voltage-clamping device M_{CP} is biased, at the voltage V_{CP}. As the overshoot of V_{DD} occurs, the voltage-clamping device M_{CN} is turned-off the output device M_{ON}. As the ground bounce occurs, the output device M_{ON} is turned-off that the overshoot of the ground will not show at the node Dₒᵤₜ.

A Green Energy Smart Window Wireless Window 5R System W5RS comprises substrate noiseless P&G plan having all the ground nets being connected together one LDO typed constant current source. In FIG. 26E, all the ground nets are connected together. Furthermore, the Green Energy Smart Window Wireless Window 5R System W5RS further comprises ground-bounce-less output buffer. As shown in FIG. 26D2 and FIG. 26F, the output buffer has non-overlap, tri-state and voltage clamping mechanism made of MCP and MCN. The ground-bounce-less output buffer comprises non-overlapping mechanism, tri-state mechanism and clamping mechanism. The clamping mechanism detects the undershoot of the ground-bounce-less output buffer and turns off the N type output device. The clamping mechanism detecting overshoot of the ground-bounce-less output buffer and turns off the P type output device.

As shown in FIG. 26G, the Green Energy Smart Window Wireless Window 5R System W5RS has a rippleless LDO to deliver rippleless DC output power at an output voltage. The rippleless LDO has one error amplifier and voltage divider. The voltage divider divides the output voltage to generate a feedback voltage V_{FB}. The error amplifier has a reference voltage V_{BG} and the feedback voltage V_{FB} been connected as inputs.

FIG. 26G is the programmable LDO which can be programmed to be analog LDO and digital LDO. Furthermore, programmable LDO is the “Auto-LDO” which is constituted of the steering-wheel, brake and accelerator. The combinatory operations of brake mechanism and accelerator mechanism of the “Auto-LDO” can have the smooth and fast transition without overshoot in the startup and POS Power-On-Sequence. A Green Energy Smart Window Wireless Window 5R System W5RS further comprises a overshootless LDO. It has the brake module to deliver overshootless output power during the startup process. The overshootless LDO has one error amplifier. The error amplifier has the steering wheel function module and voltage divider. The voltage divider divides the output voltage to generate a feedback voltage V_{FB}. The error amplifier has a reference voltage V_{BG} and the feedback voltage V_{FB} been connected as inputs. As the feedback voltage V_{FB} is less than the reference voltage V_{BG}, a switch MOS connects the reference voltage V_{BG} input with feedback voltage V_{FB} input.

There are two orthogonal conjugated accelerator modules. The accelerator modulates the biasing current in the error amplifier. As the feedback voltage V_{FB} is not equal to reference voltage V_{BG}, we increase the bandwidth of the error amplifier to speedup the error amplifier. FIG. 26H is the alternative design with trans-impedance cascade amplifier. The trans-impedance cascade amplifier can reduce the ripples of digital circuit to be rippleless LDO.

FIG. 27 shows how the Noise Isolation Technology is applied to the conventional chip to serve as IP with the wrapper structure. FIG. 27A is the general Noise isolation Technology architecture. FIG. 27B is the general waxed-signal type chip which integrates all the RF/AF/Analog with Digital/FPGA. FIG. 27C is the wrapper structure of the IP of the current regulator. It wraps around the mixed-signal type chip.

FIG. 28 shows the details of the general nixed-signal chip. It illustrates the state of art of semiconductor industry, A|D represents analog to digital conversion A/D and/or digital to analog conversion D/A. S|P represents serial to parallel conversion S/P and/or parallel to serial conversion P/S. The FPGA has merged the logic, Digital Signal Processor DSP, the Serial/Parallel and Parallel/Serial two-way Conversions S|P together. The Radio Front RF, Analog Front AF, the Analog to Digital Conversion (ADC) and Digital to Analog Conversion (DAC) A|D are excluded due to the substrate noise. As shown in FIG. 28B, it is the A|D overlapping waveform of the analog input and digital output. As shown in FIG. 28C, it is the logic signal of the S|P in the analog wave form. The A|D signal steps are much smaller than the S|P logic signal. The small A|D signal steps make the A|D is much more susceptible to the substrate noise. The FPGA has a lot digital circuit and injects a lot of switching noise into the substrate. Even worse, the higher frequency is, the higher slew rate is, the larger switching noise is, the lower the circuit performance is. The substrate switching noise forbids the integration, of the high speed and high performance A|D. So, today the FPGA only can integrate the S|P and low speed and low performance ADC. Even for the low performance ADC, the embedded controller still needs to shut down all the digital circuit during the ADC operation.

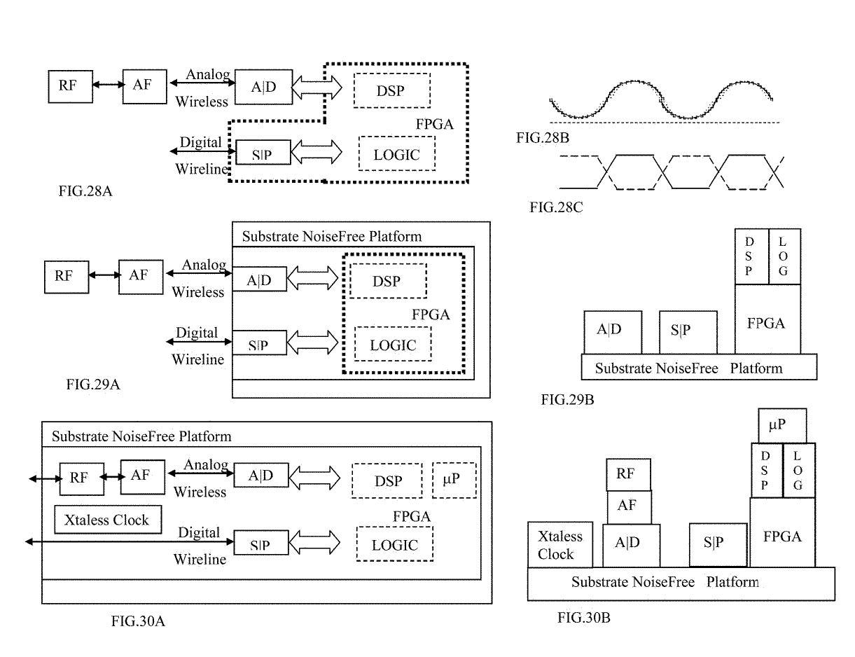

For the signal path, after A|D, it is the DSP. For the logic path, after S|P, it is the combinatory logic. As shown in FIG. 28A, today FPGA only can integrate DSP, S|P and Logic circuit. As shown in FIG. 29A, with our novel Noise Isolation Technology, the A|D of ADC and DAC can be integrated into FPGA. FIG. 29B shows the Noise Isolation Technology is the platform to integrate the A|D, S|P, FPGA, DSP and Logic all together.

A Green Energy Smart Window comprises the field programmable gate array FPGA, the ADC and DAC conversion between analog and digital. The Green Energy Smart Window integrates the FPGA, the ADC and DAC on the platform made of noise isolation technology to be field programmable system on chip FSOC.

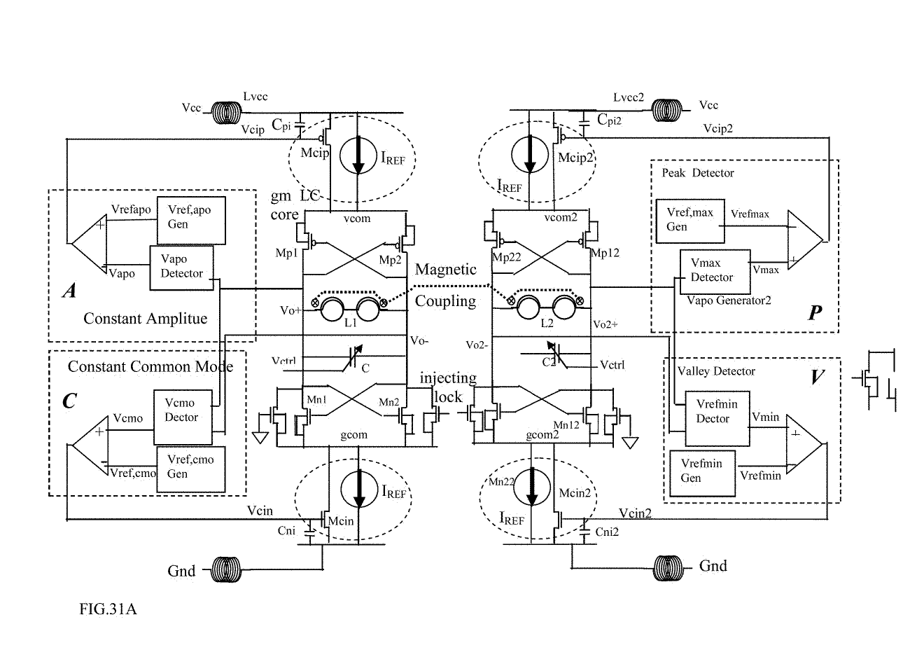

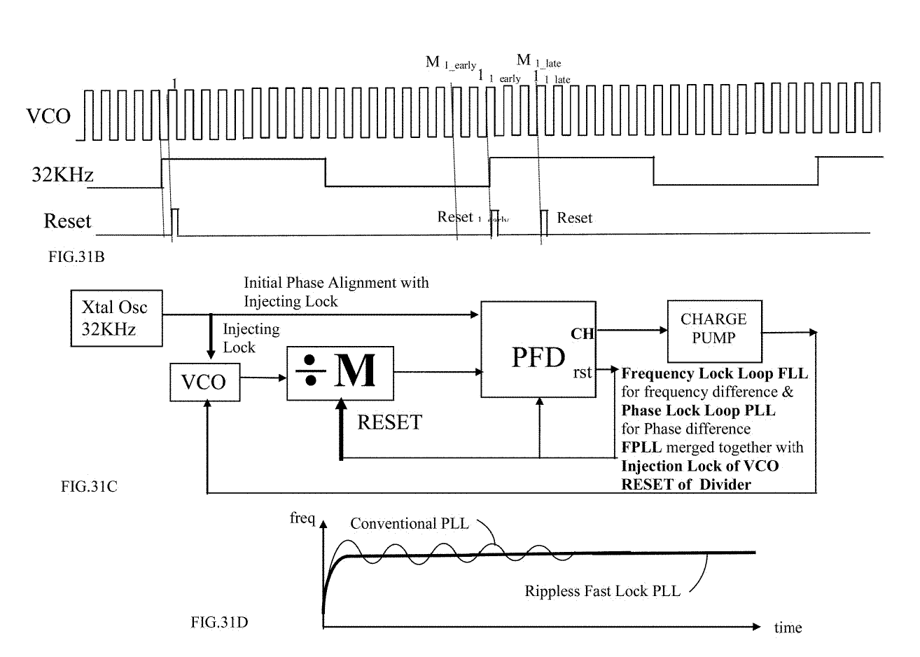

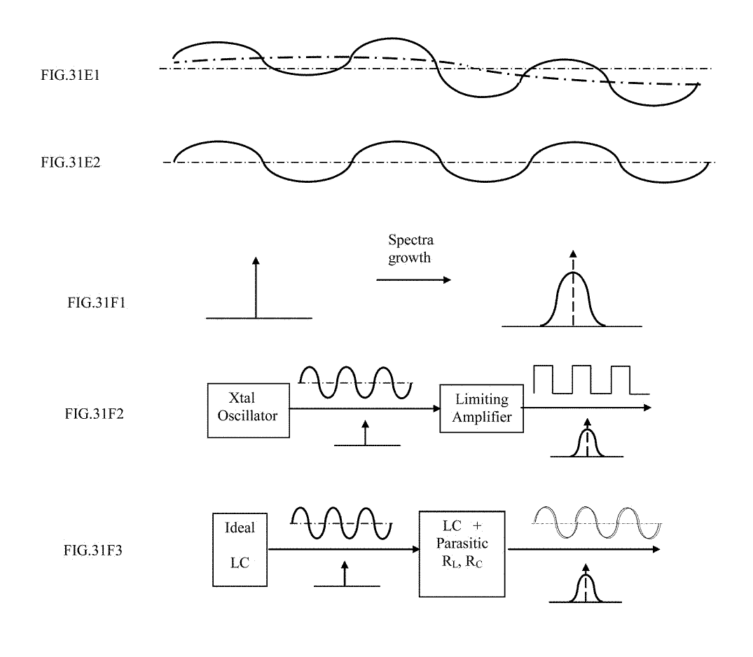

Furthermore, as shown in FIG. 30A, with our noise isolation technology, the RF and AF are all integrated into one single chip FSOC. As shown in FIG. 30B, the Noise Isolation Technology is the platform for the FSOC. Both the ADC and the LC resonator of the Xtaless Clock are very sensitive to the substrate noise.

The Green Energy Smart Window comprises the digital signal processing DSP and the application specific integrated circuit ASIC. The ASIC can be the combinatory integration of the radio front RF, analog front AF, analog and mixed signal, etc. The Green Energy Smart Window integrates the ASIC with DSP on the platform made of the noise isolation technology to be field programmable system on chip FSOC. This DSP can be the, portion of FPGA. The ASIC is integrated with FPGA. The green technology integration system comprises microprocessor and the application specific integrated circuit ASIC. The Green Energy Smart Window integrates the ASIC and microprocessor to be the field programmable system on chip FSOC. This microprocessor can be the portion of FPGA that the ASIC is integrated with FPGA, too.

As shown in FIG. 27C, FIG. 30A and FIG. 30B, the Green Energy Smart Window has the noise isolation to be the platform. The noise isolation serves as wrapper to integrate the versatile combinations of application specific integrated circuit ASIC means, field programmable gate array FPGA means, conversion means between analog and digital, digital signal processing DSP, microprocessor means, RF/AF/Analog circuit and digital circuit to be field programmable system on chip FSOC.

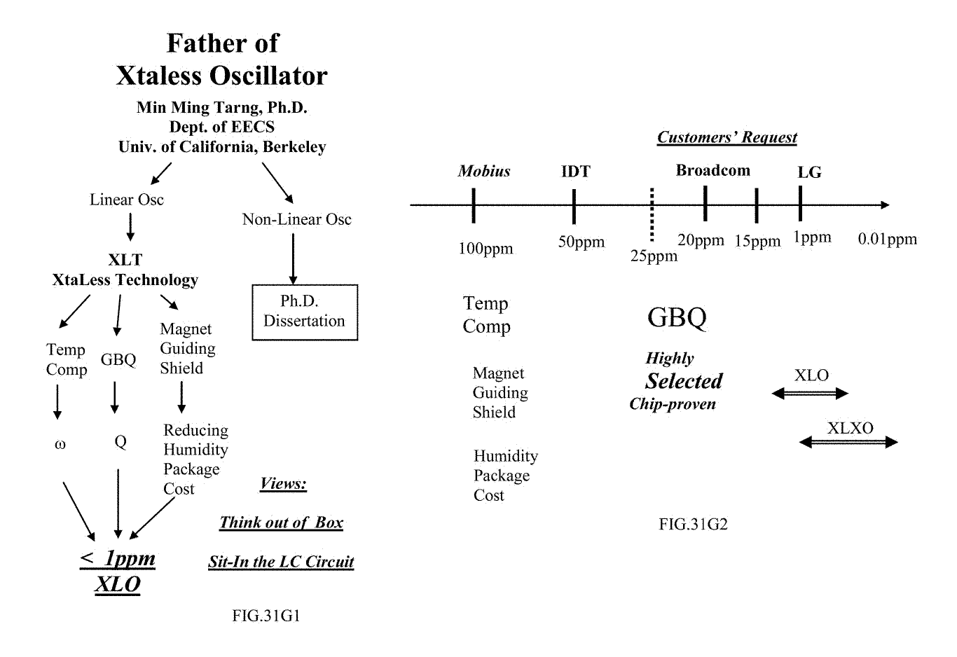

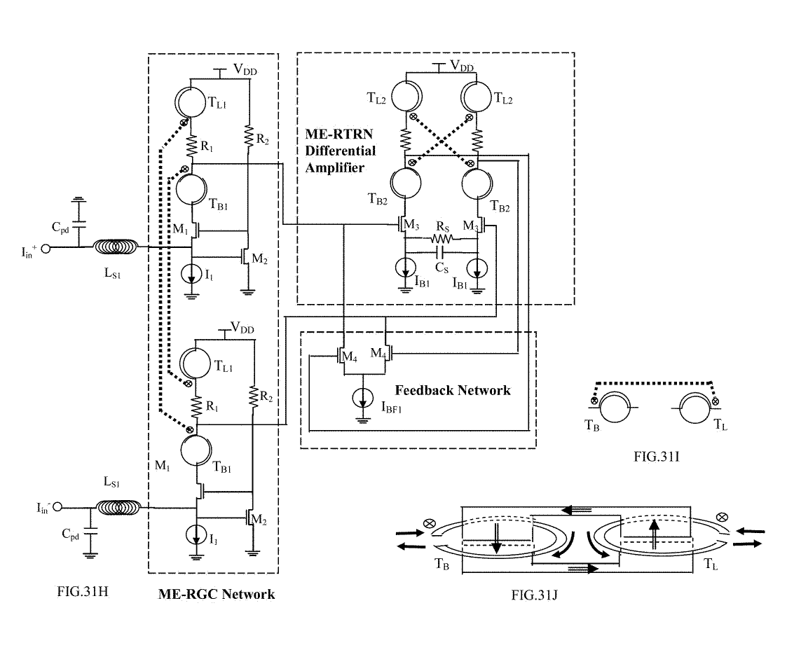

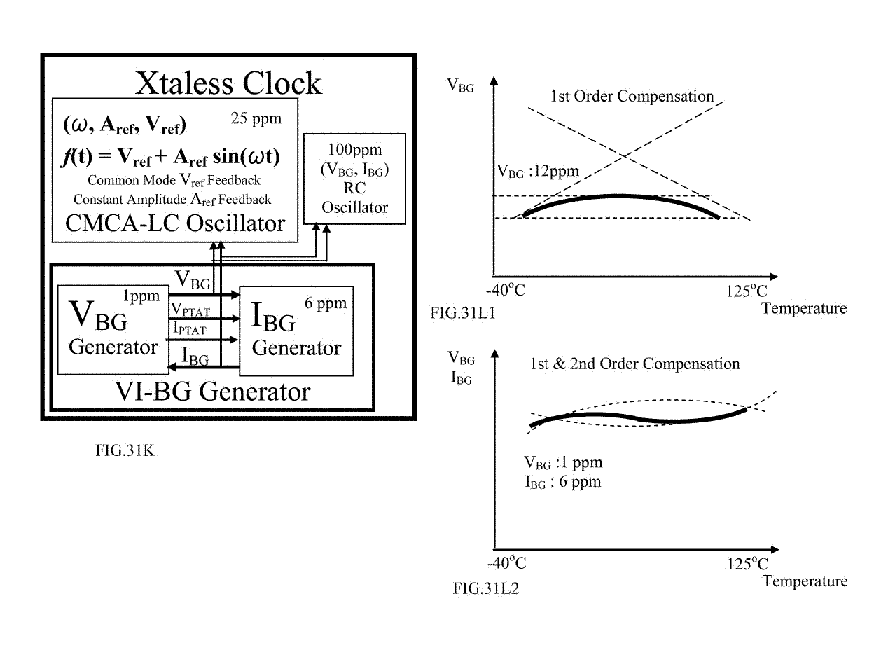

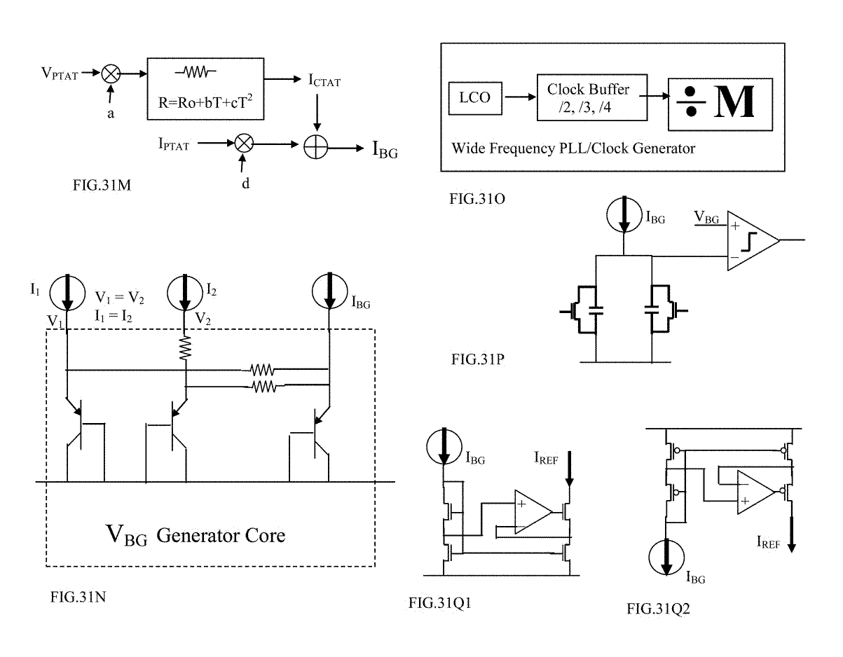

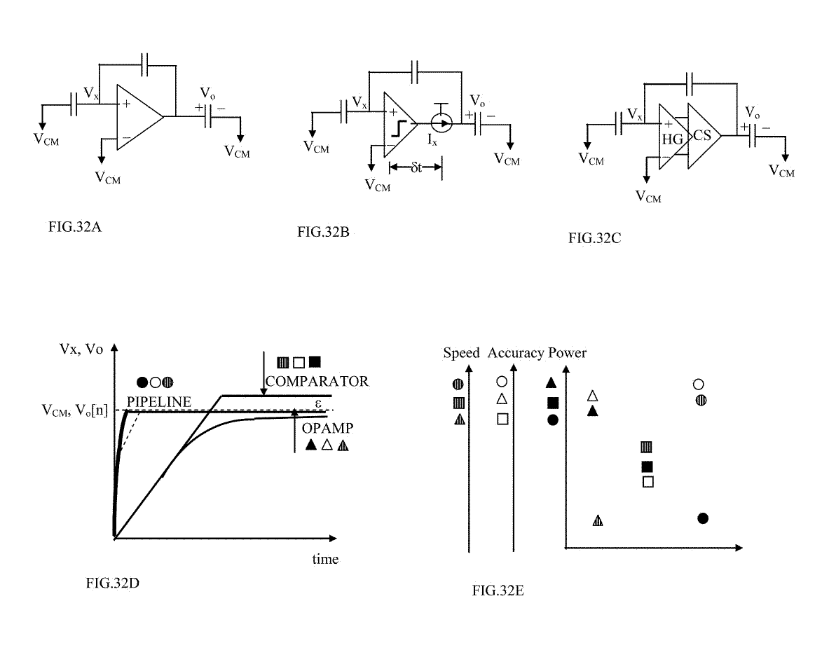

As shown in FIG. 31A, it is the combination of the FIG. 14G and FIG. 25B with the magnetic enhanced coupled inductor as shown in FIG. 31I and FIG. 31J. As shown in FIG. 14G and FIG. 31A, the Xtaless oscillator adopts the embedded Hybrid Current Regulator Noise Isolation technology. Furthermore, as shown in FIG. 24C, the LC resonator of the Xtaless Clock uses the Hybrid current regulator at both the power and ground layer to have the highest quality noise isolation. As shown in FIG. 31A, FIG. 31Q1 and FIG. 31Q2, the P-device and N-device marked with the dotted circle are corresponding to the P-type current regulator PCR and the N-type current regulator NCR. As shown in FIG. 15A, the LC resonator of the Xtaless Clock is located in the RF/AF/Analog Circuit region that adopts the embedded Hybrid current generator Noise Isolation Technology as shown in FIG. 31A.

The fundamental principle of the LCO equation is

f(i)=V_{REF}+A_{REF} sin(ωt)

In other words, to have the high accurate clock, it must have (ω, A_{REF}, V_{REF}) control parameter to control the LCO. The conventional LCO has only L and C to control the oscillatory frequency. It doesn't have the control of A_{REF} and V_{REF}. It generates a lot problems of jitter and phase noises. Therefore, as shown in FIG. 31A and FIG. 31K, the P-device of the hybrid current regulator is controlled by the amplitude control or maximum voltage control; the N-device of the hybrid current regulator is controlled by the common mode control or the minimum voltage control.

Furthermore,

V_{REF}=(V_{PEAK}+V_{VALLEY})/2

A_{REF}=(V_{PEAK}−V_{VALLEY})/2

Therefore, as shown in the left side FIG. 31A, the system of the combination of constant peak voltage feedback control and the, constant valley voltage feedback control is the same as the combination of constant peak voltage feedback control and the constant valley, voltage feedback control as shown in the right side FIG. 31A.

The modulation has the innovation of modulation from the amplitude modulation AM to frequency modulation FM. Similarly, the oscillator has the innovation of control from frequency control FC to amplitude control AC.

Modulation innovation. AM=>FM

Oscillator innovation: FC=>AC

Furthermore, we make he unified approach to generalize the passive circuit to be the active circuit as follow

passive circuit: Q=E(L,C)/R_{dissipative}
Damping Curve RC decaying envelop [symbol] Q

active circuit: Q=E(L,C)/[R_{dissipative}+(−R)]^{1/2}I²
Virtual Damping RC decaying envelop [symbol] Q

Constant Amplitude Control will boost-up the Q as follows.

(−R)>R_{dissipative}: amplitude/voltage envelop exponential grow

(−R)<R_{dissipative}: amplitude/voltage envelop exponential decay

(−R)=R_{dissipative}: amplitude/voltage envelop=const
−R : gain of circuit

Q=E(L, C)/{[(R_{dissipative}+(−R)]^{1/2}I²}=E(L, C)/0=∞

Constant Common Mode Control boost-up the Q

gain=f(operating point)=f(V_{baseline})

As the baseline wandering, the gain changes as R(t)!=constant

R_{dissipative}−R(t)!=0

Q=E(L, C)/{[(R_{dissipative}+(−R)]^{1/2}I²}!=E(L, C)/0!=∞

We need to have both Constant Amplitude Control and Constant Common Mode Control at the same time to guarantee to have R(t)=constant=R_{dissipative} and Q=∞

Constant Amplitude Control and Constant Common Mode Control

=>R_{dissipative}C(−R)

=>Q=∞

LC oscillator has the gain to oscillate. It also finds the active circuit has larger Q than the passive circuit. However, is not necessary to have the perfect matching of −R(t)=R_{dissipative} all the time.

Due to the relation of

R_{dissipative}+(−R)<R_{dissipative}

so the active circuit has larger Q than the passive circuit. However, Q!=∞. To have the perfect matching of −R(t)=R_{dissipative} all the time to have Q=∞ all the time. As shown in FIG. 31E1 and FIG. 31E2, we especially mention the Constant Amplitude Control and Constant Common Mode Control to be the gain-boost Q.

Furthermore, as shown in FIG. 31A, FIG. 31I and FIG. 31J, the inductor is the magnetic enhanced ME-LCO. The magnetic enhanced ME-LCO has magnetic enhanced inductor MEL. As shown in FIG. 31A, there are the magnetic coupling between two LCO. Being similar to the electronic injecting to increase the Q of LC oscillation, the magnetic coupling together between the two LCO is to have magnetic inject locking to increase Q of LC oscillation.

As shown in FIG. 31G2, the customer, Broadcom, requests the clock to have <20 ppm. The object of the Xtaless Clock is to replace the high-end Xtal Oscillator. It has to be the complete set of ultra-high-Q Xtaless LCO technologies.

Xtaless Clock is to replace Xtal Oscillator. As shown in FIG. 31G1, the Xtaless Technology actually came from ETC Berkeley and, developed by Dr. Min Ming Tarng in 1980. All the final f curves show the bandgap variation characteristics.

As shown in FIG. 31E1 and FIG. 31E2, LCO itself is the switching noise generator and causing baseline wandering.

As shown FIG. 31F1, FIG. 31F2 and FIG. 31F3, they show Spectra. Re-Growth. The Spectra Re-Growth is NOT always causes jitter. So, we need to separate the Waveform-Shaping Spectra Re-Growth and Jitter Noise Spectra Re-Growth.

RFIC design cares Waveform-Shaping Spectra Re-Growth. However, Clock cares Jitter Noise Spectra Re-Growth. So, it is wrong to use the PLL for RF Spectra Re-Growth to be the clock Jitter Noise Spectra Re-Growth.

As shown in FIG. 31F1, under the current Injection of the Active Device, the Sinusoidal Oscillatory Wave is not the idealized sinusoidal wave. There is the spectra-growth. However, for the periodic wave, it will not cause the Jitter.

As shown in FIG. 31F2 and FIG. 31F3, for the extreme case, both the xtal type output waveform have the same jitter, however, the spectra is completely different. It implies the failure of the current spectra approach and the successful of our Jitter approach with the modified spectra.

As shown in FIG. 31G1, it is the global innovation history of the Xtaless Clock Chip. As shot FIG. 31G2, it is the route map for the Xtaless Clock Chip.

As shown in FIG. 31B, FIG. 31C and FIG. 31D, the Wireless Window 5R System W5RS further comprises the Rippleless Fast Locked frequency phase lock loop FPLL. The Rippleless Fast Locked frequency phase lock loop FPLL comprises a clock-divider to divide clock and phase frequency detector PFD. The PFD generates the reset signal. As shown in FIG. 31C, it is the merge of Frequency Lock Loop t and the Phase Lock Loop with injection of VCO/LCO and the RESET of Divider. The reset signal resets the clock divider after the reset signal generated by the phase frequency detector PFD. To make the phase alignment, the Initial Phase Alignment is done with Injecting Lock of VCO/LOC. The Rippleless Fast Locked frequency phase lock loop FPLL has (1) the frequency lock mechanism embedded in the divider; and (2) the phase lock mechanism embedded in the PFD.

To have the multimedia window, the Optical Fiber SerDes might be adopted. The transimpedance amplifier TIA is the key issue of the Optical Fiber SerDes. Now, the bit rate is 100 Gb/s for one channel. In the next generation, it will target for 150 Gb/s. As shown in FIG. 31H, the differential amplifier is the core of the proposed transimpedance amplifier TIA architecture for 150 Gb/s. The differential TIA has the negative feedback network and ME-RGC magnetic enhanced regulate cascode input to achieve enhanced bandwidth. To achieve wide-band response shunt-series peaking inductors T_{L2} and T_{B2} are incorporated in the architecture. The peaking inductors can increase the bandwidth up to 10 times the uncompensated bandwidth by forming a ME-RTRN magnetic enhanced reverse triple resonant network. To improve the bandwidth more a capacitive degeneration network, RS-CS is employed to introduce additional peaking in the frequency response. The magnetic enhanced regulated cascode (ME-RGC) is used for broad-band TIA design in high-speed optical communication. The ME-RGC network is inserted between the input of differential amplifier and photodiode to attain wide band response. ME-RGC is essentially a common gate amplifier with a local feedback. The transistor M₂ with resistor R₂ forms the local feedback of RGC amplifies Local feedback herein acts as a common source amplifier which gets a small portion of input signal and creates a voltage at the gate of M₁. This signal is amplified at the output of M₁. Moreover, it increases the effective transconductance of common gate structure which reduces the input resistance. Reduction in input resistance isolates the input pole associated with large parasitic capacitance, Cpd from the bandwidth determination. As a result, the dominant pole of ME-TIA magnetic enhanced transimpedance amplifier is located within the amplifier rather than at the input node. To increase the bandwidth more, shunt peaking magnetic enhanced inductor T_{L1} and series peaking inductor L_{S1} are also incorporated in the ME-RGC structure. The negative feedback network formed by transistor M4 is implemented for further bandwidth enhancement. Feedback network increases the bandwidth by splitting the poles by stagger bandwidth tuning.

As shown in FIG. 31I, the magnetic enhanced circuit is implemented with the couple of the transformer type inductors. The dotted line is the magnetic coupling between the two inductors. As shown in FIG. 31J, the magnetic enhanced circuit has the magnetic conduction loop between the transformer type inductors. The circled cross symbol represents the magnetic couple, between two inductors having the pseudo magnetic flux/current connection between two coupled inductors.

As shown in FIG. 31L1, the conventional bandgap generator has the V_{BG} generator only. It has the linear curvation compensation to have (ΔV_{BG}/V_{BG}) to be 12 ppm. It cannot meet the requirement fur the high performance Xtaless Clock having Δff to be 25 ppm. Furthermore, on the chip, the resistor R has the temperature variance about 6%, 60000 ppm. However, the handgap current needs to be 6 ppm only. Therefore, we cannot get I_{BG} with the division of (V_{BG}/R).

As shown in FIG. 31K, the Xtaless clock comprises the Bandgap Generator and the LCO. The Bandgap Generator has both both the bandgap voltage V_{BG} and the Bandgap current I_{BG}. The V_{BG} generator has the output bandgap voltage V_{BG} feeding into the I_{BG} generator; the I_{BG} generator has the output handgap current I_{BG} feeding into the V_{BG} generator. The BG bandgap generator comprises of a coupling pair (V_{BG}, I_{BG}). It is noted that V_{BG} are I_{BG} coupled to generate the bandgap references. Theoretically, with I_{BG}=constant, we cart have V_{BG}=constant. Due to the non-ideal situations in the real world, with the coupling pair (V_{BG}, I_{BG}), as shown in FIG. 31L2, the BG bandgap generator can generate the VBG having the variance of (ΔV_{BG}/V_{BG}) to be 1 ppm and the IBG having the variance of (ΔI_{BG}/I_{BG}) to be 6 ppm.

The conventional VBG generator has the V_{BG}, V_{PTAT} and I_{PTAT} to be output. As shown in FIG. 31M, the IBG generator has the inputs of V_{BG}, V_{PTAT} and I_{PTAT}. The coefficients a, b, c, d are the parameters. The on-chip resistor R has the temperature dependent coefficients, R=Ro+bT+cT². With the (a*V_{PTAT}/R) cancelling the bT effect of R, the output current becomes the low order nonlinearity. With the summation of (d*I_{PTAT}/R) and I_{CTAT}, we can get I_{BG}.

As shown in FIG. 31N, the bandgap current I_{BG} is fed back to the V_{BG} Generator Core. Theoretically, with I_{BG}=constant, we can have V_{BG}=constant. However, due to the nonideality of I_{BG} as shown in FIG. 31L2, with the I_{BG} generator we can get I_{BG} having (ΔI_{BG}/I_{BG}) to be 6 ppm over the PVT corners with temperature varying from −40° C. to 125° C. Accordingly, we can get V_{BG} having (ΔV_{BG}/V_{BG}) to be 1 ppm over the PVT corners with temperature varying from −40° C. to 125° C.

The complete set description of the sinusoidal oscillation is

f(t)=V_{ref}+A_{ref} sin(ωt).

Therefore the LC oscillator has three dominating factors, (ω, A_{REF}, V_{REF}).

For V_{REF}=constant, we adopt the Common Mode V_{REF} Feedback.

For A_{REF}=constant, we adopt the Constant Amplitude A_{REF} Feedback.

The clock generator is to have the ω=constant, A_{REF}=constant and V_{REF}=constant. As shown in FIG. 31A and FIG. 31K, the xtaless clock comprises (1) the common-mode-constant-amplitude CMCA LC oscillator; and (2) the bandgap coupling pair (V_{BG}, I_{BG}) BG bandgap generator.

As shown in FIG. 31K, the Xtaless Clock is costituted of the CMCA-LC Oscillator and VI-BG Generator. The xtaless clock has (Δff) to be less than 25 ppm over all the PVT corners with temperature varying from −40° C. to 125° C. Due to the layout area constraint, the LCO has the defect of narrow frequency range. To have the wide frequency range, as shown in FIG. 31O, the clock buffet has the programmable dividers 2/3/4 that the LCO can operate at high frequency to have smaller layout area.

For the low power and low frequency clock, the Xtaless clock is made of the RC oscillator and the coupling pair (V_{BG}, I_{BG}) BG bandgap generator. As shown in FIG. 31K and FIG. 31P, the RCO type Xtaless Clock uses the V_{BG} and L_{BG} as the reference inputs. As shown in FIG. 31A, FIG. 31N and FIG. 31P, for the high performance timing products such as clock generator, the current buffer is made of the high accurate current mirror as shown in FIG. 31Q1 and FIG. 31Q2. With, the high gain amplifier to equalize the V_{DS} voltage, the reference MOS and the mirrored MOS has exactly the same V_{GS} and V_{DS} that the current mirror has very accurate value.

As shown in FIG. 32A, it is the conventional OPAMP embedded in the Multiplying DAC, MDAC of ADC. The high-speed and high-performance ADC converter adopts the pipeline architecture. The MDAC is the analog circuit which consumes a lot of power and determines the speed of the conversion. The key issue is to increase the conversion speed at the high resolution and reduce the power consumption. These are conflict goals. The solution is the dynamic switching type analog circuit.

There are A type OPAMP and AB type OPAMP. At the steady state, they both consume DC current. The biasing current serves as both the switching current and biasing current. They treat the OPAMP as a whole circuit. As shown in FIG. 32B, at beginning, the Vx is the slew rate to approach V_{CM}. Finally, it is the RC delay of C/gₘ for Vx to approach V_{CM} where gₘ is the gain of the small signal. As shown in FIG. 32B, it, is the comparator in the MDAC. There is a constant current source which is corresponding to the slew rate of the OPAMP in the conventional MDAC. It is just to eliminate the RC delay of C/gₘ with the constant current source which is the duplicate of the biasing current. However, it is at the cost of losing the accuracy. There is the comparator switching delay which causes the inaccuracy of the Vx. Even with the delay compensation techniques for the deviation n, this inaccuracy is still uncertain. It is impossible to have the accuracy, Vx=V_{CM}.

The FPGA having the Low power pipeline ADC with pipeline buffer will enable the merge the industrial ASIC with FPGA to be the green technology FSOC. As shown in FIG. 32C and FIG. 32F, the pipeline OPAMP adopts the dynamic switch technique in both High Gain HG OPAMP stage and Clamping Switch CS output stage. Referring to FIG. 32F, the green technology integration system comprises the pipeline buffer ADC. The pipeline buffer ADC is constituted of the high gain operational amplifier stage and dynamic switching output stage. The Dynamic Clamping Switch DS OUTPUT has the digital switching effect to drain a large amount current. So, the slew rate of the pipeline OPAMP is dynamic and is not limited by the biasing current. As shown in FIG. 32D, the dynamic switch of the pipeline OPAMP has the much higher slew rate due to the dynamic switch of the DS output stage. At the smell signal stage, due to the clamping mechanism having much higher gain, the settling time is much faster and having the highest accuracy. FIG. 32E is the MDAC comparison result of the pipeline OPAMP, the comparator and the conventional OPAMP. The MDAC made of the pipeline OPAMP has the highest speed, highest accuracy and the least power.

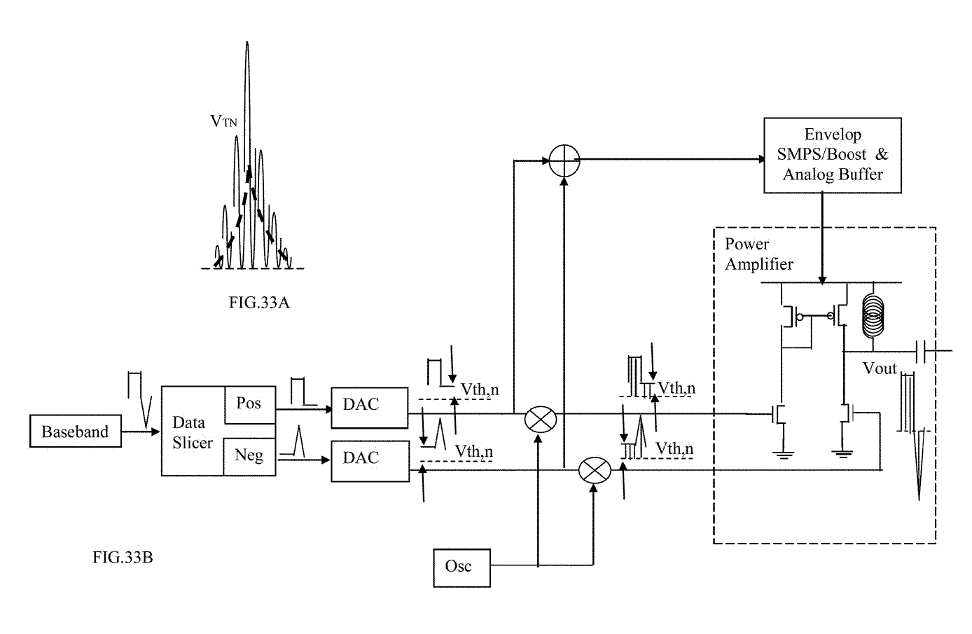

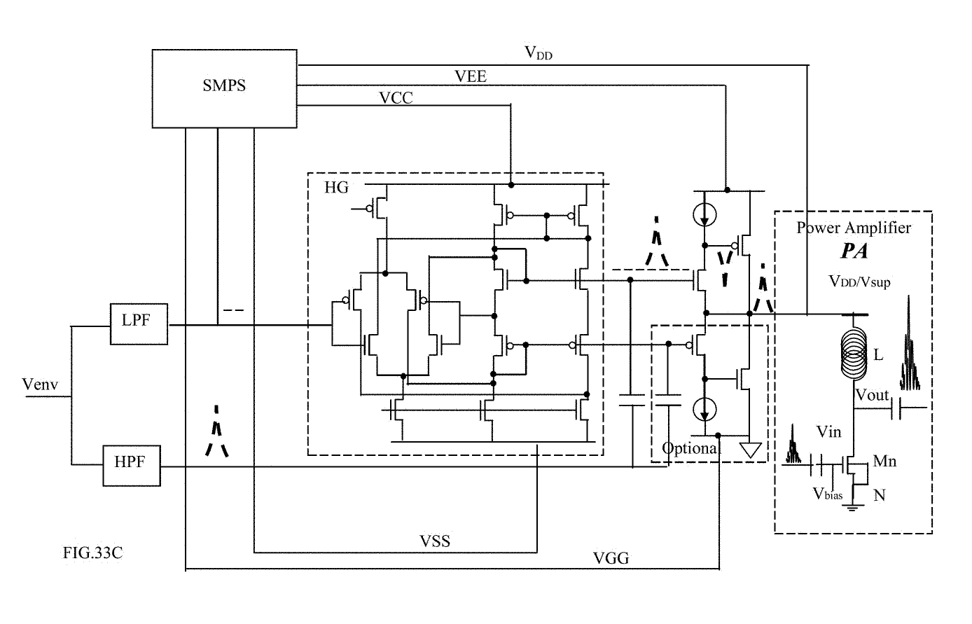

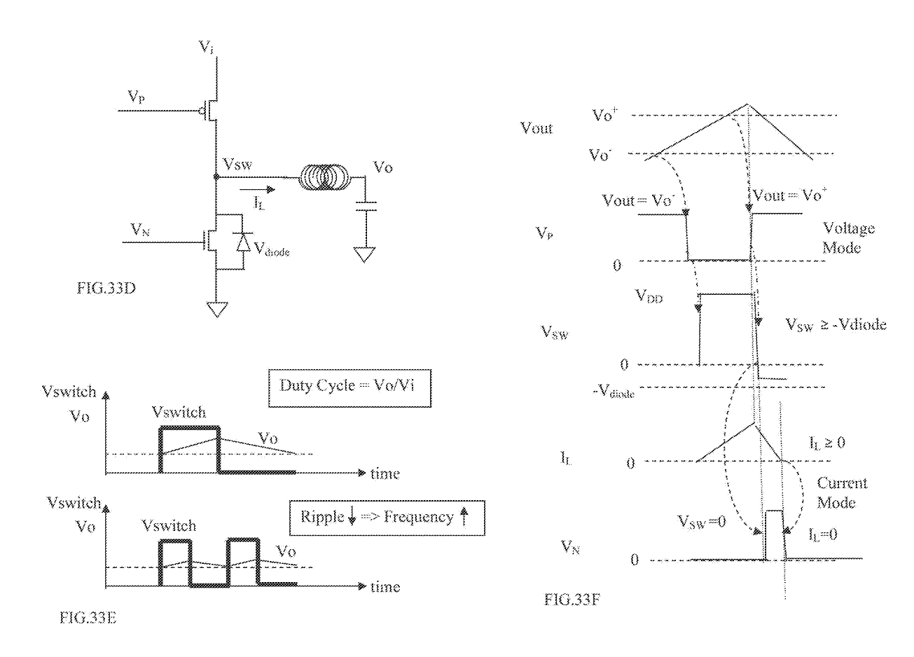

As shown in FIG. 1A, there is the need for the wireless connection for the Green Energy Smart Window. The most power consumption for the high Peak-Average-Ratio PAR wireless signal in FIG. 33A is the power amplifier. We need to use the dynamic power supply to reduce the power consumption of the power amplifier. A green technology integrated system comprising RF Power Amplifier dynamic power supply. The RE Power Amplifier dynamic power supply has boost converter and Low Drop Voltage Regulator LDVR type analog buffer power supply. Referring to FIG. 33C, the green technology integration system comprises the RF Power Amplifier dynamic power supply. The RE Power Amplifier dynamic power supply has the Low Drop Voltage Regulator LDVR type analog buffer power supply.

The Green Energy Smart Window 5R System W5RS further comprises a high-power-efficiency conjugated power amplifier. The conjugated power amplifier takes analog signals of positive sliced data and negative sliced data to operate at amplifier B mode and/or amplifier C mode. As shown in FIG. 33B, the baseband generates the data to be transmitted by the power amplifier. The data slicer slices the transmitted data to be the positive and negative data streams. The DACs converts the positive and negative data streams to be the analog signal with the voltage level shift of Vth,n. The oscillator generates the high frequency carrier signals to carry the baseband analog signals to be the RF signal having the zero signal level to be Vth,n. Then the positive and negative modulated RF signals are fed into the dual conjugated power amplifier which is operated between the modes of amplifier B and amplifier C with the fidelity of class A. Class-A is exceptionally linear, and forms the basis of many more complex circuits. Class B has a maximum theoretical efficiency of π/4, (i.e. 78.5%). therefore, as shown in FIG. 33B and FIG. 33C, the W5RS Green Energy Smart Window 5R system has the dual conjugated power amplifies with the envelop tracing power supply. The green energy smart Window 5R System W5RS comprises a high-power-efficiency conjugated power amplifier system. The conjugated power amplifier takes analog signals of positive sliced data and negative sliced data to operate at amplifier B mode and amplifier C mode. The data stream coining from baseband is sliced to be positive sliced data and negative sliced data. Two separate DACs converting the positive sliced data and the negative sliced data to be two separate analog signals of positive sliced data and negative sliced data.

As shown in FIG. 33D, FIG. 33E and FIG. 33F, the Switch Mode Power Supply SMPS adopts the Adaptive Optimum Constant On Time AOCOT operation to have the best power efficiency. To be simple to explain, FIG. 33D is the output stage of buck converter the same principles, can be applied and extended to the other type SMPS. FIG. 33F shows the fundamental principle of the SMPS buck converter. The duty cycle is determined by the ratio of the voltage. Assume the input supply voltage is fixed, the duty is determined by the output voltage Vo only. The frequency is determined by the ripple amplitude ΔVo. To have the adaptive optimum operation, we use the equivalent relations.

Vo+=Vo+ΔVo/2

Vo−=Vo−ΔVo/2

Therefore, we might use Vo+ and Vo− to have the optimum operation. This is the voltage mode to control the switch voltage of the PMOS power supply charging device.

For the energy recycling operation of recycling NMOS device, as current I_{L}=0, the recycling NMOS will be shut off. As the switch out node VSW is zero, the current I_{L}>0, the NMOS device is turned on. This is the Current mode for the NMOS power recycling device.

For the adaptive optimum constant on time operation AOCOT of SMPS, we use the hybrid operation of (1) the switch of PMOS with voltage mode control for switch voltage VP and (2) the switch of NMOS with current mode control for switch voltage VN. The constant on time COT is adaptive to the buck converter operation to have the optimum value automatically.

The green energy smart window is an Intelligent Graphic Unit IGU. The Intelligent Graphic Unit IGU father comprises battery, thin-film battery and/or electrochromic window and transparent solar window/panel. The transparent solar window/panel provides electricity to the battery, thin-film battery and/or electrochromic window to be self-sustained IGU. Since the solar window/panel is transparent, the solar window/panel has the fill factor to be 100% to cover the whole fame of IGU. It can generate electricity supplying the smart window and the smart home.

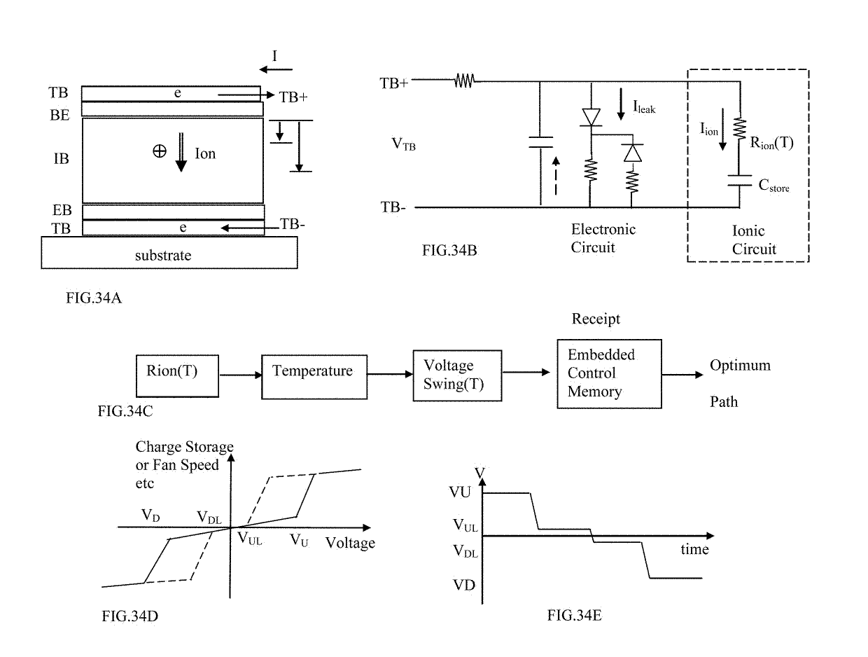

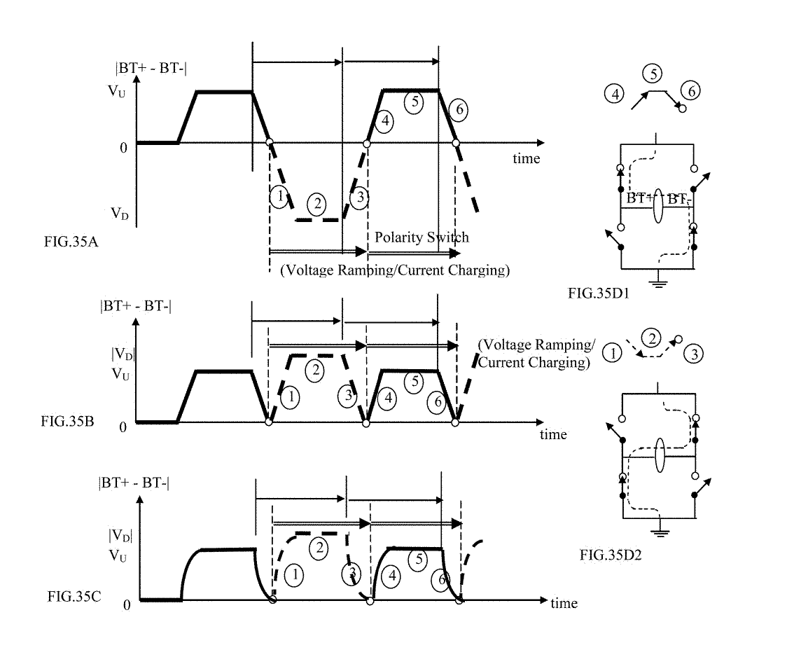

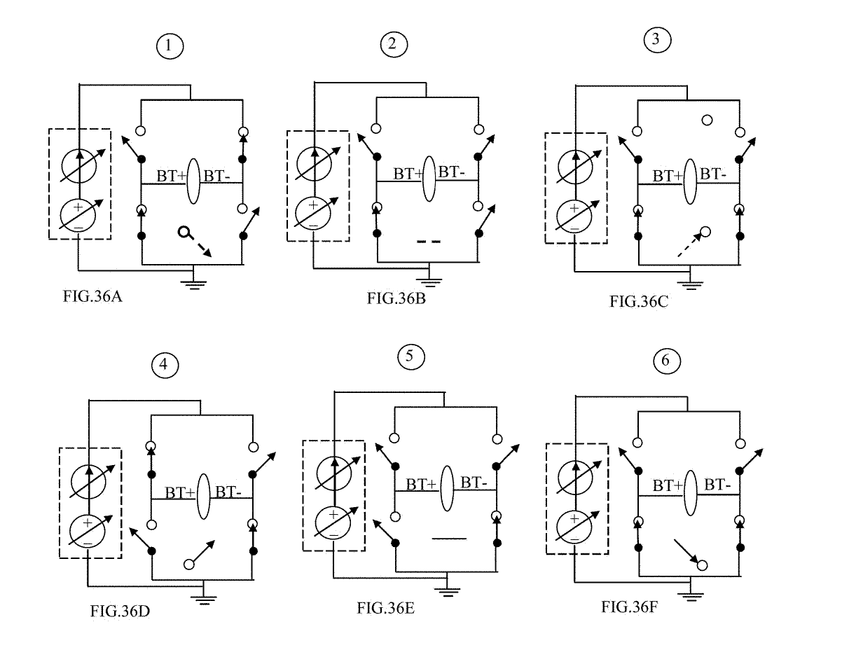

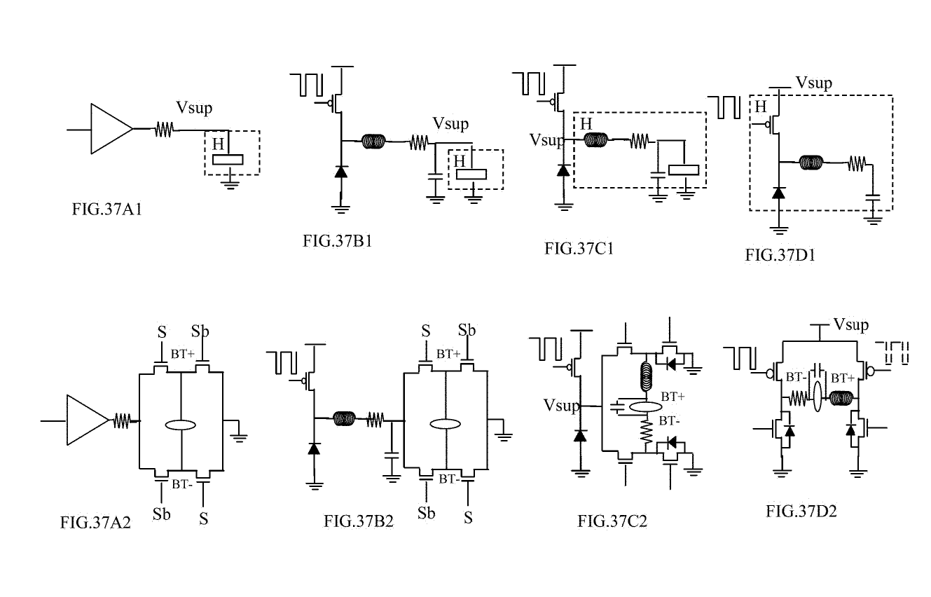

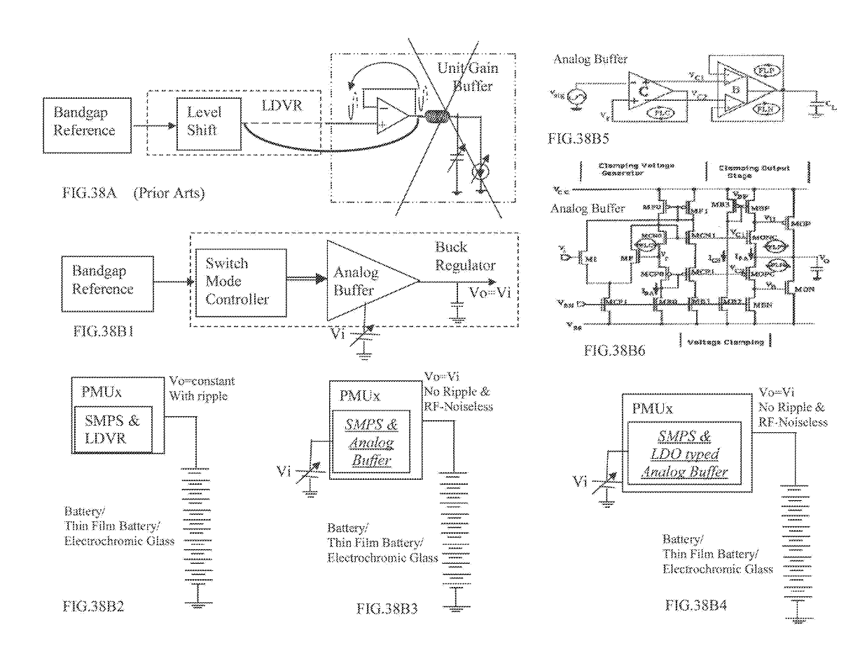

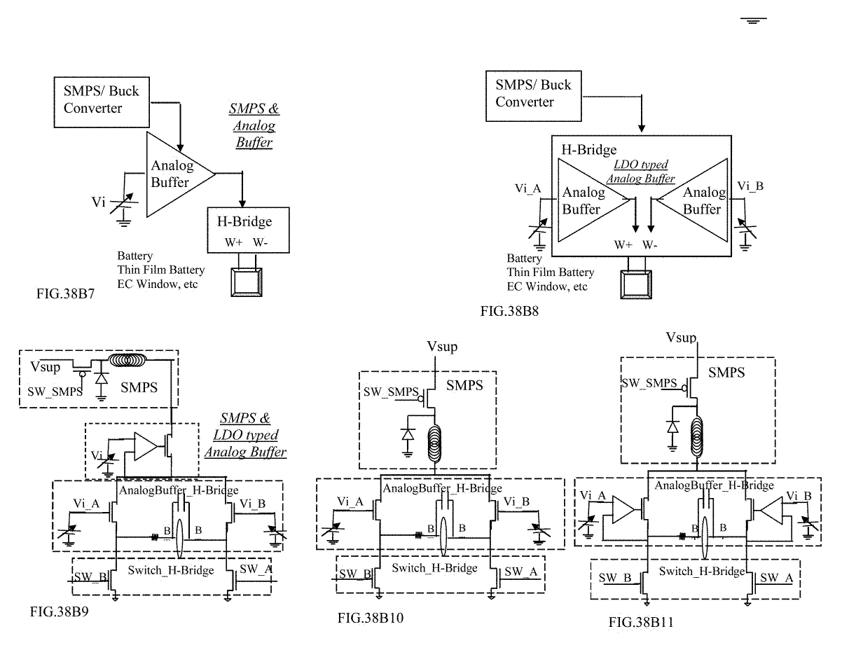

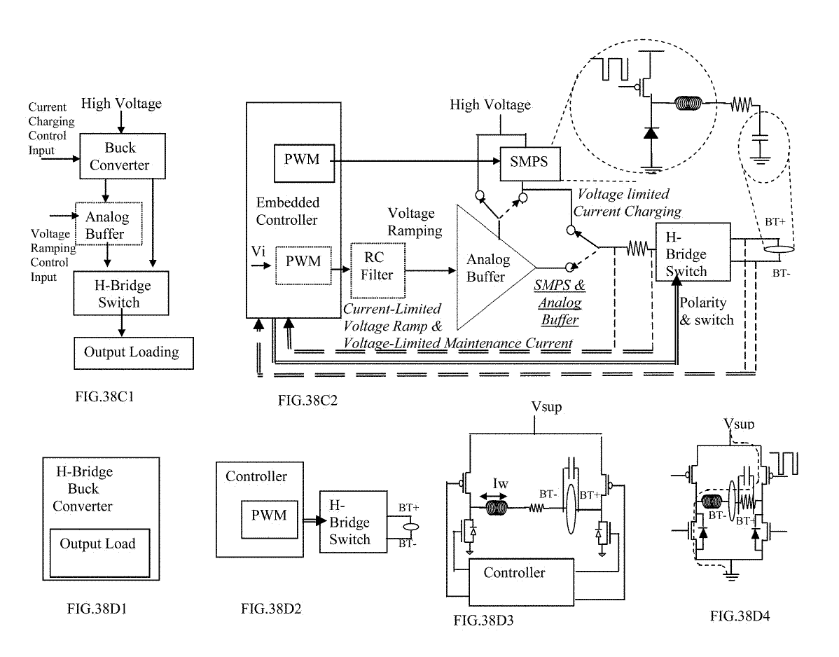

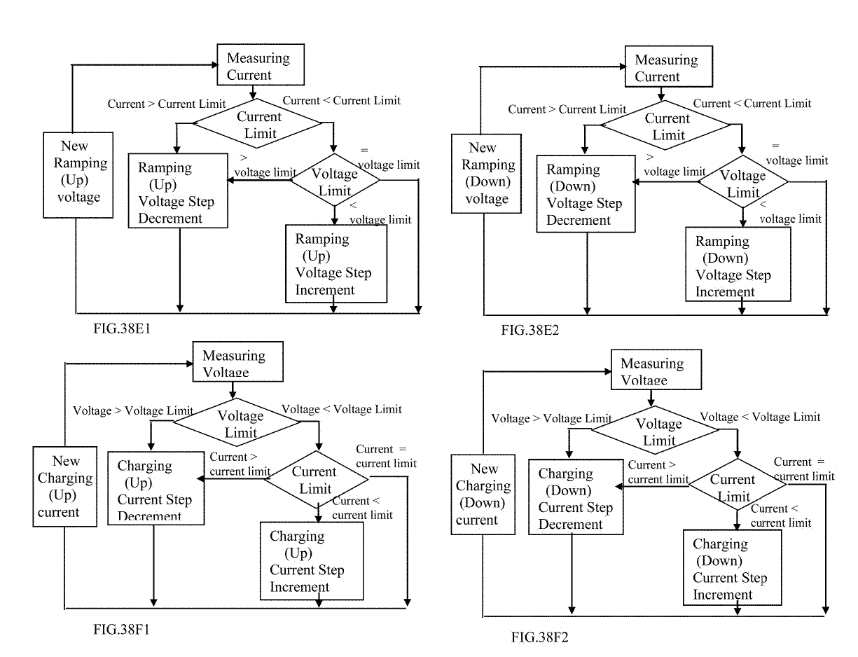

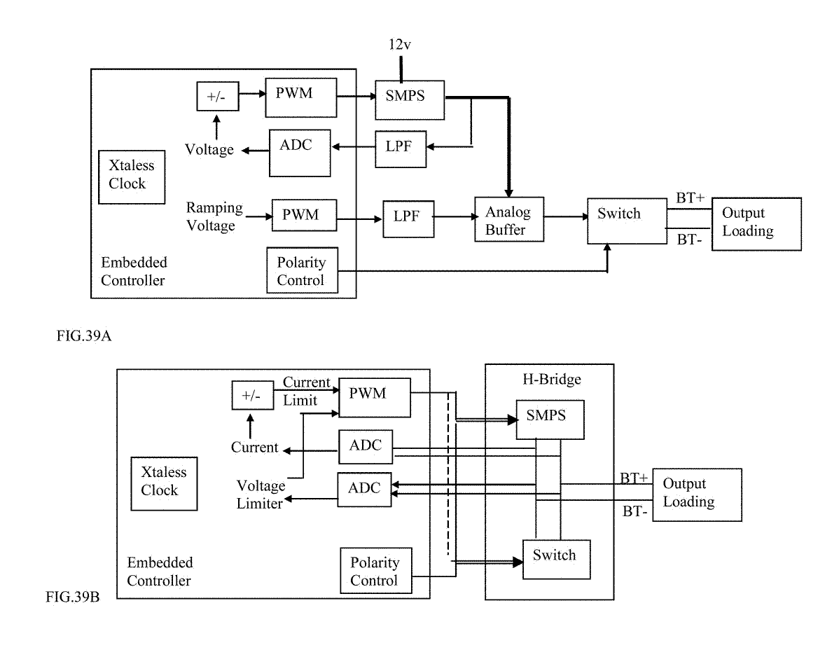

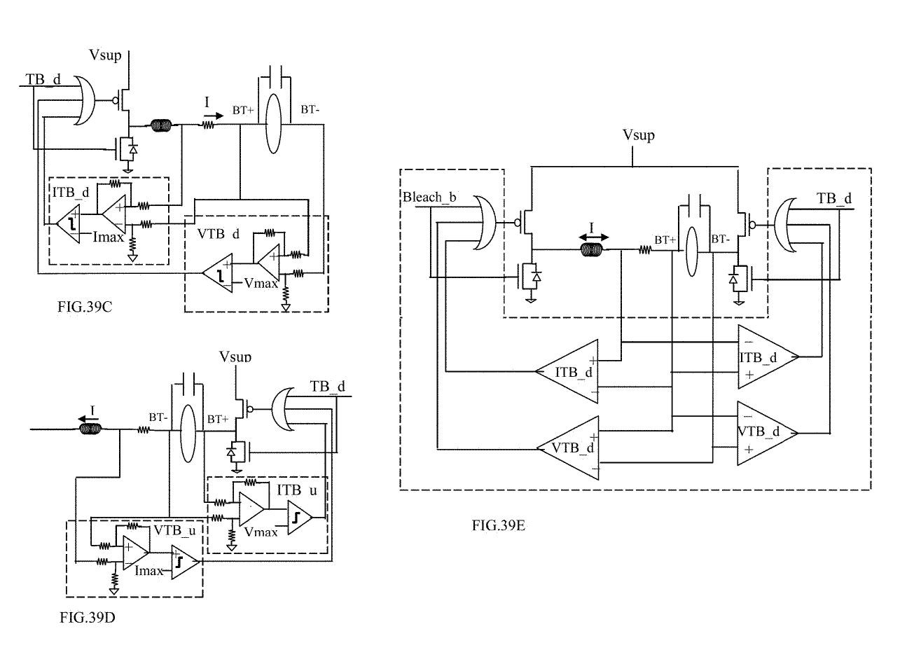

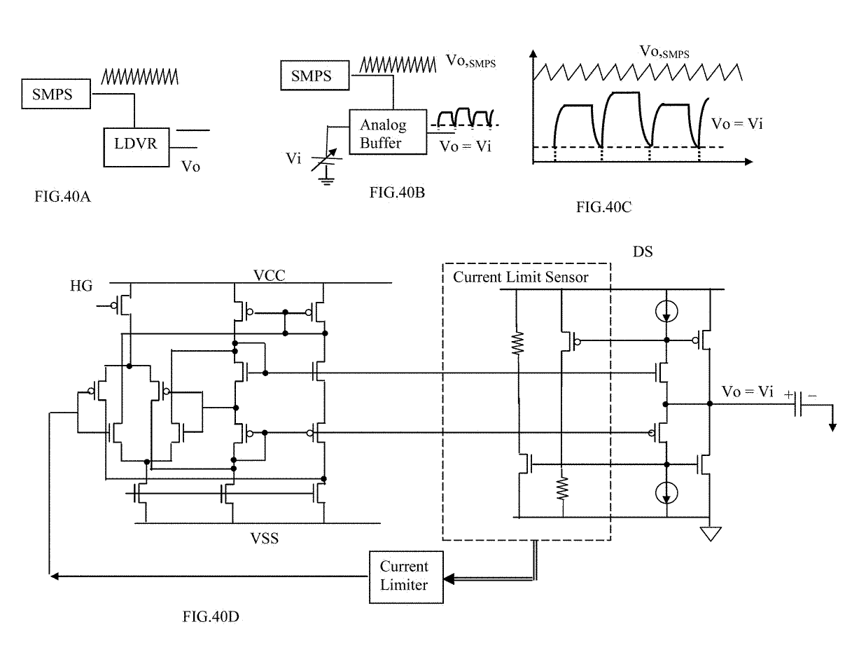

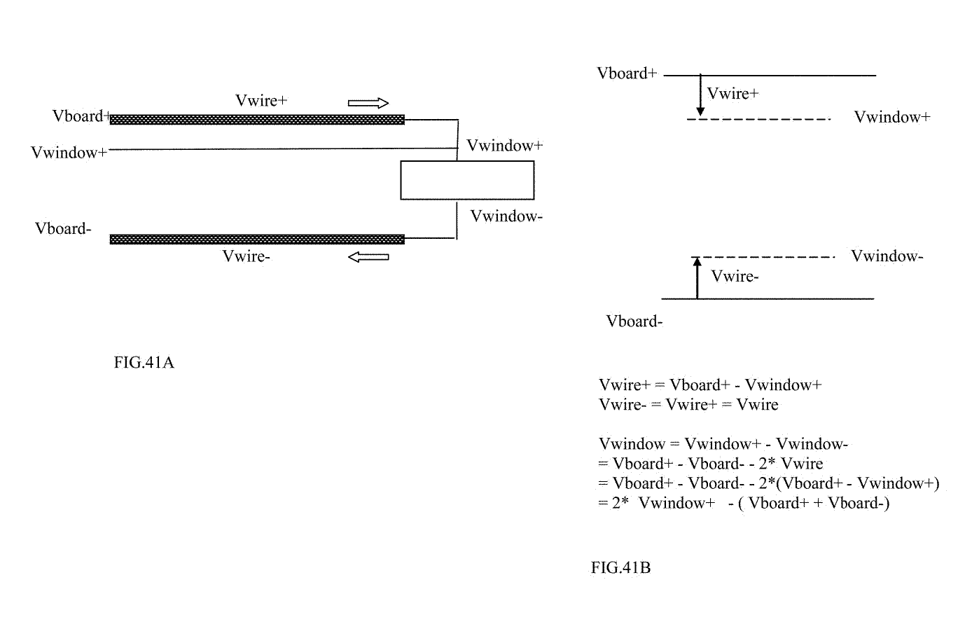

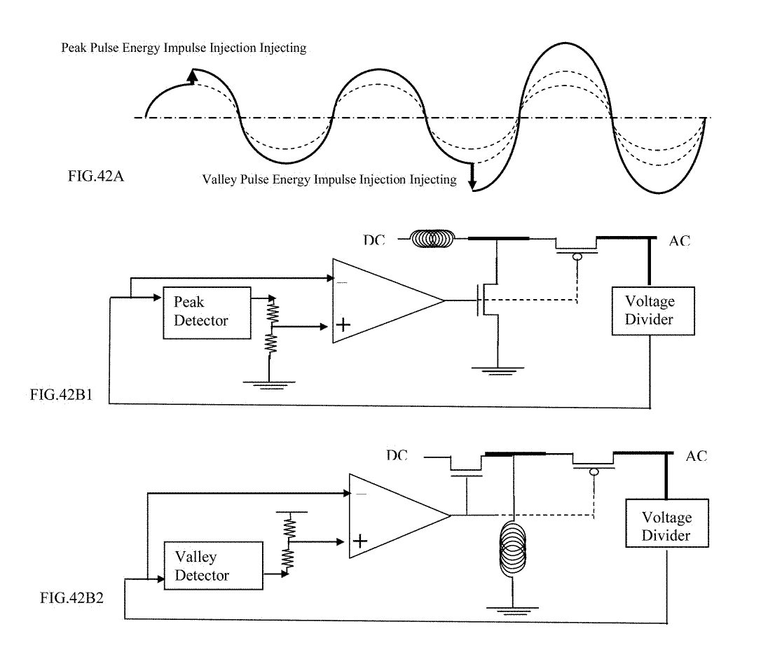

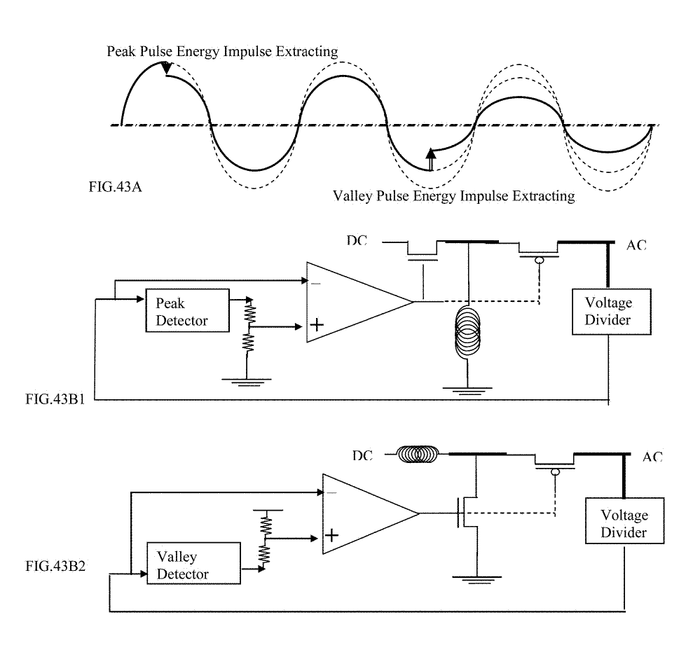

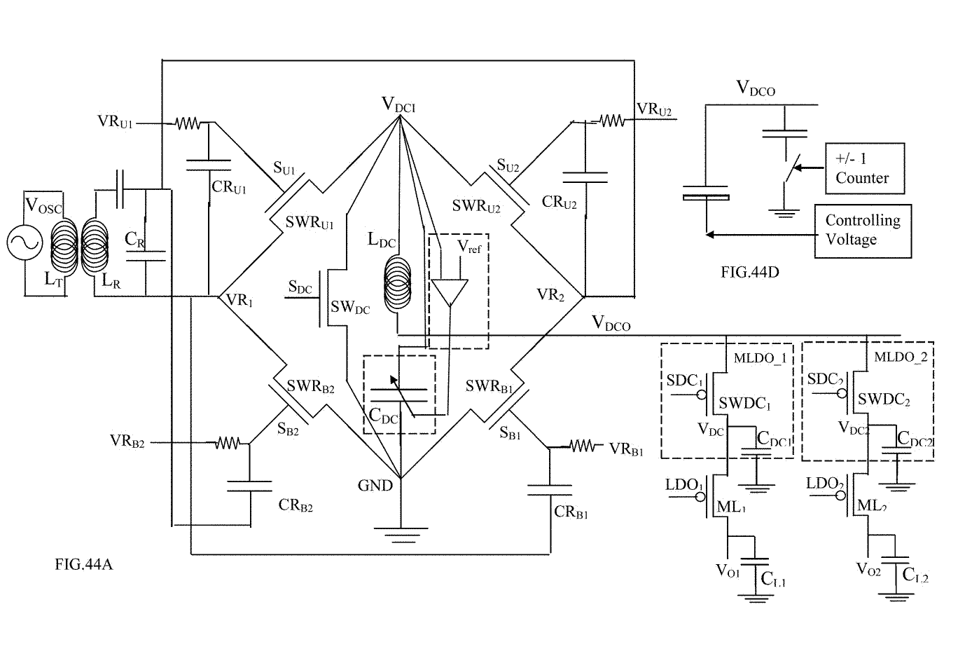

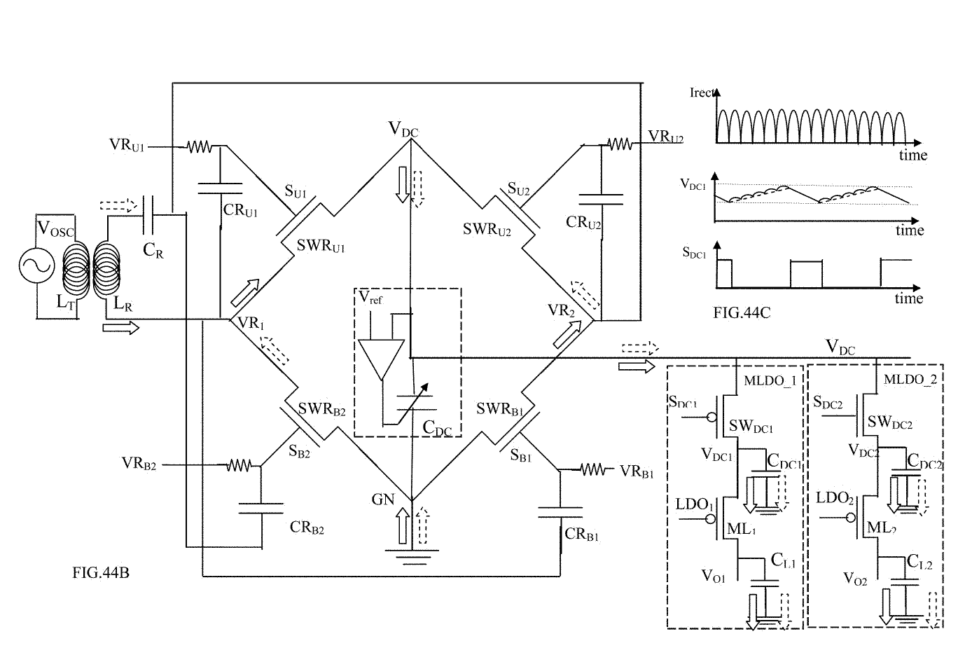

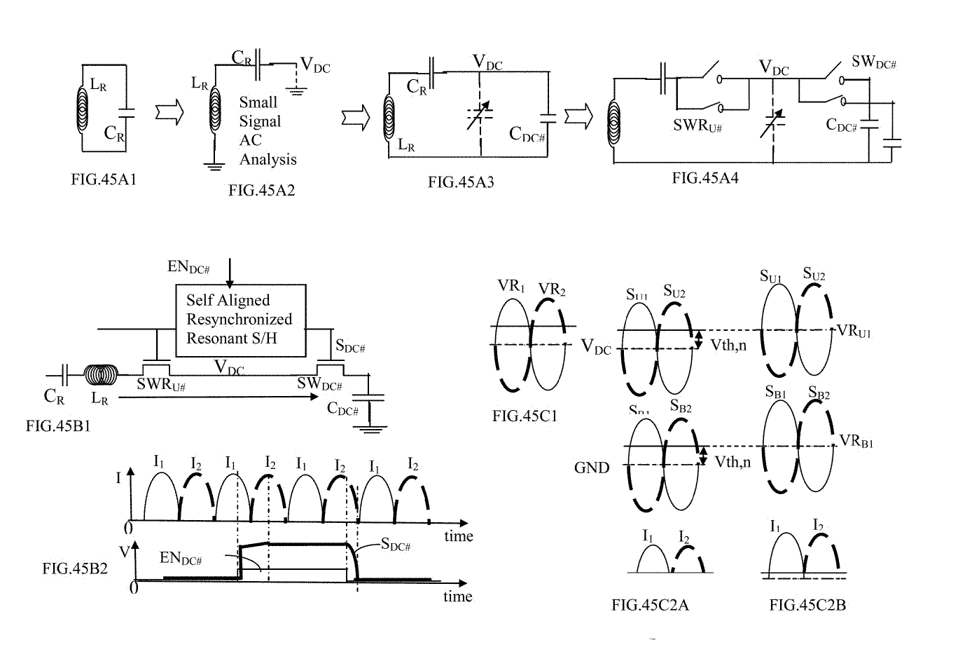

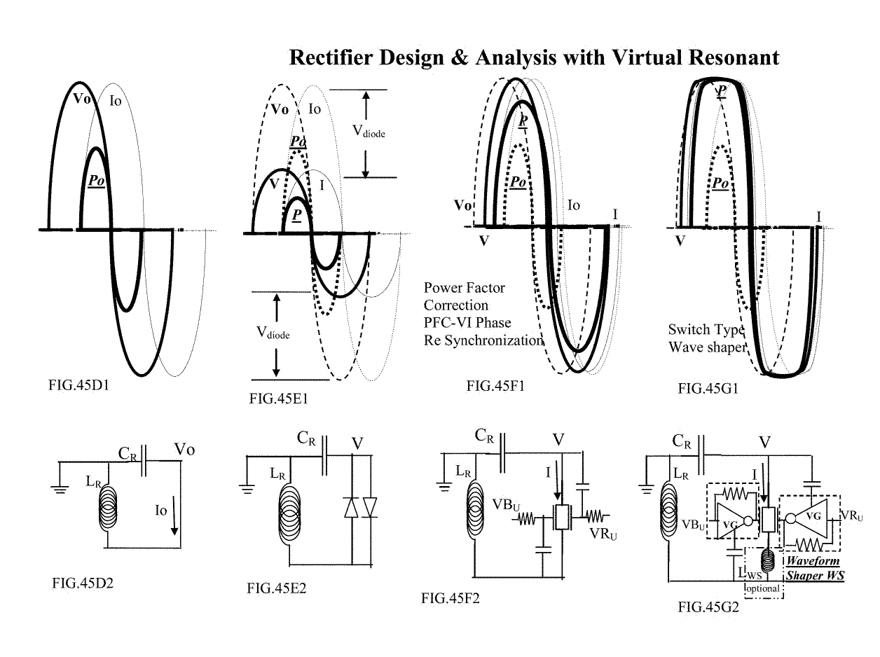

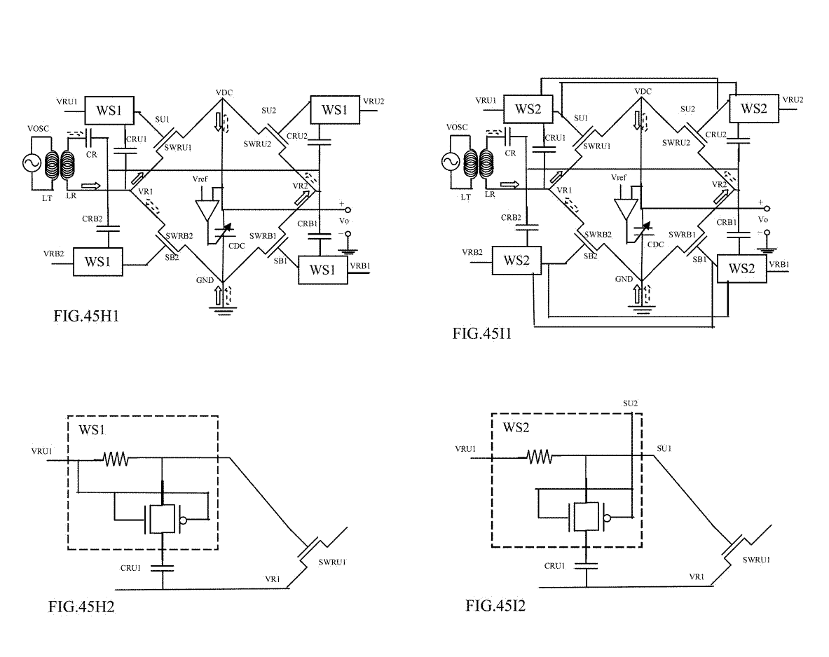

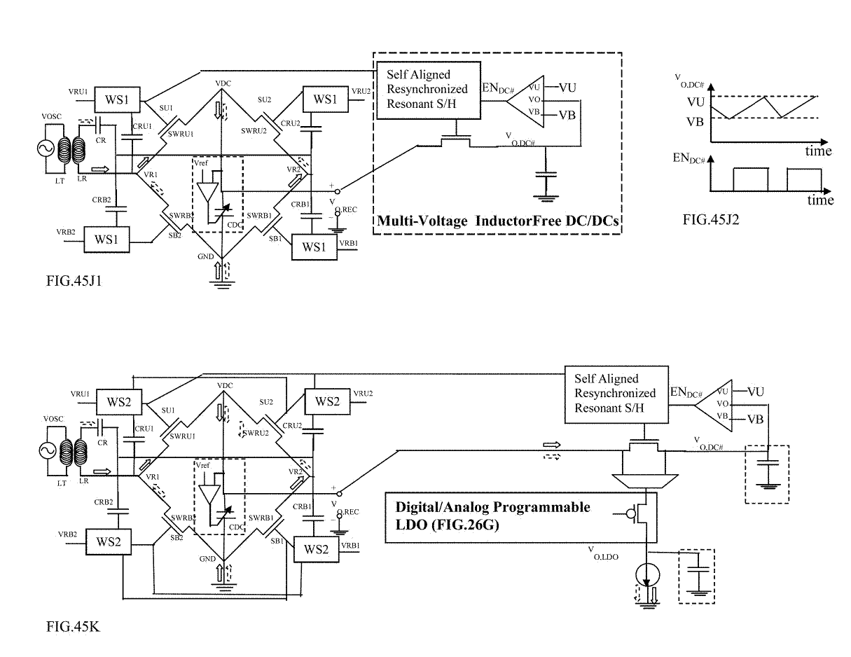

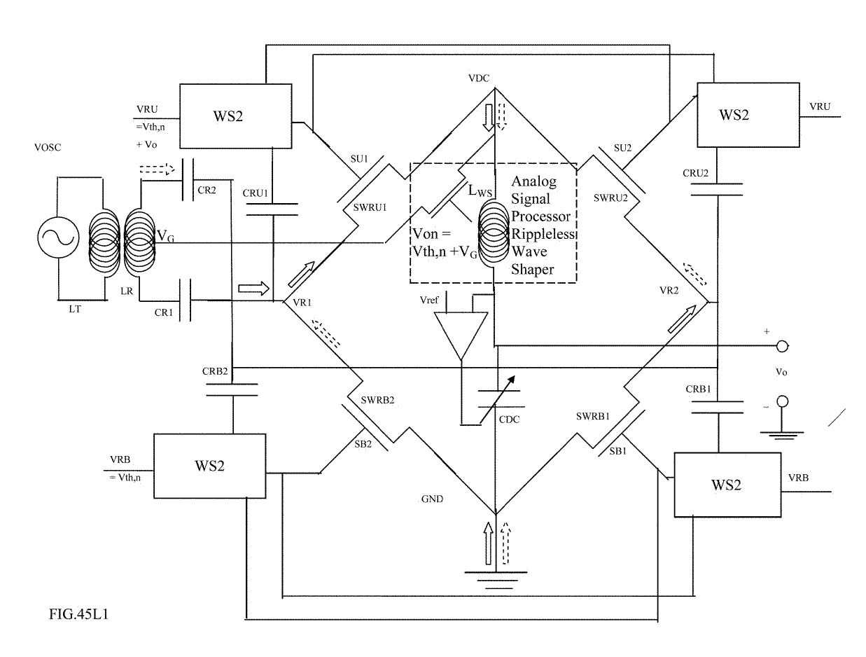

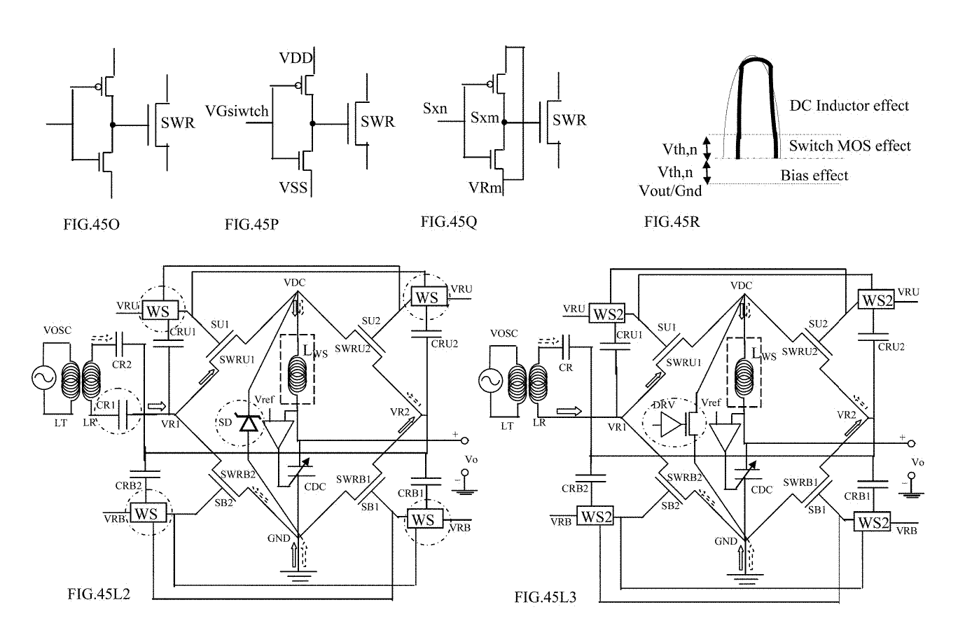

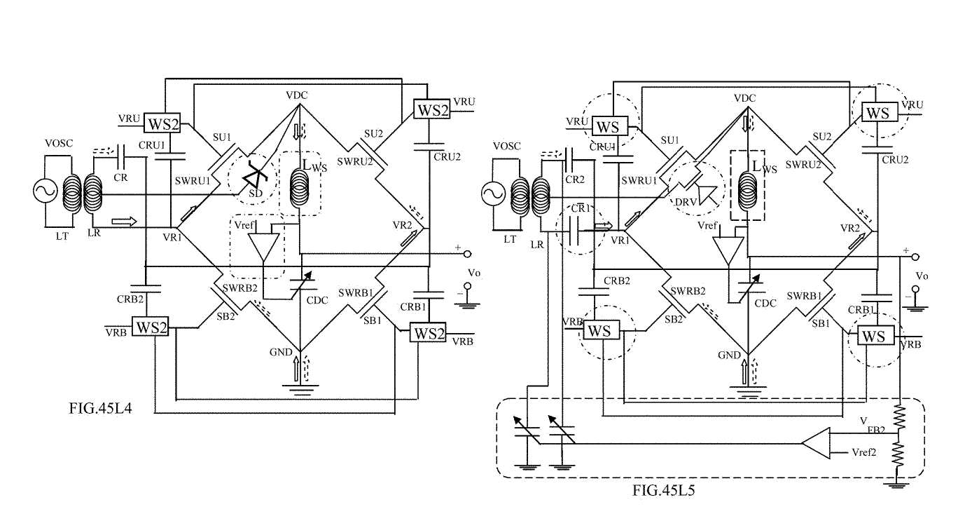

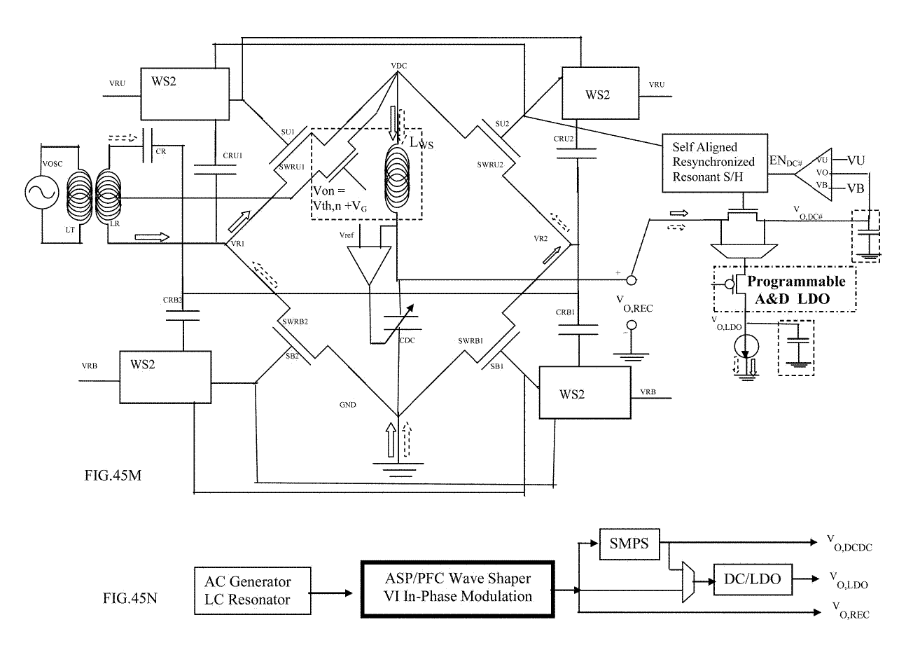

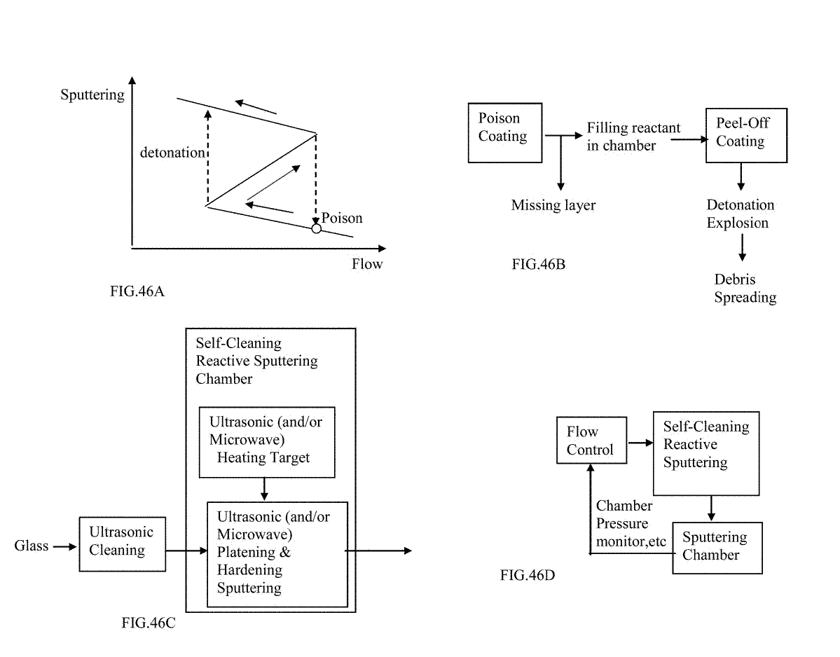

FIG. 34A is the cross section, of the thin film battery and/or Electro-Chromic Window (EC Window). The thin film battery/EC window is made of five layers, Transparent Conductor (TC), Electrochromic Electrode (EC), Ion Conductor (IC), Counter Electrode (CE) and Transparent Conductor (TC). As shown in FIG. 34A, being similar to the MOS and Bipolar devices, there are the hot-ion Iᵢₒₙ and break-down/reliability voltage problems for the EC window. The current-limited voltage ramping is the adaptive increment of voltage difference according to constant current/field. As shown in FIG. 34B, the const current/field is the difference of the applying voltage and the built in potential of Cstore. Basically, there are two different operations of window controller. The first kind operation is the Current-Limited Voltage Ramping circuit. The second kind operation is the Voltage-Limited Current Charging circuit. The voltage limit and, current limit are the function of temperature. In he real case, the operations are the versatile hybrid combinations of two basic operations.

The ion resistance Rᵢₒₙ is function of the temperature. As shown in FIG. 34C, we can get the temperature of the EC window from the value of Rᵢₒₙ(T) with the relations as follows,

Vw=I(t)R(T)+ΣI(t)/C

Vw1=I1(t)R(T)+ΣI(t)/C

Vw2=I2(t)R(T)+ΣI(t)/C

Vw2−Vw1=[I2(t)−I1(t)]R(T)

R(T)=(Vw2−Vw1)/[I2(t)−I1(t)]

I=Ni v=Ni E=Ni(Vw−ΣI(t)/C)/dᵢₒₙ

I(t)=(Vw−ρI(t)/C)/R(T)

R(I)=dᵢₒₙ/Ni

The battery and/or EC window have the bi-stability as shown in FIG. 34D. The battery and/or EC window can operate as shown in FIG. 34E to reduce the leakage current.

FIG. 35A shows the switching operation of the battery and/or EC window. The voltage difference across the battery and/or EC window is (W+−W−). The voltage of the bleach might be different from the voltage of the color. There is polarity. To protect the battery and/or EC window, there are the voltage limit and the current limit. To avoid the current limit, in the switching from bleaching to the coloring and vice versa, there is the voltage ramping of the switch. As shown in FIG. 35A, the EC window switching time is the start of bleaching or coloring. The voltage starts to ramp up or down. The polarity switch is the time the ramping voltage across the zero voltage W+=W−.

The thin film Battery/EC window has two limits, current limit and voltage limit. Due to the hot-ion effect, the speed limit of the ion is limited to the maximum ion speed. The hot-ion speed limit can be observed with the current-limit. The thin film battery/EC window can be thought as the battery. The voltage limit is the electrical field causing the reliability of the thin film battery/EC-window battery. As shown in FIG. 36, during the operations of the thin film battery/EC window, the voltage source or the current source are varying to keep both the voltage-limit and current limit. According to the switching operation in FIG. 35, the fundamental thin film battery/EC-window switching operation are classified to be six phases.

Phases 1 is the start or continue Switching of coloring phase;

Phase 2 is the hold of the color;

Phase 3 is the start of discharge/bleach;

Phases 4 is the start or continue switching of discharging/bleaching phase;

Phase 5 is the hold of the discharge/bleach;

Phase 6 is the start of charging/coloring.

All the operations of the thin film battery/EC-window H-bridge switch are followed this fundamental switching principle. To protect the thin film battery/EC window, the power is current-limited and/or voltage-limited source depending on the operational requirements.

Furthermore the H-Bridge Switch structure can be applied to have the different components. As shown in FIG. 37A1, it is the thin film battery/EC window driven by the analog buffer. It is the fundamental voltage ramping mode. From the electric model of the thin film battery/EC window, the thin film battery/EC window can be treated as the capacitor with the dissipative current source. Applying the H-Bridge structure to the capacitor of the thin film battery/EC window, the circuit of the H-Bridge with the analog buffer is shown as FIG. 37A2. The resistor is served as the current sensing. With, the feedback of the current sensing, the circuit in FIG. 37A2 can be served as the current-limited voltage ramping.

The H-Bridge structure applying to the Switch Mode Power Supply has, much more versatile novel structures. As shown in FIG. 37B1, it is the basic Buck converter. Applying the H-Bridge to the thin film battery/EC window, the current-limit window controller is as shown in FIG. 37B2. As shown in the FIG. 37C1, the H-Bridge structure is applied to the inductor, current-sensing resistor, capacitor and the battery/EC window. The corresponding current-limited window controller is shown as FIG. 37C2. Applying the H-Bridge to the whole buck converter as show in FIG. 37D1, the corresponding window controller is as shown in FIG. 37D2. The MOS devices in the H-Bridge serve as not only the switches but also the switching gate of the buck converter, too.

There are different thin film battery/EC window controller algorithms of

(1) voltage-ramping,

(2) current-limited.

(3) current-limited voltage-ramping and

(4) voltage-ramping current-limited, etc.

We can apply the different H-Bridge window controller architectures in FIG. 37 to the different thin film battery/EC window controller algorithms.

FIG. 38C1 and FIG. 38C2 show the, design platform having the different practical implementations of the thin film battery/EC window controller. The buck converter is to convert the high voltage power supply to the low voltage power having the large current. There are many different ways to implement the thin film battery/EC controller. The green technology integrated Current-Limited Voltage Ramping mode having a analog buffer to drive a H-bridge switch structure to drive battery, thin-film battery and Electrochromic Window. The Voltage Limited Current Charging mode further comprises a buck converter to drive a H-bridge switch structure to drive a battery and/or Electrochromic Window. The Voltage-Limited Current Charging mode also can comprise H-bridge switching Buck Converter to drive battery, thin-film battery and Electrochromic Window. As shown in FIG. 38C1, the control input signals can be either current charging signal or the voltage ramping signal.

However, for the networking consideration, there is the need for the embedded controller. The embedded controller has the Pulse Width Modulation PWM, signals. In the practical design, the thin film battery/EC window controller is designed around the embedded controller.

As shown in FIG. 38E1 and FIG. 38E2, the green energy smart window comprises Current-Limited Voltage Ramping circuit and algorithms to charge a battery or switch battery/Electrochromic Window. As shown in FIG. 38F1 and FIG. 38F2, the green energy smart window comprises Voltage-Limited Current Charging circuit and algorithm to charge a battery or switch battery and/or Electrochromic Window means.

As shown in FIG. 35B, there are the charging process and the discharging process. As the voltage increases from 0 to the voltage limit, it is the charging process. As the voltage decreases from the voltage limit to 0, it is the discharging process. The voltage limit for the tint/coloring is different from the voltage limit of the charge/discharge and/or transparent/bleach. The discharging process for the LDVR type single side pull up analog buffer can be done by the short of the thin film battery/EC window as shown in FIG. 36C and FIG. 36F. For the two-sided pull-up and pull-down analog buffer, the discharging process can be done by the pull-down of the analog buffer as shown in FIG. 36A and FIG. 36D by the short of the thin film battery/ EC window as shown in FIG. 36C and FIG. 36F. For the SMPS buck converter, there is no discharging mechanism. However, as the polarity changes, the voltage becomes the negative. It still can use the SMPS to charge up in the discharging process as long as the voltage limit and the current limit is in the safe range. As shown in FIG. 35A and FIG. 35B, for the polarity switch, it can be applied to both voltage ramping and current charging method. For the charge/discharge and color/bleach switch, it is applied to the current charging method only.

There are two major algorithms to switch the thin film battery charger-IC window controller, the current-limited voltage-ramping and the voltage-limited current-charging. As shown in FIG. 38C1, it is the charging process of the current-limited voltage-ramping; As shown in FIG. 38C2, it is the discharging process of the current-limited voltage-ramping. As shown in FIG. 38B it is the charging process of the voltage-limited current-charging. As shown in FIG. 38D2, it is the discharging process of the voltage-limited current-charging. The current-limited voltage-ramping methodology is the conjugate of the voltage-limited current-charging. They are the general fundamental algorithms. They can be easily modified to fit for the different systems and architectures of the thin film battery charger/EC window controller.

As shown in FIG. 38C1, the voltage ramping up and the ramping rate is bounded by the constant current of current limit. The current is fed back to modify the voltage ramping up rate. The ramping voltage rate is reduced or increased for the ramping voltage. As shown in FIG. 38A2 and FIG. 38C1, for the embedded controller having the PWM signal to generate the voltage ramping signal, it can, use the PWM signal to generate the voltage ramping signal. As shown in FIG. 38A2 and FIG. 38D1, for the current Switch battery/EC window controller, the current feedback is to adjust the PWM duty-cycle.

For the voltage ramping algorithm, as shown in FIG. 35C, the voltage ramping |W+−W−| signal is sent to the PWM generator. The RC filter filters out the digital switch and get the |W+−W−| analog signal. The |W+−W−| analog signal is sent to the analog buffer to generate the voltage ramping voltage source to drive the battery/EC window. As the voltage ramping voltage become zero, the polarity switch signals are generated to switch the H-Bridge. This is the feed forward system.

If the embedded controller uses the current-sensing resistor feedback current signal information to adjust the voltage ramping rate, it is the current-limited voltage ramping. Then it becomes the feed forward system with the addition of the feedback signal control. For the current limited algorithm, the duty-cycle signal is sent to the PWM generator to generate the corresponding PWM signal. The PWM signal is the switching signal of the Buck Converter type Switch Mode Power Supply SMPS. The current-sensing resistor senses the current and feedback to the embedded controller to adjust the duty-cycle. This is the feedback system.

If the embedded controller uses the feedback signal of (W+−W−) voltage to adjust and enable/disable the PWM signal due to the maximum voltage limit allowance, it becomes the voltage-limited current charging. Then it becomes the current feedback system with the addition of the voltage feedback signal control. As shown in the upper-right portion in the FIG. 38C2, the green technology integration system is made of the Voltage-Limited Current Charging circuit. It further comprises a buck converter to drive a H-bridge switch structure to drive a thin film battery/Electrochromic Window.

As shown in FIG. 38A, it is the design mistake in the conventional of battery charger/electrochromatic window driver, etc. to use the unit gain amplifier as the driver. It causes (1) overheat of the chip and board, (2) wastes a lot of power (3) no driving capability. As shown in FIG. 38B1, it is the combining switch mode power supply with analogy buffer having the input varying voltage capability. It is the buck regulator with analog output voltage having no ripple to be the radio-RF-Noiseless buck regulator.

As shown in FIG. 38B2, FIG. 38B3 and FIG. 38B4, comparing the conventional “SMPS & LDVR” with our unique “SMPS & Analog Buffer” and “SMPS & LDVR type Analog Buffer”, the conventional “SMPS & LDVR” has the constant voltage output with ripple. However, our unique “SMPS & Analog Buffer” and “SMPS & LDVR type Analog Buffer” have the varying output voltage being equal to input voltage. The output voltage has no ripple to be the Rh-Noiseless. The building block diagram of Analog Buffer as shown in FIG. 38B5. The detailed schematic of Analog Buffer is shown in FIG. 38B6.

There are versatile combinatory innovations of our innovations of SMPS, analog buffer. LDO type analog butler and H-Bridge. As shown in FIG. 38B4, FIG. 38B7, FIG. 38C1 and FIG. 38C2, they show the architecture and system made of the SMPS/Buck Converter, analog buffer and H-Bridge. The Analog Buffer accepts the output voltage of SMPS/BUCK converter as input power supply. The Analog Buffer input is the dynamic varying “signal input” Vi. The Analog Buffer output is the output power having Vo=Vi.

A Wireless Window 5R System W5RS comprises a smart battery charger to drive battery and electrochromic window The smart battery charger comprises switch mode power supply SMPS, low drop-offset LDO type analog buffer with the option of the H-Bridge for discharging. The switch mode power supply SMPS provides power to the low drop-offset LDO type analog buffer. The low drop-offset LDO type analog buffer provides power to the H-Bridge. The low drop-offset LDO type analog buffer is either, analog buffer or LDO analog buffer. The H-Bridge charges and discharges the battery and electrochromic window, etc with switches embedded in the H-Bridge.

As shown in FIG. 38B4 and FIG. 38B9, they show the alternative design of the architecture and system made of the SMPS/Buck Converter, LDO typed analog buffer and H-Bridge. As shown in FIG. 38B8, FIG. 38B10 and FIG. 38B11, they show the alternative design of the architecture and system made of the SMPS/Buck Converter, H-Bridge and LDO typed analog butler. The analog buffers are embedded in the H-Bridge. A Wireless Window 5R System W5RS comprises a smart battery charger to drive battery, thin-film battery and electrochromic window, etc. The smart battery charger ruttier comprises switch mode power supply SMPS and H-Bridge. The switch mode power supply SMPS provides power to the H-Bridge. The H-Bridge further comprises low drop-offset LDO type analog buffers and switches. The H-Bridge charges and discharges the battery and the electrochromic window with switches and low drop-offset LDO type analog buffer embedded in the H-Bridge. The low drop-offset LDO type analog buffer is either analog buffer or LDO analog buffer. The low drop-offset LDO type analog buffer further provides rippleless RF-Noiseless output power to the battery and the electrochromic window.

FIG. 38D1 and FIG. 38D2 show the application of FIG. 37D2 being applied to the thin film battery charger/EC window controller. As shown in FIG. 38D3, the green technology integration system is made of the Voltage-Limited Current Charging circuit. It further comprises H-bridge switching Buck Converter to drive a thin film battery/Electrochromic Window. The embedded window controller sends the polarity and SMPS switching signals to the H-Bridge. There are many different ways for the combination of the polarity and SMPS switching, signals. For simplicity, the PMOS signal is the SMPS signal gated by the polarity signal. The NMOS signal is the polarity signal. For the high power efficiency, both the PMOS and NMOS signals can be SMPS signal gated by the polarity signal.

The Battery Charger and/or EC window controller, etc. in the iPindow/Smart Window can be independent device. As shown in FIG. 1A, the smart Battery Charger and the smart EC window 20 can be operated as either the dimmer battery/window or bi-state battery/window. As shown in FIG. 39A and FIG. 39B, the battery charger/window controller adopts the embedded controller. FIG. 39A is the system block diagram for the current-limited voltage ramping Battery Charger/EC window controller. FIG. 39B is the system block diagram for the voltage-limited current charging Battery Charger/EC window controller. In the embedded controller, there are embedded ADC and embedded Xtaless Clock. In the embedded Xtaless Clock, there are the embedded current regulators.

As shown in FIG. 39C, during the discharge/bleach, the current flows in one direction. Bleach_b is the discharge/bleach signal. The ISW_b circuit is the current-limit detect circuit to switch off the switching gate. The VSW_b circuit is the voltage-limit detect circuit to switch off the switching gate. This is the event-driven switch mode buck converter. As shown in FIG. 39D, during the color, the current flows in the reverse direction. Color_b is the charge/Color signal. The ISW_c circuit is the current-limit detect circuit to switch of the switching gate. The VSW_c circuit is the voltage-limit detect circuit to switch of the switching gate. This is the event-driven switch mode buck converter. FIG. 39E are the combinatory circuit of the FIG. 39C and FIG. 39D to be the complete Battery Charger and/or EC window controller circuit.

As shown in FIG. 21A and FIG. 40A, the Switch Mode Power supply SMPS provides the power to Low-Drop Voltage Regulator LDVR to generate the clean power. Similarly, as shown in FIG. 40B, the analog buffer of the EC window controller will filter out the switching noise of the SMPS. With the analog buffer in FIG. 40D and the H-Bridge operation in FIG. 36, the operation curve is shown as FIG. 40C. There are many ways to implement the current sensing technique. As shown in FIG. 38A, the current sensing resistor can feedback the current information to the embedded controller or the SMPS. Use the SMPS to control the current to be current-limited voltage ramping. We can also use the resistorless current sensing in the prior applications. As shown in FIG. 40D, we can also use the current limit sensor embedded in the analog buffer.

The green technology integration system is made of the Current-Limited Voltage Ramping circuit having a analog buffer to drive a H-bridge switch structure to drive the Electrochromic Window. As shown in FIG. 34E and FIG. 40C, the analog buffer can filter out the noise of the switch mode power supply. As shown in FIG. 40D, the analog buffer has the output stage serves as LDVR type operation. In other words, it is single side pull-up that no DC biasing current for the output stage. It will not burn the DC biasing current for the output stage as the conventional unit gain amplifier does. Furthermore, the current limit sensing mechanisms are implemented with the current mirror mechanism in the analog buffer.

As shown in FIG. 41A, the two power wires “V_{board+}˜V_{window+}”, “V_{board-}˜V_{window-}” and one single wire “V_{window+}˜V_{window+}” constituted to be one triple-wire. As shown in FIG. 41B, the window voltage Vwindow can be calculated as

V_{window}=2*V_{window+}−(V_{board+}+V_{board-})

A Green Energy Smart Window 5R System W5RS means further comprises a micro-inverter to convert Solar window harvesting solar energy to be electric energy. The micro-inverter adopts in-phase power injection to inject the energy. It increases the amplitude of injected energy waveform in phase. It minimizes the phase interruption of the injected energy waveform. The amplitude in the AC oscillator is the energy of the AC oscillator. As the current injects into the AC oscillator, the phase of the AC oscillation will not be influenced to be In-Phase injection. FIG. 42A shows the “In-Phase Current Injection” into the AC oscillation. The amplitude of AC oscillation increases as “In-Phase Current Injection” into the AC oscillation, FIG. 42B1 is the circuit having the “In-Phase Current Injection” into the AC oscillation. The current is injected at the peak voltage of the AC oscillation, FIG. 42B2 is the circuit having the “In-Phase Current Injection” to inject the current into the AC oscillation at the valley voltage of the AC oscillation. As shown in FIG. 42B1, the boost converter injects the current into the AC oscillation. As the Peak Detector detects the peak of AC waveform, the peak detector switches off the NMOS and switch on the PMOS, the inductor injects the inductor current into AC oscillator. As shown in FIG. 42B2, the buck-boost converter extracts the current out of the AC oscillation at the valley. As the Valley Detector detects the valley of AC waveform, the valley detector switches off the NMOS and switch on the PMOS, the inductor extracts the inductor current out of the AC oscillator. It pulls down the valley to increase the amplitude of the AC oscillation.

The same principle can be applied to the conjugated circuit to extract the energy from the AC oscillator. As the current extract the energy out of the AC oscillator at either the peak or valley of AC waveform, the phase of the AC oscillation will not be influenced to be In-Phase extraction. FIG. 43A shows the “In-Phase Current extinction” out of the AC oscillation. The amplitude of AC oscillation decreases as “In-Phase Current extraction” out of the AC oscillation. FIG. 43B1 is the circuit to have the “In-Phase Current extraction” out of the AC oscillation at the peak voltage of the AC oscillation. FIG. 43B2 is the circuit to have the “In-Phase Current Extraction” out of the AC oscillation at the valley voltage of the AC oscillation. As shown in FIG. 43B1, the buck-boost converter extracts the current out of the AC oscillation. As the Peak Detector detects the peak of AC waveform, the peak detector switches off the NMOS and switch on the PMOS, the inductor extracts the inductor current out of AC oscillator. As shown in FIG. 43B2, the buck converter injects the current into the AC oscillation at the valley. As the Valley Detector detects the valley of AC waveform, the valley detector switches off the NMOS and switch on the PMOS, the inductor injects the inductor current into the AC oscillator to push up the valley to decrease the amplitude of the AC oscillation.

W5RS is the platform for the multiple standards. Referring to FIG. 1L1, FIG. 44A and FIG. 44B, W5RS has the 5R: Resonant Resynchronization Rectifier Regulator. It has 96% Power Efficiency. The circuit enclosed in the dotted lines are optional. As shown in FIG. 44A, FIG. 44B, FIG. 45H1, FIG. 45I1, FIG. 45J1 and FIG. 45K, the Wireless Window 5R System W5RS comprises a wireless power supply 5R Recycling Resonant Resynchronization Rectifier Regulator. The wireless power supply Recycling Resonant Resynchronization Rectifier Regulator 5R is connected between LC resonator means and DC output loading, etc. The 5R converts energy in the LC resonator to be DC power to supply DC output loading. The 5R has only one single stage. It integrates conventional rectifier, DC/DC and LDO three stage to be single stage.

The 5R thriller comprises capacitors biased at different level to have boost voltage. The boost voltage recycles the resonating energy in the LC resonator to turn on switch devices synchronously. The capacitors have one end been connected to output terminal of the LC resonator and another end been connected to switching MOS devices of rectifier.

A Green Energy Smart Window 5R System W5RS comprises a wireless power supply Recycling Resonant Resynchronization Rectifier. The capacitors are connected between the terminals of the LC resonator and switches. The switch is weakly biased at proper biasing voltages. As the LC resonator resonates, the capacitors drive the switch to switch-on and switch-off the switch device. Furthermore, the switching energy of capacitor is recycled through the LC resonator. As shown in FIG. 45A1, the W5RS has the LC oscillator made of L_{R} and C_{R}. As shown in FIG. 45A2, the W5RS is transformed to be the serial resonator made of L_{R} and C_{R}. As shown in FIG. 45A3, the W5RS is transformed to be the serial resonator made of L_{R}, C_{R} and C_{DC#}. The 5R further comprises LC resonator, switch and capacitors. As shown in FIG. 45A4, the W5RS is transformed to be the serial resonator with the insertion of power-loss-less switches. Comparing FIG. 44A and FIG. 44B with FIG. 45A4, the W5RS is just “single stage” power conversion. Comparing with the conventional Rectifier, DC/DC buck converter and LDO “three-stage” power conversion mechanism, the single stage W5RS is super-power-efficient to have the power efficiency 96%. p Referring to FIG. 44C, FIG. 44A and FIG. 44B, the C_{DC} has the multiple functions to make the fine-tune of the Rectifier output voltage V_{DC} or V_{DC1}. The C_{DC} is fine-tuned according to the output voltage V_{DC} or V_{DC1} with the frequency fine-tuning relative the resonant frequency. In other words, there are three voltage fine-tuning mechanisms, (1) the rectifier output voltage fine-tuning mechanism, (2) the DC/DC output voltage fine-tuning mechanism and (3) the LDO output voltage fine-tuning mechanisms. The closer the output voltages are, the higher the power efficiency is. The smaller the capacitor C_{DC} and _{CDC#} are, the higher the power efficiency is. For the limited case, the capacitor C_{DC} and _{CDC#} are eliminated that the rectifier, DC/DC and LDO are merged to be one single stage 5R Recycling Resonant Resynchronization Rectifier Regulator.

Referring to FIG. 45C2A and FIG. 44B, the threshold voltage Vth,n will decrease the power efficiency of the Rectifier and DC/DC conversion. Referring to FIG. 45C2A and FIG. 44C, VR_{U1}, VR_{U2}, VR_{B1} and VR_{B2} are biased at the proper voltage. VR_{U1} and VR_{U2} are biased at the voltage to be the sum of the V_{DC} and Vth,n. VR_{U2} and VR_{B2} are biased at the voltage to be the sum attic Ground and Vth,n i.e., Vth,n. With the proper bias of VR_{U1}, VR_{U2}, VR_{B1} and VR_{B2}, under the boost kick of capacitors CR_{U1}, CR_{U2}, CR_{B1} and CR_{B2}, The 5R power efficiency increases a lot in FIG. 45C2B. Furthermore, as shown in FIG. 45B1 and FIG. 45B2, the S_{U1}, S_{U2}, S_{B1}, S_{B2}, S_{DC1} and S_{DC2} gates voltages are recycling with the synchronizing resonant energy, S_{U1}, S_{U2}, S_{B1} and S_{B2} are boosted up by the recycling energy of L_{R} and C_{R}. S_{DC1} and S_{DC2} are boosted up by the sampled and hold recycling energy of L_{R} and C_{R}. Therefore, the 5R power efficiency can be as high as 96%.

The 5R is compatible to both WPC Wireless Power Consortium Qi standard and A4WP Alliance for Wireless Power standard. (1) Due to 5R factors, the 5R can be considered as “single-stage” power conversion. (2) Due to the power recycling, the switching loss of rectifier and DC/DC power conversion, etc are eliminated. (3) Due to wave shaping, the Rectifier operation can be considered to be switching operation instead of analog operation. Due to the above three factors, from AC to DC, the 5R has the highest power efficiency 96% in all the world.

FIG. 45D1 is the resonant voltage, current and power of the ideal resonant circuit as shown in FIG. 45D2. FIG. 45D2 is the ideal resonant circuit. The 5R can be transformed from the ideal resonant circuit to make the analysis and design. FIG. 45E1 is the resonant voltage, current and power of the resonant circuit having the diodes. FIG. 45E2 is the resonant circuit having the diodes. The Schottky diode reduces the power efficiency a lot.

To eliminate the power loss due to the Schottky diode, the active MOS devices are adopted. FIG. 45F1 is the resonant voltage, current and power of the resonant circuit having the active MOS. FIG. 45F2 is the resonant circuit having the MOS. The MOS device is not only to reduce the power loss but also to have the power factor correction PFC effect. The current of MOS device increases with the gate voltage of MOS that the MOS device has the power factor correction effect.

To reduce the loss of MOS at low voltage, the resonant voltage of LC resonator needs to sharp the rising edge and falling edge. Therefore, the waveform shaper circuit is needed to shape up the analog sinusoidal voltage to be the digital switching voltage. FIG. 45G1 is the resonant voltage, current and power of the resonant circuit having wave-shaper switching driver. FIG. 45G2 is the resonant circuit having the wave-shaper switching driver.

Combing the above Rectifier. Design & Analysis with Virtual Resonant, the Wireless Window 5R System W5RS comprises a 5R. The 5R thriller comprises wave-shaping and switches. The wave-shaping shapes up the switching voltage of switches to have sharp rising and falling edge. It is to reduce on-resistance of the switches in switching transition process. FIG. 45H1 is the rectifier having MOS with wave-shaper switching driver as shown in FIG. 45H2. FIG. 45H2 is the fundamental wave-shaper. The rectifier has the voltage regulating capability with the frequency tuning of the capacitor C_{DC}. The rectifier can stand alone as the power supply. There is no need for the DC/DC converter and regulator. FIG. 45H1 is the rectifier having regulated output voltage capability with wave-shaper switching driver as shown in FIG. 45I2. FIG. 45I2 is the mutual-latch enhanced wave-shaper.

To have multi-voltage supply capability, the inductor-free DC/DC converter technique is adopted. The DC/DC converter shares the inductor with the rectifier to recycle the energy. FIG. 45J1 is the rectifier with multi-voltage Inductor-Free DC/DC converter. FIG. 45J2 is the waveform of the multi-voltage Inductor-Free DC/DC converter. FIG. 45K is the complete set of 5R having the rectifier, multi-voltage Inductor-Free DC/DC converter and Digital/Analog Programmable LDO integrated single power-conversion stage. FIG. 45L1 is the complete schematics of the 5R having the ASP/PFC wave shaper. FIG. 45O is the generic wave shaper WS. FIG. 45P is the gate-activated wave shaper. FIG. 45Q is the source-activated switch-energy recycling wave shaper WS2. FIG. 45P, is the operational analysis of wave shaper. As VRₘ voltage is less than Vₒᵤₜ+2V_{th,n} the active rectifying, MOS SWR is riot turned on, where, m represents 1 or 2 and Vₒᵤₜ represents VDC. The oscillating current makes the VRₘ voltage rises up rapidly. As Vₘ voltage is larger then Vₒᵤₜ+2V_{th,n}, the active rectifying MOS SWR is aimed on and the oscillating current rushes into L_{WS}. The VRₘ voltage rises up rapidly due to L(di/dt). As shown in FIG. 45Q, accordingly, the Sₙₘ rapidly rises to switch on SWR. The on-resistance of SWR is minimized. As the resonant current reverses flowing direction, the VRm voltage decreases rapidly. As shown in FIG. 45Q, the Sₙₘ rapidly switches off SWR. It is the “digital switch” mode of SMPS Switch Mode Power Supply. As The ASP/PFC wave shaper increases the slopes of the rising edge and falling edge. The on-resistance and power loss are reduced a lot. Based on the same wave shaping principle. FIG L2 is the alternative design of 5R circuit with Schottky Diodes. FIG. L3 is the alternative design of 5R circuit with active MOS. FIG. L4 is the alternative design of 5R circuit with Schottky Diodes. FIG. L5 is the alternative design of 5R circuit with active MOS. It shows the alternative design for the frequency tuning of the LC resonator. All the alternative and optional designs are circled with dotted lines. FIG. 45M is the complete schematics of the 5R having the ASP/PFG wave shaper, SMPS and A&D programmable LDO. FIG. 45N is the functional block diagram of the 5R having the ASP/PFC wave shaper, SMPS and A&D programmable LDO. It illustrate the VI In-Phase Modulation. The ASP/PFC Wave Shaper VI In-Phase Modulation makes the necessary phase modulation of the voltage V and current I from 90 degree to be in-phase. The phase modulation from 90 degree to 0 degree in-phase, it increases the power-efficiency tremendously. If the voltages of V_{O,RECT}, V_{O,DC} and V_{O,LDO} are closed enough, the inductor sends the current through the series of switch gates of rectifier, DC/DC convener and LDO. The power resistance loss is minimized Furthermore, with the wave, shaped up switching type voltage waveform and recycling switching energy, the rectifier has very high power efficiency as more than 95%.

There are many ways to manufacture the thin Film Battery/EC window. The Window 5R System W5RS further comprising thin film being planarized with assistance of ultrasonic wave. The deposition is cleaned with assistance of ultrasonic wave. The thin films are deposited to be layers. The layer is first deposited one interfacing layer. Then plating and hardening the interfacing layer to form a well-crystallized foundation. Then, the Layer depositing on the well-crystallized foundation to grow the layer. For the mass production, the gas reaction sputtering process is preferred. The deposition comprises a gas reaction sputtering. It comprises the ultrasonic self-cleaning target to clean passion deposition on the target.

As shown in FIG. 46A, the gas reaction sputtering has the poison effect. The sputtering material will coat on the target. As shown in FIG. 45B, it causes the unstable operation of the sputtering chamber. It causes the missing layer and debris spreading problem. To avoid the poison problem in the sputtering chamber, it uses the ultrasonic self-cleaning target. The sputtering material will be vaporized from the target instead of coating on the target. The system design of the self-cleaning sputtering chamber is as shown in

The general manufacture flow for the thin Film Battery EC window is shown in FIG. 47A. Furthermore, as shown in FIG. 47A, the ultrasonic wave is not only for the self-cleaning sputtering but also for the glass cleaning, plating and hardening, etc. The ion conduction layer is plating and hardening the layer with ultrasonic assisted means. As shown in FIG. 47B, the thin film battery, solar window and/or EC window layer grows the ion conduction layer without the plating and hardening. As shown by the solid line, the ion path zigzag and the ion has low speed. It causes the switch of the battery and/or EC window taking a much longer time. As shown in FIG. 47C, the EC window upper layer is deposited one thin layer. After the sputtering this than layer, using the plating and hardening process to organized this thin interface layer. Then begin the formal sputtering of this layer. This layer will grow on the plating and hardening thin layer with the ordering way to form good crystal structure. As shown by the solid line, the ion movement is in straight line and the ion moves fast. The EC window can switch fast. The green technology integration system comprises the Layers. In general, the layers are deposited to be layers. The layer is first deposited to be one interfacing layer. Then apply the plating and hardening process to the interfacing layer to form a well-crystallized foundation. Then the Layer is deposited on the well-crystallized foundation to grow this layer. The layer is very much important for the ion conduction layer. It can increase the performance of the EC window a lot. Normally, the heating and hardening are done with the quartz light. The heating and hardening the layer with the versatile combination of the assisted ultrasonic and/or microwave have the plating effect, too. For example, the planarization platening is assisted with ultrasonic and the heating hardening is assisted with microwave.

FIG. 48 shows the application of the Anlinx & Milinx & Zilinx FSOC with the 23Less Green Technology of Smart Window. As shown in FIG. 30B, FIG. 45A is the platform of the Anlinx & Milinx & Zilinx FSOC having the 23Less Green Technology for of Smart Window. As shown in FIG. 27C, FIG. 48B is the Anlinx & Milinx & Zilinx FSOC having the IP wrapper of Noise Isolation Technology for 23Less Green Technology for of Smart Window.

The green energy smart window W5RS is the new standard promoted by the innovative company Tang System. S is System and Supply, “W5” represents “Wireless Wireline Weave Wishful Window”. “5R” represents “Recycling Resonant, Resynchronization Rectifying Regulator”. “W5RS” is the killer application product of Silicon Valley and “5R” is the killer core technology of Silicon Valley. Even for the WPC Qi and A4WP wireless power supply standards, the novel single stage 5R even can have the AC/DC power efficiency as high as 95% which is the highest record in all the world. While the invention has been particularly shown and described with reference to the preferred embodiments thereof, it will be understood by those skilled in the art that various changes in form and details may be made therein without departing from the spirit and scope of the invention.

We claim:

1. [FIG. 1A] A green energy smart window unit comprising:
control circuitry comprising: a processor, a multimedia window controller, an electrochromic window controller, a solar cell panel controller, and a power supply controller;
a rechargeable power supply;
a wireless charging power supply circuit;
a multimedia window, an electrochromic window, and a transparent solar cell pawl enclosed in an isolated glass unit;
said isolated glass unit comprises an exterior glass panel located at a first side facing an external light, source and an interior glass panel located at a second side, opposite the first side;
said transparent solar cell panel is positioned on said exterior glass panel in said isolated glass unit, whereby exterior light is transmitted through said transparent solar cell panel and received by said electrochromic window, said transparent solar cell panel is capable of generating an electrical current that can power components of the smart window unit including the control circuitry, said rechargeable power supply, said wireless charging power supply circuit, said electrochromic window, and said multimedia window;
said multimedia window is positioned on said interior glass panel in said isolated glass unit and further comprising a touch screen display capable of displaying video and detecting touch inputs;
said electrochromic window is positioned on said multimedia window, in said isolated glass unit, and is capable of blocking received light from passing through said multimedia window and said interior glass panel;
a mobile device charging unit comprising a wireless power pad charger inductively coupled to said wireless charging power supply circuit; and
said power supply controller capable of controlling the rechargeable power supply to selectively discharge current to an external electrical grid coupled to the smart window unit.

2. [FIG. 1A] A green energy smart window unit comprising:
control circuitry comprising: a processor, a multimedia window controller, a solar cell panel controller, and a power supply controller;
a rechargeable power supply;
a wireless charging power supply circuit;
a multimedia window, and a transparent solar cell panel enclosed in an isolated glass unit;
said isolated glass unit comprises an exterior glass panel located at a first side, lacing an external light source and an interior glass panel located at a second side, opposite the first side;
said transparent solar cell panel is positioned on said exterior glass panel in said isolated glass unit, whereby exterior light is transmitted through, said transparent solar cell panel and received by said multimedia window, said transparent solar cell panel is capable of generating an electrical current that can power components of the smart window unit including the control circuitry, said rechargeable power supply, said wireless charging power supply circuit, and said multimedia window;
said multimedia window is positioned on said, interior glass panel in said isolated glass unit and further comprising a touch screen display capable of displaying, video and detecting touch inputs;
a mobile device charging unit comprising a wireless power pad charger inductively coupled to said wireless charging power supply circuit; and
said power supply controller capable of controlling the rechargeable power supply to selectively discharge current to an external electrical grid coupled to the slum window unit.

3. [FIG. 1A] A green energy smart window unit comprising:
control circuitry comprising: a processor, an electrochromic window controller, a solar cell panel controller, and a power supply controller;
a rechargeable power supply;
a wireless charging power supply circuit;
an electrochromic window and a transparent solar cell panel enclosed in an isolated glass unit;
said isolated glass unit comprises an exterior glass panel located at a first side facing an external light source and an interior glass panel located at a second side, opposite the first side;
said transparent solar cell panel is positioned on said exterior glass panel in said isolated glass unit, whereby exterior light is transmitted through said transparent solar cell panel and received by said electrochromic window, said transparent solar cell panel is capable of generating an electrical current that can power components of the smart window unit including the control circuitry, said rechargeable power supply, said wireless charging power supply circuit, and said electrochromic window;
said electrochromic window is positioned on said interior glass in said isolated glass unit, and is capable of blocking received light from passing through said exterior glass pallet;
a mobile device charging unit comprising a wireless power pad charger inductively coupled to said wireless charging power supply circuit; and
said power supply controller capable of controlling the rechargeable power supply to selectively discharge current to an external electrical grid coupled to the smart window unit.

4. [FIG. 1A FIG. 1D FIG. 1E] A green energy smart window unit according to claim 2 wherein said green energy smart window further comprising a micro-computer to control said Multimedia Window,
said micro-computer further comprising touching screen to have user interactive with said Multimedia Window;
said touching, screen covering on a screen of said Multimedia Window;
touching on said touching screen to make interaction with said Multimedia Window through said micro-computer
said touching screen laying on said interior glass panel having layer of sensor to detect touching positions on said touching screen.

5. [FIG. 1A FIG. 1I FIG. 42A FIG. 42B1 FIG. 42B2 FIG. 43A FIG. 43B1 FIG. 43B2] A green energy smart window unit according to claim 3 wherein said power supply controller further comprising a micro-inverter to convert said Solar Cell Panel harvesting solar energy to be electric energy,
said micro-inverter adopting in-phase power injection to inject the energy with in-phase micro-inverter to increase amplitude of injected energy wayform in phase to minimize phase interruption of said injected energy waveform;
said micro-inverter further comprising peak detector to inject current at peak of output voltage to have said in-phase power injection;
said micro-inverter further comprising valley detector to pull current at valley of output voltage to have said in-phase power injection.

6. [FIG. 1A FIG. 31C FIG. 31D] A green energy smart window unit according to claim 2 wherein processor further comprising Rippleless Fast Locked Frequency Phase Lock Loop FPLL,
said Rippleless Fast Locked Phase Lock Loop FPLL anther comprising an oscillator, a clock-divider to divide clock and a phase frequency detector PFD generate reset signal,
an input reference clock injecting said oscillator to make phase alignment of said infut reference clock and oscillation of said oscillator;
said reset signal resetting said clock divider after each reset signal being generated by said phase frequency detector PFD. said Rippleless Fast Locked PLL having an option of programmable clock buffer;
said programmable clock buffer having programmable divider to divide oscillation of said oscillator to widen frequency range of output clock.

7. [FIG. 31K FIG. 31M FIG. 31N] A green energy smart window unit according to claim 2 wherein processor further comprising bandgap generator;
said bandgap generator further comprises a pair of voltage bandgap generator and current bandgap generator;
said voltage bandgap generator generating bandgap voltage feeding into said current bandgap generator to generate bandgap current;
said current bandgap generator generating bandgap current feeding into said voltage bandgap generator to generate bandgap voltage.

8. [FIG. 31K FIG. 31A] A green energy smart window unit according to claim 2 wherein processor further comprising xtaless clock made of LC oscillator and bandgap generator;
said LC oscillator controlling amplitude, centerline and frequency of oscillation;
amplitude being controlled with constant amplitude feedback loop for said oscillation;
centerline being controlled with common mode feedback for said oscillation;
said bandgap generator further comprises a pair of voltage bandgap generator and current bandgap generator;
said voltage bandgap generator generating bandgap voltage feeding into said current bandgap generator to generate bandgap current;
said current bandgap generator generating bandgap current feeding into said voltage bandgap generator to generate bandgap voltage;
said LC oscillator having an option to be magnetic enhanced ME-LC oscillator;
said magnetic enhanced ME-LC oscillator comprising a plurity of inductors and a plurity of capacitors;
said LC oscillator controlling amplitude, centerline and frequency of oscillation;
said inductors being magnetic enhanced inductor MEL;
said magnetic enhanced inductor MEL having magnetic conductive material wrapped around electric conductive wires to confine magnetic field not penetrate into package.
said xtaless clock having an option of a plurity of pairs of magnetic enhanced ME-LCO;
said magnetic enhanced ME-LCO farther having said magnetic enhanced inductor MEL being mastic coupling together to have magnetic inject locking to increase Q of said oscillation.

9. [FIG. 31K FIG. 31A FIG. 31P FIG. 31Q1 FIG. 31Q2] A green energy smart window unit according to claim 8 wherein xtaless clock having current buffer made of current mirror;
an output MOS device of said current buffer having the same gate connection with an reference MOS device;
a source of said output MOS of said current buffer and a source of said reference MOS device being connected together;
a drain voltage of said output MOS and a drain of reference MOS being input of a high gain differential amplifier;
an output of said high gain differential amplifier being connected with a cascade output MOS of said current buffer;
a source of said cascade output MOS being connected with the drain of said output MOS device.

10. [FIG. 1A FIG. 31H] A green energy smart window unit according to claim 3 wherein multimedia window controller further comprising optical Serdes,
said optical Serdes further comprising transimpedance amplifier;
said transimpedance amplifier comprising magnetic enhanced regulatedcascode ME-RGC Network, magnetic enhanced reversed triple resonant network ME-RTRN Differential Amplifier and Feedback Network;
said ME-RGC Network being a pair of differential regulatedcascode RGC having a differential cross-coupling magnetic enhanced coupled inductor;
said ME-RTRN Differential Amplifier being a triple resonant network TRN differential amplifier having differential cross-coupling magnetic enhanced coupled inductors;
said ME-RGC Network having a pair of input and sending output to a pair of input of said ME-RTRN;
said ME-RTRN sending output to a pair of input said Feedback Network;
a pair of output of said Feedback Network connected to a pair of said ME-RTRN to have negative feedback to enhance bandwidth.

11. [FIG. 33C FIG. 33D FIG. 33F] A green energy smart window unit according to claim 3 wherein power supply controller further comprising snitch mode power supply using Adaptive Optimum Constant On Time AOCOT,
said switch mode power supply comprising a plurity of power charging devices, energy recycling devices and inductors;
said power charging devices being switched with voltage mode control;
said voltage mode control detecting a specified low voltage to switch on said power charging devices;
said voltage mode control detecting a specified upper voltage to switch off said power charging devices;
said energy recycling devices being switched with current mode control;
said current mode control detecting a zero voltage of drain node and inductor current continuing charging output load, said energy recycling devices being switched on to provide recycling power to said output load;
as said current mode control detecting zero inductor current, said energy recycling devices being switched being switched off.

12. [FIG. 1A FIG. 33B ] A green energy smart window unit according to claim 2 wherein processor further comprising a high-power-efficiency conjugated power amplifier system,
said conjugated power amplifier taking analog signals of positive sliced data and negative sliced data to operate at amplifier B mode and amplifier C mode,
said power amplifier being a differential amplifier having a pair of positive input aid negative input;
said conjugated power amplifier taking analog signals of positive sliced data and negative sliced data;
said positive sliced data being sent to said positive input and said negative sliced data being sent to said negative input;
said power-efficiency conjugated power amplifier system having an option to have data stream coming from baseband being sliced to be said positive sliced data and said negative sliced data; DACs converting said positive sliced data and said negative sliced data to be said analog signals of positive sliced data and negative sliced data,
said power amplifier operating at amplifier B mode and/or amplifier C mode.

13. [FIG. 1A FIG. 1L1 FIG. 44x FIG. 45x] A green energy smart window unit according to claim 3 wherein said mobile device charging unit further comprising a wireless power supply Recycling Resonant Resynchronization Rectifier Regulator 5R.
said wireless power supply Recycling Resonant Resynchronization Rectifier Regulator 5R having only one single stage to integrate conventional rectifier, DC/DC and LDO three stage to be single stage; said wireless power supply Recycling Resonant Resynchronization Rectifier further comprising LC resonator, switch and capacitors;
said capacitor being connected between said LC resonator and said switch,
said wireless power supply Recycling Resonant Resynchronization Rectifier Regulator 5R being connected between LC resonator and DC output loading;
said wireless power supply Recycling Resonant Resynchronization Rectifier Regulator 5R converting energy in said LC resonator to be DC power to supply said DC output loadin;
said wireless power supply Recycling Resonant Resynchronization Rectifier Regulator 5R further comprising capacitors biased at different level to have boost voltage to recycle resonating energy in said LC resonator to turn on switch devices in said wireless power supply Recycling Resonant Resynchronization Rectifier Regulator 5R synchronously,
said capacitors having one end been connected to output, terminal of said LC resonator and another end being connected to switching MOS devices of rectifier,
as said LC resonator resonating, said capacitors driving said switch with switching energy to switch-on and switch-off said switch device to perform rectifying function;
the switching energy of said capacitor being recycled through said LC resonator.
said switch being weakly biased at proper biasing voltages; said Recycling Resonant Resynchronization Rectifier Regulator 5R having an option of wave-shaping; said wave-shaping shaping up switching voltage of said switching to have sharp rising and falling edge to reduce on-resistance of said switching in switching transition process.

14. [FIG. 1A FIG. 26G FIG. 26H] A green energy smart window unit according to claim 3 wherein said power supply controller further comprising, a overshootless smart LDO comprising brake mechanism to deliver said DC output power at an output voltage smoothly;
said overshootless LDO having one error amplifier and voltage divider;
said voltage divider dividing said output voltage to generate a feedback voltage;
said error amplifier having a reference voltage and said feedback voltage been connected as inputs;
said brake mechanism connecting inputs of said steering-wheel mechanism;
said brake mechanism reducing the difference of input voltage of said inputs of said steering-wheel mechanism;
said brake mechanism having a switching connecting said reference voltage input terminal of said error amplifier with feedback voltage input terminal of said error amplifier as said feedback voltage being less than said reference voltage,
said overshootless smart LDO having an option of biasing current injecting modulating biasing current in said error amplifier as said feedback voltage being not equal to said reference voltage to increase bandwidth of said error amplifier to speedup said error amplifier in correct direction in orthogonal conjugated common-mode accelerator mode.
said overshootless smart LDO having an option of programmable analog LDO/digital LDO mechanism, accelerator mechanism and steering-wheel mechanism,
said programmable analog LDO digital LDO being able to programmable to be high-gain for analog LDO and high-bandwidth for digital LDO;
said accelerator mechanism being orthogonal conjugated with said steering-wheel mechanism to have fast reaction to ripple of output voltage.

15. [FIG. 1A FIG. 38B4 FIG. 38B7 FIG. 38B8 FIG. 38B9 FIG. 38 C1 FIG. 38C2] A green energy smart window unit according to claim 3 wherein said power supply controller further comprising a smart battery charger to drive battery and said electrochromic window,
said a smart battery charger further comprising switch mode power supply SMPS, low drop-offset LDO type analog buffer with the option of the addition of the H-Bridge for discharging;
said switch mode power supply SMPS providing power to said low drop-offset LDO type analog buffer, said low drop-offset LDO type analog buffer providing power to said H-Bridge;
said low drop-offset LDO type analog buffer being either analog buffer or LDO analog buffer;
said H-Bridge charging and discharging said battery and said electrochromic window with switches embedded in said H-Bridge.

16. [FIG. 1A FIG. 38B4 FIG. 38B7 FIG. 38B8 FIG. 38B10 FIG. 38B11 FIG. 38C1 FIG. 38C2] A green energy smart window unit according to claim 3 wherein said power supply controller further comprising a smart battery charger to drive battery and said electrochromic window,
said a smart battery charger further comprising switch mode power supply SAWS and H-Bridge;
said mode power supply SMPS providing power to said H-Bridge;
said H-Bridge further comprising low drop-offset LDO type analog buffer and switches;
said H-Bridge charging and discharging said battery and said electrochromic window with said itches and said low drop-offset LDO type analog buffer embedded in said H-Bridge;
said low drop-offset LDO type analog buffer being either analog buffer or LDO analog buffer;
said low drop-offset LDO type analog buffer further providing rippleless RF-Noiseless output power to said battery and said electrochromic window according to specified input voltages of said low drop-offset FDO type analog buffer.

17. [FIG. 1A FIG 26F] A green energy smart window unit according to claim 2 wherein processor further comprising ground-bounce-less output buffer,
said ground-bounce less output buffer further comprising non-overlapping mechanism tri-state mechanism and clamping mechanism,
said clamping mechanism detecting undershoot of said ground-bounce-less output buffer and turning off said N type output device;
said clamping mechanism detecting overshoot of said ground-bounce-less output buffer and turning off said P type output device

18. [FIG. 1A FIG. 26E] A green energy smart window unit according to claim 2 wherein processor further comprising substrate noiseless P&G plan having all, the ground nets being connected together going through a plural of LDO typed constant current sources.

19. [FIG. 1A FIG. 1F1 FIG. 1F2 FIG. 1F3] A green energy smart window unit according to claim 3 wherein said green energy smart window further comprising smart fans;
said smart fans further comprising bladders turbofan and temperature sensor;
said bladeless turbofan circulating air for air conditioning;
said temperature sensor detecting temperatures of air and said smart fans.

20. [FIG. 1A FIG. 46C FIG. 47A] A green energy smart window unit according to claim 3 wherein said electrochromic window further comprising thin film being made of layer being planarized and hardening with option of assistance of versatile combination of ultrasonic and microwave and deposition with option of being cleaned with assistance of ultrasonic;
said thin film being deposited to be layers
said layer first deposited one interfacing layer, then plating and hardening said interfacing layer to form a well crystallized foundation;
then said Layer depositing on said well-crystallized foundation to grow said layer.
said deposition comprising a gas reaction sputtering further comprising ultrasonic self-cleaning target to clean passion deposition on said target.
